(19) United States
(12) Patent Application Publication
(10) Pub. No.: US 2016/0181545 A1
(43) Pub. Date: Jun. 23, 2016

(54) ORGANIC ELECTROLUMINESCENT DEVICE

(71) Applicant: MERCK PATENT GMBH, Darmstadt (DE)

(72) Inventors: Philipp STOESSEL, Frankfurt Am Main (DE); Amir Hossain PARHAM, Frankfurt Am Main (DE); Christof PFLUMM, Darmstadt (DE); Anja JATSCH, Frankfurt Am Main (DE); Joachim KAISER, Darmstadt (DE)

(21) Appl. No.: 14/892,424

(22) PCT Filed: Mar. 18, 2014
(86) PCT No.: PCT/EP2014/000740

§ 371 Date: Nov. 19, 2015

(30) Foreign Application Priority Data
Jun. 6, 2013 (EP) 13002927.5

(51) Int. Cl. H01L 51/00; C09K 11/06; C09K 11/02; H01L 51/56

(52) U.S. Cl. CPC H01L 51/0072; H01L 51/0067; H01L 51/0008; H01L 51/0004; H01L 51/0003; H01L 51/56; C09K 11/06; C09K 11/02; H01L 51/5004

(57) ABSTRACT

The present invention relates to organic electroluminescent devices which comprise a mixture of a luminescent material having a small singlet-triplet separation and a matrix material in the emitting layer.

The present invention relates to organic electroluminescent devices which comprise a mixture of a luminescent material having a small singlet-triplet separation and a matrix material in the emitting layer.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are also, in particular, organometallic iridium and platinum complexes, which exhibit phosphorescence instead of fluorescence (M. A. Baldo et al., Appl. Phys. Lett. 1999, 75, 4-6). For quantum-mechanical reasons, an up to four-fold increase in the energy and power efficiency is possible using organometallic compounds as phosphorescence emitters.

In spite of the good results achieved with organometallic iridium and platinum complexes, these also have, however, a number of disadvantages: thus, iridium and platinum are rare and expensive metals. It would therefore be desirable, for resource conservation, to be able to avoid the use of these metals. Furthermore, metal complexes of this type in some cases have lower thermal stability than purely organic compounds or can only be sublimed to a limited extent owing to the high molecular weight, so that the use of purely organic compounds would also be advantageous for this reason so long as they result in comparably good efficiencies. Furthermore, blue-, in particular deep-blue-phosphorescent iridium and platinum emitters having high efficiency and a long lifetime can only be achieved with technical difficulty, so that there is also a need for improvement here. Furthermore, there is, in particular, a need for improvement in the lifetime of phosphorescent OLEDs comprising Ir or Pt emitters if elevated temperatures arise during operation of the OLED, as is the case in some applications.

An alternative development is the use of emitters which exhibit thermally activated delayed fluorescence (TADF) (for example H. Uoyama et al., Nature 2012, Vol. 492, 234). These are organic materials in which the energetic separation between the lowest triplet state T₁ and the first excited singlet state S₁ is so small that this energy separation is smaller or in the region of thermal energy. For quantum-statistical reasons, the excited states arise to the extent of 75% in the triplet state and to the extent of 25% in the singlet state on electronic excitation in the OLED. Since purely organic molecules usually cannot emit from the triplet state, 75% of the excited states cannot be utilised for emission, meaning that in principle only 25% of the excitation energy can be converted into light. However, if the energetic separation between the lowest triplet state and the lowest excited singlet state is not or is not significantly greater than the thermal energy, which is described by kT, the first excited singlet state of the molecule is accessible from the triplet state through thermal excitation and can be occupied thermally. Since this singlet state is an emissive state from which fluorescence is possible, this state can be used for the generation of light. Thus, the conversion of up to 100% of electrical energy into light is in principle possible on use of purely organic materials as emitters. Thus, an external quantum efficiency of greater than 19% is described in the prior art, which is of the same order of magnitude as for phosphorescent OLEDs. It is thus possible, using purely organic materials of this type, to achieve very good efficiencies and at the same time to avoid the use of rare metals, such as iridium or platinum. Furthermore, it is also possible in principle to achieve highly efficient blue-emitting OLEDs using such materials.

The prior art describes the use of various matrix materials in combination with emitters which exhibit thermally activated delayed fluorescence (called TADF compound below), for example carbazole derivatives (H. Uoyama et al., Nature 2012, 492, 234; Endo et al., Appl. Phys. Lett. 2011, 98, 083302; Nakagawa et al. Chem. Commun. 2012, 48, 9580; Lee et al. Appl. Phys. Lett. 2012, 101, 093306/1), phosphine oxide dibenzothiophene derivatives (H. Uoyama et al., Nature 2012, 492, 234) or silane derivatives (Mehes et al., Angew. Chem. Int. Ed. 2012, 51, 11311; Lee et al., Appl. Phys. Lett, 2012, 101, 093306/1).

A common feature of the electroluminescent devices described in the prior art is that the TADF compound is employed in the emitting layer in low doping concentrations of about 5-6% by weight. This corresponds approximately to the concentration in % by vol.

In general, there is still a further need for improvement, in particular with respect to lifetime, efficiency, voltage and/or roll-off behaviour, in organic electroluminescent devices which exhibit emission by the TADF mechanism. The technical object on which the present invention is based is thus the provision of OLEDs whose emission is based on TADF and which have improved properties, in particular with respect to one or more of the above-mentioned properties.

Surprisingly, it has been found that organic electroluminescent devices which have an organic TADF compound and a matrix material in the emitting layer, where the TADF compound is employed in a doping concentration of 7% by vol. or more, achieve this object and result in improvements in the organic electroluminescent device compared with electroluminescent devices which otherwise have the same structure, but comprise the same TADF compound in a lower concentration. The present invention therefore relates to organic electroluminescent devices of this type.

The present invention relates to an organic electroluminescent device comprising cathode, anode and an emitting layer, which comprises the following compounds:
(A) a matrix compound; and
(B) a luminescent organic compound which has a separation between the lowest triplet state T₁ and the first excited singlet state S₁ of ≦0.15 eV (TADF compound),
   characterised in that the TADF compound is present in the emitting layer in a doping concentration of 7% by vol. or more.

A matrix compound in the sense of the present invention is any compound which is present in the emitting layer and which is not a TADF compound.

The luminescent organic compound which has a separation between the lowest triplet state T₁ and the first excited singlet state S₁ of ≦0.15 eV is described in greater detail below. This is a compound which exhibits TADF (thermally activated delayed fluorescence). This compound is abbreviated to “TADF compound” in the following description.

An organic compound in the sense of the present invention is a carbon-containing compound which contains no metals. In particular, the organic compound is built up from the elements C, H, D, B, Si, N, P, O, S, F, Cl, Br and I.

A luminescent compound in the sense of the present invention is taken to mean a compound which is capable of emitting light at room temperature on optical excitation in an environment as is present in the organic electroluminescent device. The compound preferably has a luminescence quantum efficiency of at least 40%, particularly preferably at least 50%, very particularly preferably at least 60% and especially preferably at least 70%. The luminescence quantum efficiency is determined here in a layer in a mixture with the matrix material, as is to be employed in the organic electroluminescent device. The way in which the determination of the luminescence quantum yield is carried out for the purposes of the present invention is described in detail in general terms in the example part.

It is furthermore preferred for the TADF compound to have a short decay time. The decay time is preferably ≦50 ρs. The way in which the decay time is determined for the purposes of the present invention is described in detail in general terms in the example part.

The energy of the lowest excited singlet state (S₁) and of the lowest triplet state (T₁) is determined by quantum-chemical calculation. The way in which this determination is carried out in the sense of the present invention is described in detail in general terms in the example part.

As described above, the separation between S₁ and T₁ can be a maximum of 0.15 eV in order that the compound is a TADF compound in the sense of the present invention, it being better the smaller the separation. The separation between S₁ and T₁ is preferably ≦0.10 eV, particularly preferably ≦0.08 eV, very particularly preferably ≦0.05 eV.

The TADF compound is preferably an aromatic compound which has both donor and also acceptor substituents, where the LUMO and the HOMO of the compound only spatially overlap weakly. What is meant by donor or acceptor substituents is known in principle to the person skilled in the art. Suitable donor substituents are, in particular, diaryl- and diheteroarylamino groups and carbazole groups or carbazole derivatives, each of which are preferably bonded to the aromatic compound via N. These groups may also be substituted further. Suitable acceptor substituents are, in particular, cyano groups, but also, for example, electron-deficient heteroaryl groups, which may also be substituted further.

In order to prevent exciplex formation in the emitting layer, it is preferred for the following to apply to LUMO(TADF), i.e. the LUMO of the TADF compound, and HOMO(matrix), i.e. the HOMO of the matrix compound:

LUMO(TADF)−HOMO(matrix)>S₁(TADF)−0.4 eV;

particularly preferably:

LUMO(TADF)−HOMO(matrix)>S₁(TADF)−0.3 eV;

and very particularly preferably:

LUMO(TADF)−HOMO(matrix)>S₁(TADF)−0.2 eV.

S₁(TADF) here is the first excited singlet state S₁ of the TADF compound.

Examples of suitable molecules which exhibit TADF are the structures shown in the following table.

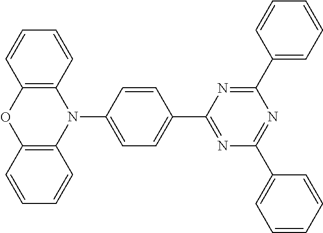 [SMILES: c1ccc(-c2nc(-c3ccccc3)nc(-c3ccc(N4c5ccccc5Oc5ccccc54)cc3)n2)cc1]

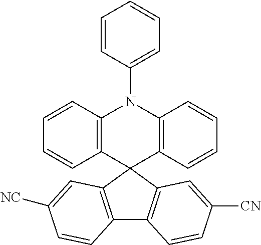 [SMILES: N#Cc1ccc2c(c1)C1(c3cc(C#N)ccc3-2)c2ccccc2N(c2ccccc2)c2ccccc21]

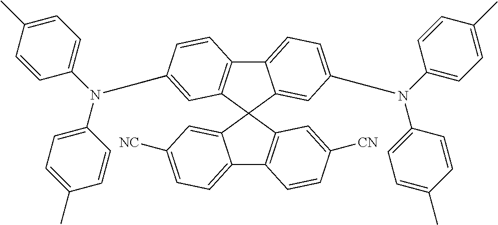

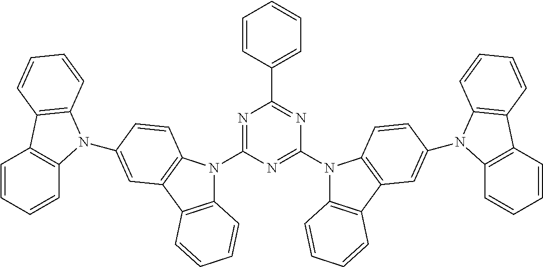 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1]

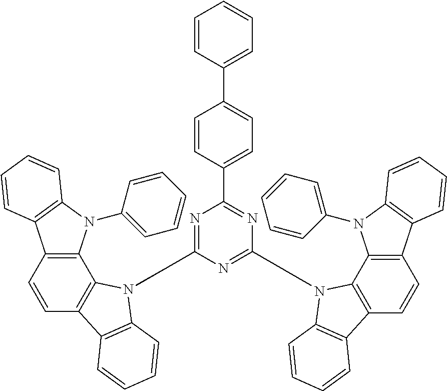

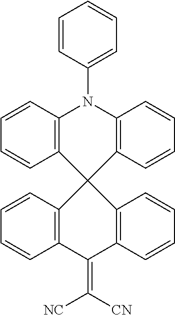 [SMILES: N#CC(C#N)=C1c2ccccc2C2(c3ccccc31)c1ccccc1N(c1ccccc1)c1ccccc12]

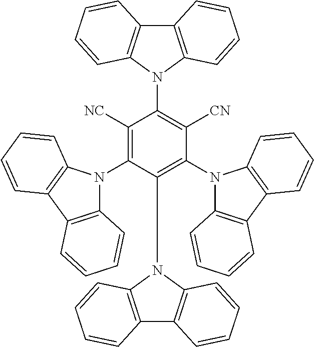

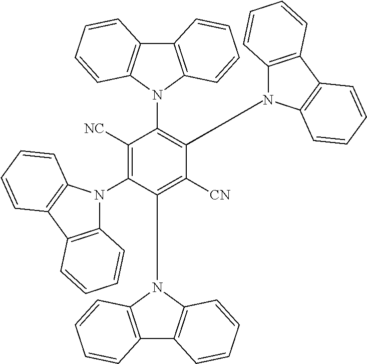

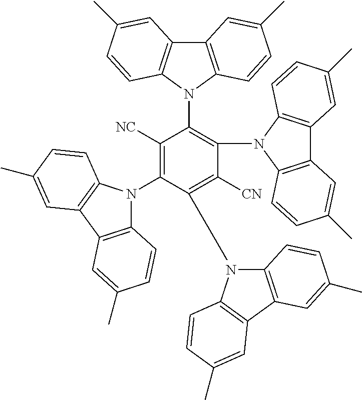

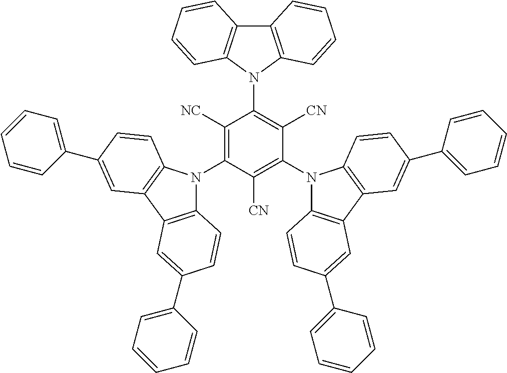 [SMILES: N#Cc1c(-n2c3ccccc3c3ccccc32)c(C#N)c(-n2c3ccc(-c4ccccc4)cc3c3cc(-c4ccccc4)ccc32)c(C#N)c1-n1c2ccc(-c3ccccc3)cc2c2cc(-c3ccccc3)ccc21]

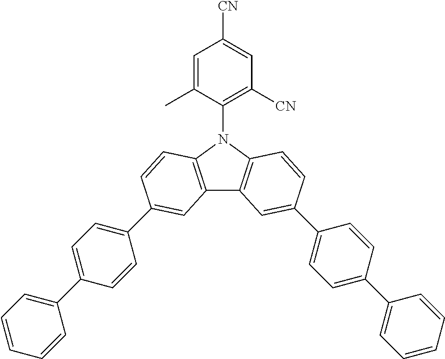 [SMILES: Cc1cc(C#N)cc(C#N)c1-n1c2ccc(-c3ccc(-c4ccccc4)cc3)cc2c2cc(-c3ccc(-c4ccccc4)cc3)ccc21]

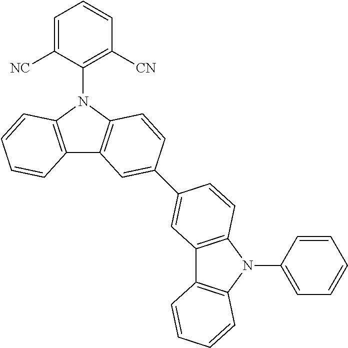 [SMILES: N#Cc1cccc(C#N)c1-n1c2ccccc2c2cc(-c3ccc4c(c3)c3ccccc3n4-c3ccccc3)ccc21]

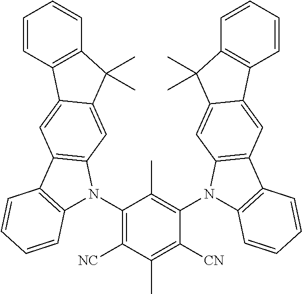 [SMILES: Cc1c(C#N)c(-n2c3ccccc3c3cc4c(cc32)C(C)(C)c2ccccc2-4)c(C)c(-n2c3ccccc3c3cc4c(cc32)C(C)(C)c2ccccc2-4)c1C#N]

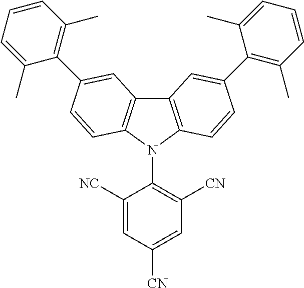 [SMILES: Cc1cccc(C)c1-c1ccc2c(c1)c1cc(-c3c(C)cccc3C)ccc1n2-c1c(C#N)cc(C#N)cc1C#N]

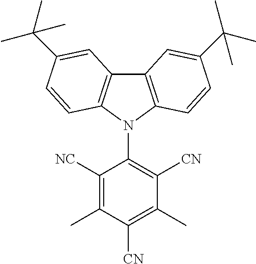 [SMILES: Cc1c(C#N)c(C)c(C#N)c(-n2c3ccc(C(C)(C)C)cc3c3cc(C(C)(C)C)ccc32)c1C#N]

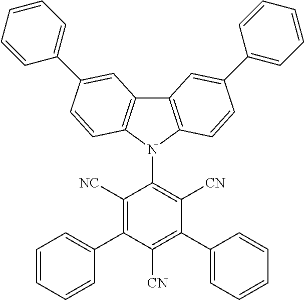 [SMILES: N#Cc1c(-c2ccccc2)c(C#N)c(-n2c3ccc(-c4ccccc4)cc3c3cc(-c4ccccc4)ccc32)c(C#N)c1-c1ccccc1]

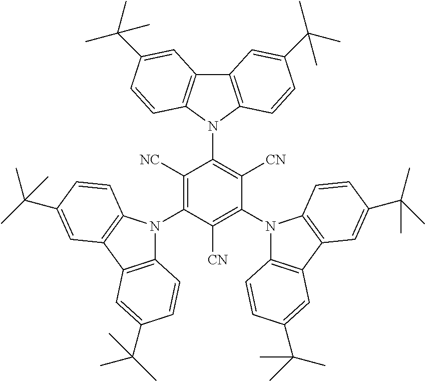 [SMILES: CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(C#N)c(-n2c3ccc(C(C)(C)C)cc3c3cc(C(C)(C)C)ccc32)c1C#N]

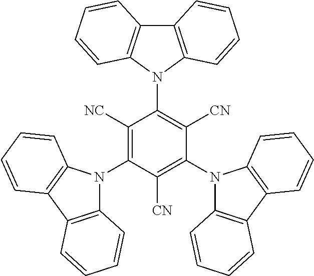 [SMILES: N#Cc1c(-n2c3ccccc3c3ccccc32)c(C#N)c(-n2c3ccccc3c3ccccc32)c(C#N)c1-n1c2ccccc2c2ccccc21]

In accordance with the invention, the TADF compound is present in the emitting layer in a doping concentration of 7% by vol. or more. The way in which the determination of the doping concentration is carried out for the purposes of the present invention is described in detail in general terms in the example part.

The doping concentration of the TADF compound in the emitting layer is preferably 25% by vol. or less.

In a preferred embodiment of the invention, the doping concentration of the TADF compound in the emitting layer is 7 to 20% by vol., particularly preferably 9 to 18% by vol. and very particularly preferably 10 to 15% by vol.

Correspondingly, the proportion of the matrix compound is preferably 80 to 93% by vol., particularly preferably 82 to 91% by vol. and very particularly preferably 85 to 90% by vol.

In a preferred embodiment of the invention, the matrix compound does not or does not significantly contribute to the emission of the mixture, and the TADF compound is the emitting compound, i.e. the compound whose emission from the emitting layer is observed.

In a preferred embodiment of the invention, the emitting layer consists only of precisely one matrix compound and the TADF compound.

In order that the TADF compound is the emitting compound in the mixture of the emitting layer, it is preferred for the lowest triplet energy of the matrix compound to be a maximum of 0.1 eV lower than the triplet energy of the TADF compound. Particularly preferably, T₁(matrix) is ≧T₁(TADF).

The following particularly preferably applies: T₁(matrix)−T₁(TADF)≧0.1 eV;

very particularly preferably: T₁(matrix)−T₁(TADF)≧0.2 eV.

T₁(matrix) here stands for the lowest triplet energy of the matrix compound, and T₁(TADF) stands for the lowest triplet energy of the TADF compound. The triplet energy of the matrix compound T₁(matrix) is determined here by quantum-chemical calculation, as described in general terms below in the example part.

Examples of suitable matrix compounds which can be used in the emitting layer according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, pyrimidine derivatives, quinoxaline derivatives, Zn, Al or Be complexes, for example in accordance with EP 652273 or WO 2009/062578, or bridged carbazole derivatives, for example in accordance with US 2009/0136779, WO 2010/050778, WO 2011/042107 or WO 2011/088877. These are incorporated into the present invention by way of reference.

The matrix compound preferably has a glass-transition temperature T_{G} of greater than 70° C., particularly preferably greater than 90° C., very particularly preferably greater than 110° C.

The matrix compounds are preferably charge-transporting, i.e. electron-transporting or hole-transporting or bipolar compounds. The matrix compounds used can furthermore also be compounds which are neither holenor electron-transporting in the sense of the present application.

An electron-transporting compound in the sense of the present invention is a compound which has an LUMO≦−2.50 eV. The LUMO is preferably ≦−2.60 eV, particularly preferably ≦−2.65 eV, very particularly preferably ≦−2.70 eV. The LUMO here is the lowest unoccupied molecular orbital.

The value of the LUMO of the compound is determined by quantum-chemical calculation, as described in general terms below in the example part.

A hole-transporting compound in the sense of the present invention is a compound which has an HOMO≧−5.5 eV. The HOMO is preferably ≧−5.4 eV, particularly preferably ≧−5.3 eV. The HOMO here is the highest occupied molecular orbital. The value of the HOMO of the compound is determined by quantum-chemical calculation, as described in general terms below in the example part.

A bipolar compound in the sense of the present invention is a compound which is both hole- and electron-transporting.

Compound classes which are preferably suitable as electron-conducting matrix compound in the organic electroluminescent device according to the invention are described below.

Suitable electron-conducting matrix compounds are selected from the substance classes of the triazines, the pyrimidines, the lactams, the metal complexes, in particular the Be, Zn and Al complexes, the aromatic ketones, the aromatic phosphine oxides, the azaphospholes, the azaboroles, which are substituted by at least one electron-conducting substituent, and the quinoxalines.

In a preferred embodiment of the invention, the electron-conducting compound is a purely organic compound, i.e. a compound which contains no metals.

If the electron-conducting compound is a triazine or pyrimidine compound, this compound is then preferably selected from the compounds of the following formulae (1) and (2),

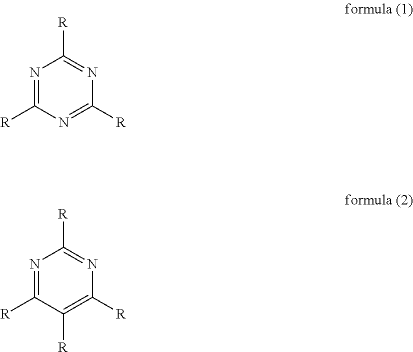

where the following applies to the symbols used
R is selected on each occurrence, identically or differently, from the group consisting of H, D, F, Cl, Br, I, CN, NO₂, N(Ar)₂, N(R¹)₂, C(═O)Ar, C(═O)R¹, P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, CI, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which may be substituted by one or more radicals R¹, or an aralkyl or heteroaralkyl group having 5 to 60 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar)₂, N(R²)₂, C(═O)Ar, C(═O)R², P(═O)(Ar)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, C═O, C═S, C═NR², P(═O)(R²), SO, SO₂, NR², O, S or CONR² and where one or more H atoms may be replaced by D, F, CI, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or an aralkyl or heteroaralkyl group having 5 to 60 aromatic ring atoms, where two or more adjacent substituents R¹ may optionally form a monocyclic or polycyclic, aliphatic, aromatic or heteroaromatic ring system, which may be substituted by one or more radicals R²;
Ar is on each occurrence, identically or differently, an aromatic or heteroaromatic ring system having 5-60 aromatic ring atoms, which may be substituted by one or more non-aromatic radicals R²; two radicals Ar which are bonded to the same N atom or P atom here may also be bridged to one another by a single bond or a bridge selected from N(R²), C(R²)₂, O or S;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another.

Adjacent substituents in the sense of the present application are substituents which are either bonded to the same carbon atom or which are bonded to carbon atoms which are in turn bonded directly to one another.

An aryl group in the sense of this invention contains 6 to 60 C atoms; a heteroaryl group in the sense of this invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic rings linked to one another by a single bond, such as, for example, biphenyl, are, by contrast, not referred to as an aryl or heteroaryl group, but instead as an aromatic ring system.

An aromatic ring system in the sense of this invention contains 6 to 80 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit, such as, for example, a C, N or O atom. Thus, for example, systems such as fluorene, 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are connected, for example, by a short alkyl group.

For the purposes of the present invention, an aliphatic hydrocarbon radical or an alkyl group or an alkenyl or alkynyl group, which may contain 1 to 40 C atoms and in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl. An alkoxy group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy or 2,2,2-trifluoroethoxy. A thioalkyl group having 1 to 40 C atoms is taken to mean, in particular, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethyl hexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio. In general, alkyl, alkoxy or thioalkyl groups in accordance with the present invention may be straight-chain, branched or cyclic, where one or more non-adjacent CH₂ groups may be replaced by the above-mentioned groups; furthermore, one or more H atoms may also be replaced by D, F, Cl, Br, I, CN or NO₂, preferably F, Cl or CN, furthermore preferably F or CN, particularly preferably CN.

An aromatic or heteroaromatic ring system having 5-30 or 5-60 aromatic ring atoms respectively, which may also in each case be substituted by the above-mentioned radicals R, R¹ or R², is taken to mean, in particular, groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or groups derived from combinations of these systems.

In a preferred embodiment of the compounds of the formula (1) or formula (2), at least one of the substituents R stands for an aromatic or heteroaromatic ring system. In formula (1), it is particularly preferred for all three substituents R to stand for an aromatic or heteroaromatic ring system, which may in each case be substituted by one or more radicals R¹. In formula (2), it is particularly preferred for one, two or three substituents R to stand for an aromatic or heteroaromatic ring system, which may in each case be substituted by one or more radicals R¹, and for the other substituents R to stand for H. Preferred embodiments are thus the compounds of the following formulae (1a) and (2a) to (2d),

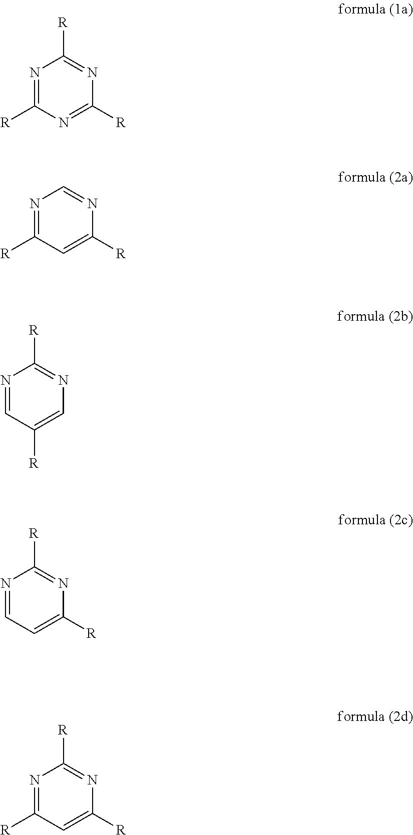

where R stands, identically or differently, for an aromatic or heteroaromatic ring system having 5 to 60 aromatic ring atoms, which may in each case be substituted by one or more radicals R¹, and R¹ has the above-mentioned meaning.

In the case of the pyrimidine compounds, preference is given here to the compounds of the formulae (2a) and (2d), in particular compounds of the formula (2d).

Preferred aromatic or heteroaromatic ring systems contain 5 to 30 aromatic ring atoms, in particular 6 to 24 aromatic ring atoms, and may be substituted by one or more radicals R¹. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. This preference is due to the higher triplet energy of substituents of this type. Thus, it is particularly preferred for R to have, for example, no naphthyl groups or higher condensed aryl groups and likewise no quinoline groups, acridine groups, etc. By contrast, it is possible for R to have, for example, carbazole groups, dibenzofuran groups, fluorene groups, etc., since no 6-membered aromatic or heteroaromatic rings are condensed directly onto one another in these structures.

Preferred substituents R are selected, identically or differently on each occurrence, from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, phenanthrene or combinations of two or three of these groups, each of which may be substituted by one or more radicals R¹. In addition, one or more C atoms in the above-mentioned aromatic ring systems may be replaced by N.

Preferred biphenyl, terphenyl and quaterphenyl groups are the groups of the following formulae (Bi-1) to (Bi-3), (Ter-1) to (Ter-3) and (Quater-1) to (Quater-4),

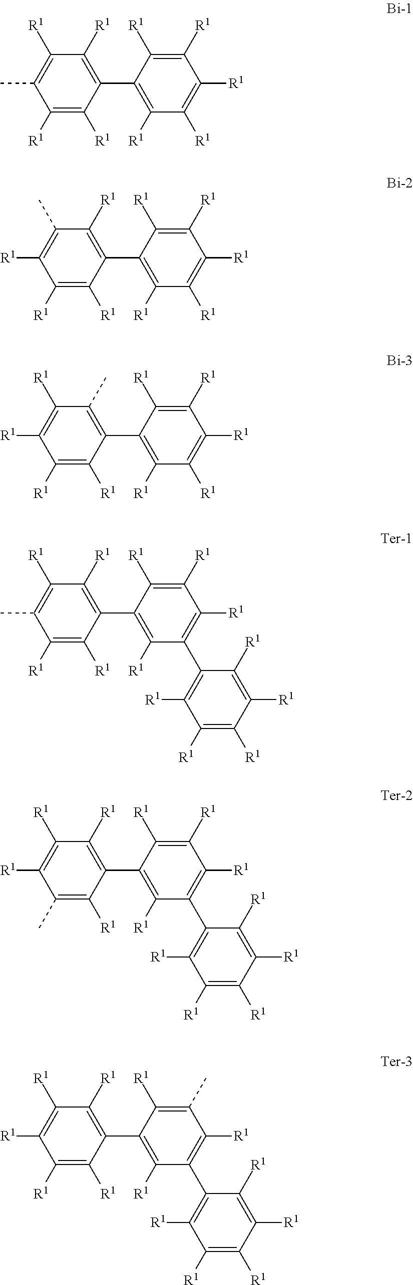

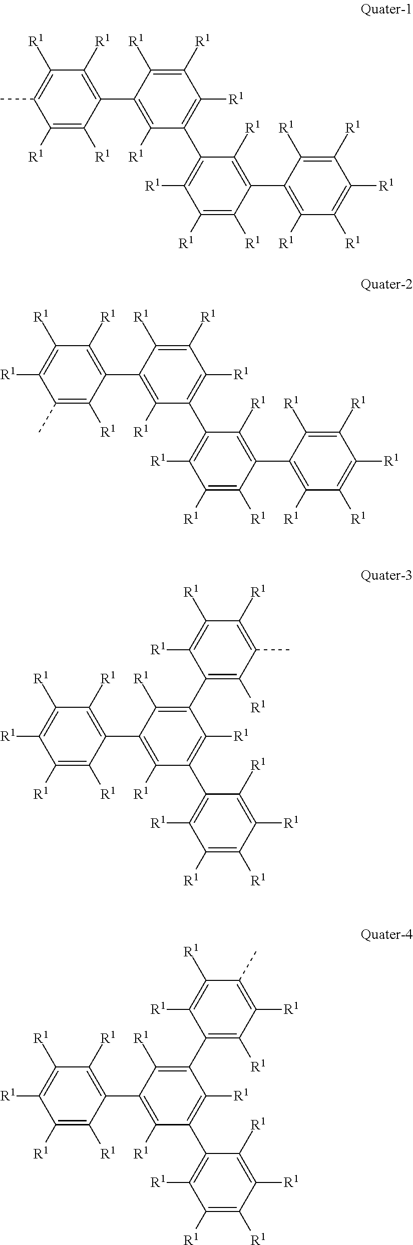

where R¹ has the above-mentioned meanings, and the dashed bond indicates the bond to the triazine or pyrimidine.

It is particularly preferred for at least one group R to be selected from the structures of the following formulae (3) to (44),

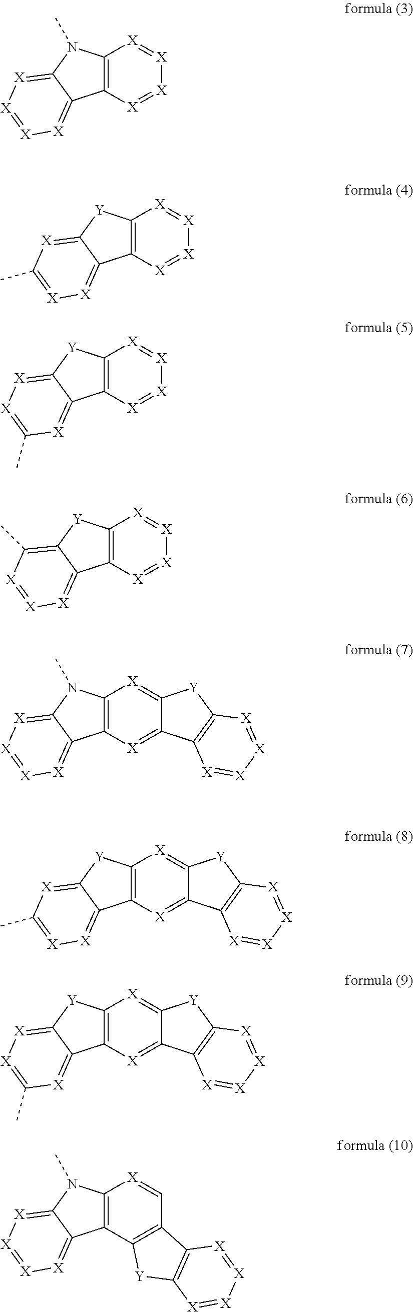

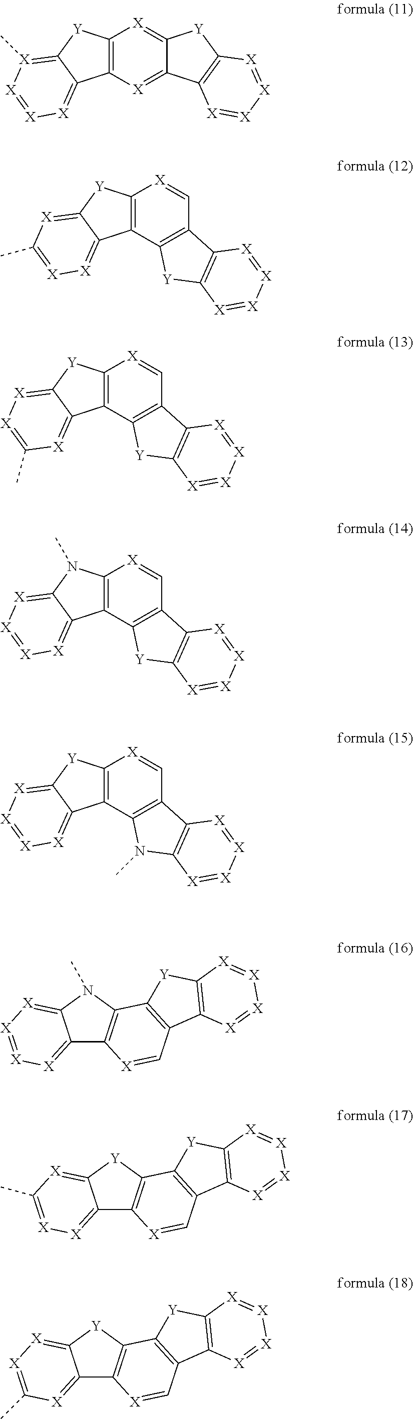

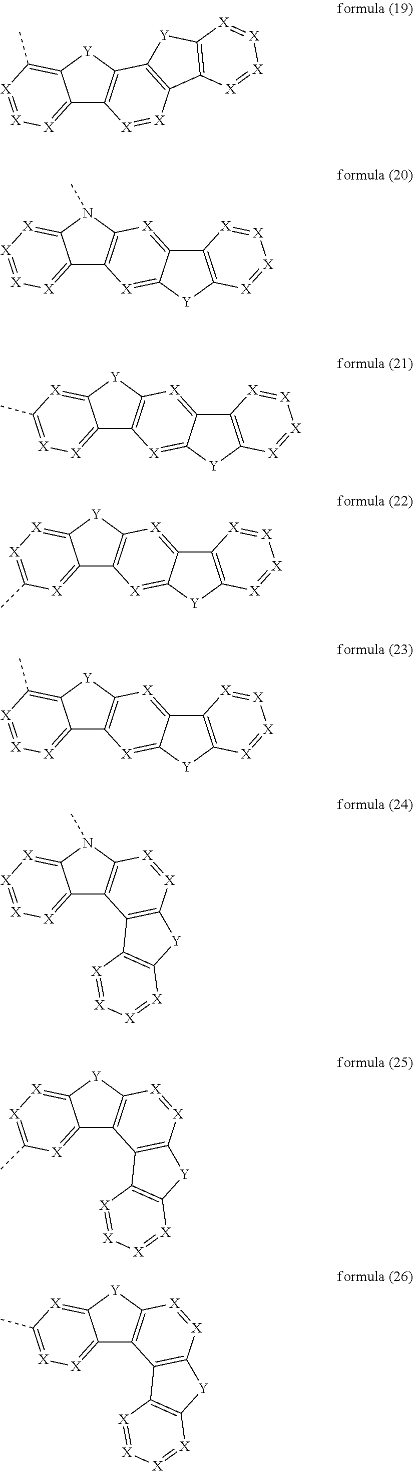

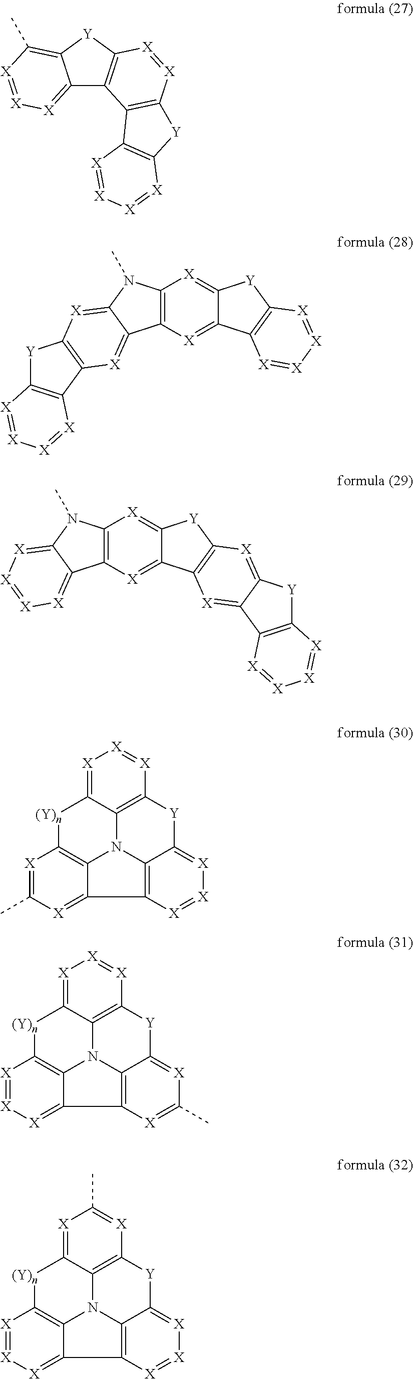

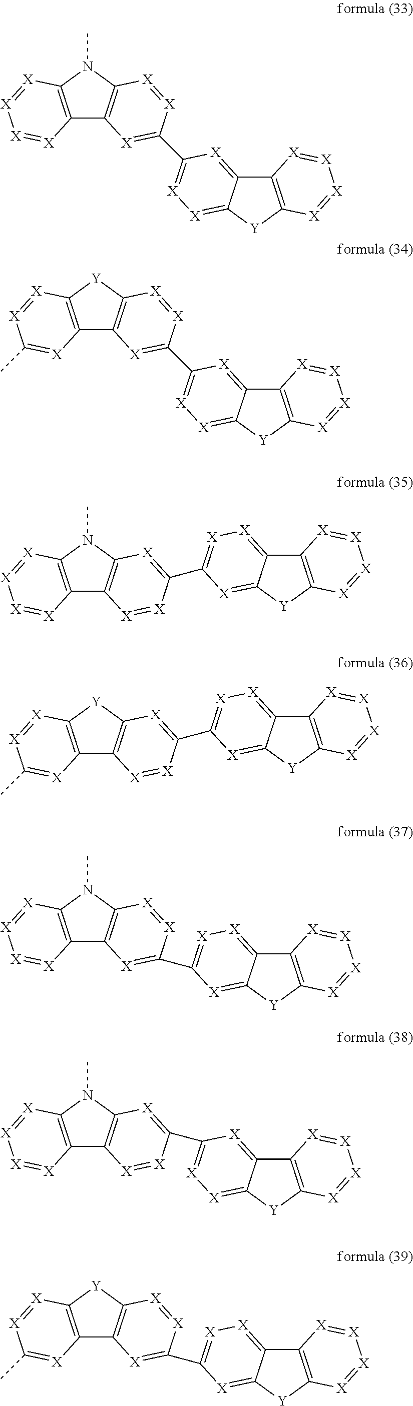

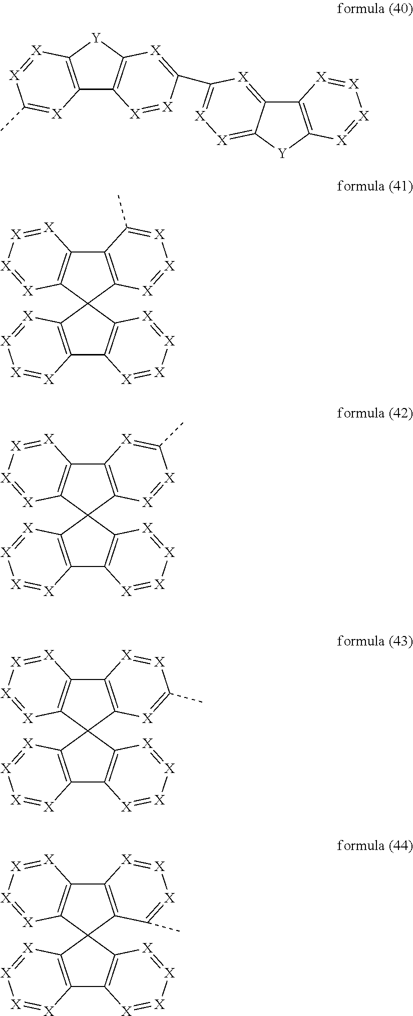

where R¹ and R² have the above-mentioned meanings, the dashed bond represents the bond to the group of the formula (1) or (2), and furthermore:
X is on each occurrence, identically or differently, CR¹ or N, where preferably a maximum of 2 symbols X per ring stand for N;
Y is on each occurrence, identically or differently, C(R¹)₂, NR¹, O or S;
n is 0 or 1, where n equals 0 means that no group Y is bonded at this position and instead radicals R¹ are bonded to the corresponding carbon atoms.

The term “per ring” mentioned above and also used below relates, for the purposes of the present application, to each individual ring present in the compound, i.e. to each individual 5- or 6-membered ring.

In preferred groups of the above-mentioned formulae (3) to (44), a maximum of one symbol X per ring stands for N. The symbol X particularly preferably stands, identically or differently on each occurrence, for CR¹, in particular for CH.

If the groups of the formulae (3) to (44) have a plurality of groups Y, all combinations from the definition of Y are possible for this purpose. Preference is given to groups of the formulae (3) to (44) in which one group Y stands for NR¹ and the other group Y stands for C(R¹)₂ or in which both groups Y stand for NR¹ or in which both groups Y stand for O.

In a further preferred embodiment of the invention, at least one group Y in the formulae (3) to (44) stands, identically or differently on each occurrence, for C(R¹)₂ or for NR¹.

If Y stands for NR¹, the substituent R¹ which is bonded directly to a nitrogen atom preferably stands for an aromatic or heteroaromatic ring system having 5 to 24 aromatic ring atoms, which may also be substituted by one or more radicals R². In a particularly preferred embodiment, this substituent R¹ stands, identically or differently on each occurrence, for an aromatic or heteroaromatic ring system having 6 to 24 aromatic ring atoms which has no condensed aryl groups and which has no condensed heteroaryl groups in which two or more aromatic or heteroaromatic 6-membered ring groups are condensed directly onto one another and which may in each case also be substituted by one or more radicals R². Particular preference is given to structures Bi-1 to Bi-3, Ter-1 to Ter-3 and Quater-1 to Quater-4 shown above.

If Y stands for C(R¹)₂, R¹ preferably stands, identically or differently on each occurrence, for a linear alkyl group having 1 to 10 C atoms or for a branched or cyclic alkyl group having 3 to 10 C atoms or for an aromatic or heteroaromatic ring system having 5 to 24 aromatic ring atoms, which may also be substituted by one or more radicals R². R¹ very particularly preferably stands for a methyl group or for a phenyl group. The radicals R¹ may also form a ring system with one another which results in a Spiro system.

Furthermore, it may be preferred for the group of the above-mentioned formulae (3) to (44) not to bond directly to the triazine in formula (1) or the pyrimidine in formula (2), but instead via a bridging group. This bridging group is then preferably selected from an aromatic or heteroaromatic ring system having 5 to 24 aromatic ring atoms, in particular having 6 to 12 aromatic ring atoms, which may in each case be substituted by one or more radicals R¹. Preferred aromatic ring systems are ortho-, meta- or para-phenylene or a biphenyl group, each of which may be substituted by one or more radicals R¹, but are preferably unsubstituted.

Examples of preferred compounds of the formula (1) or (2) are the following compounds.

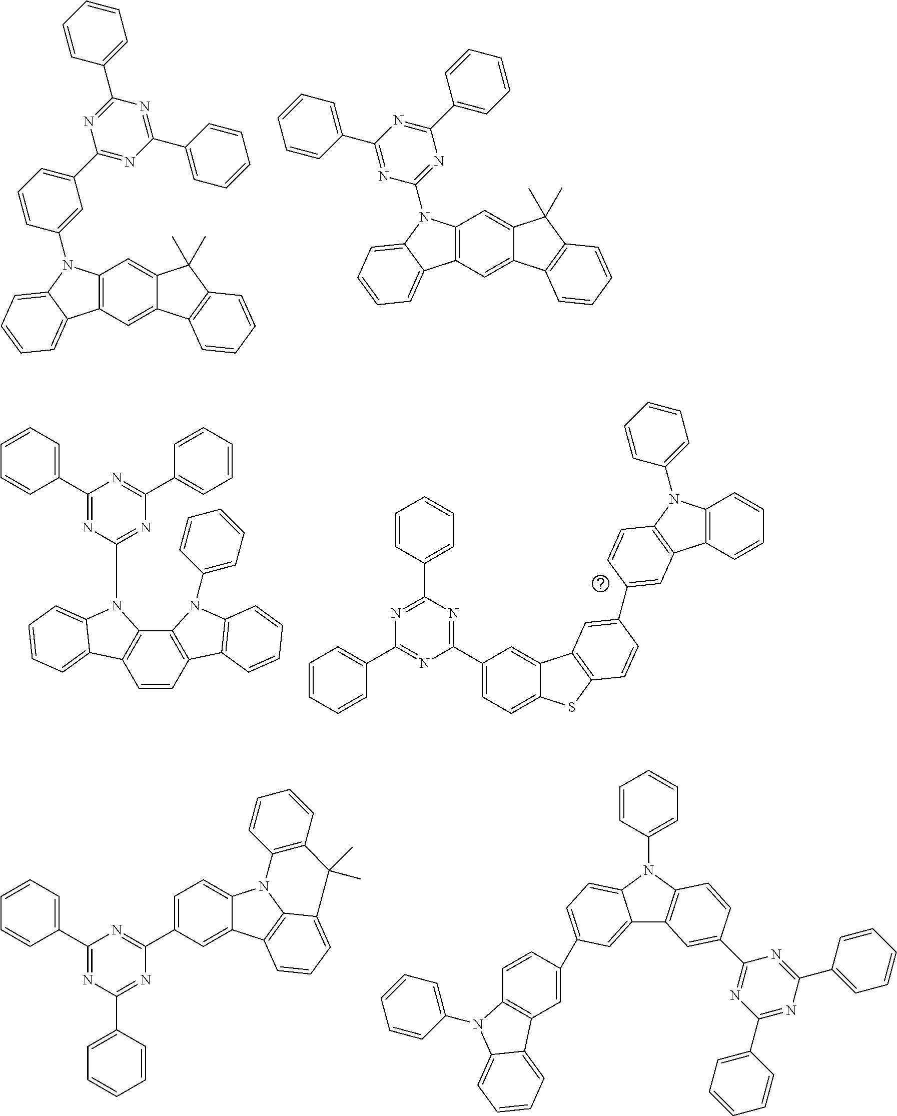

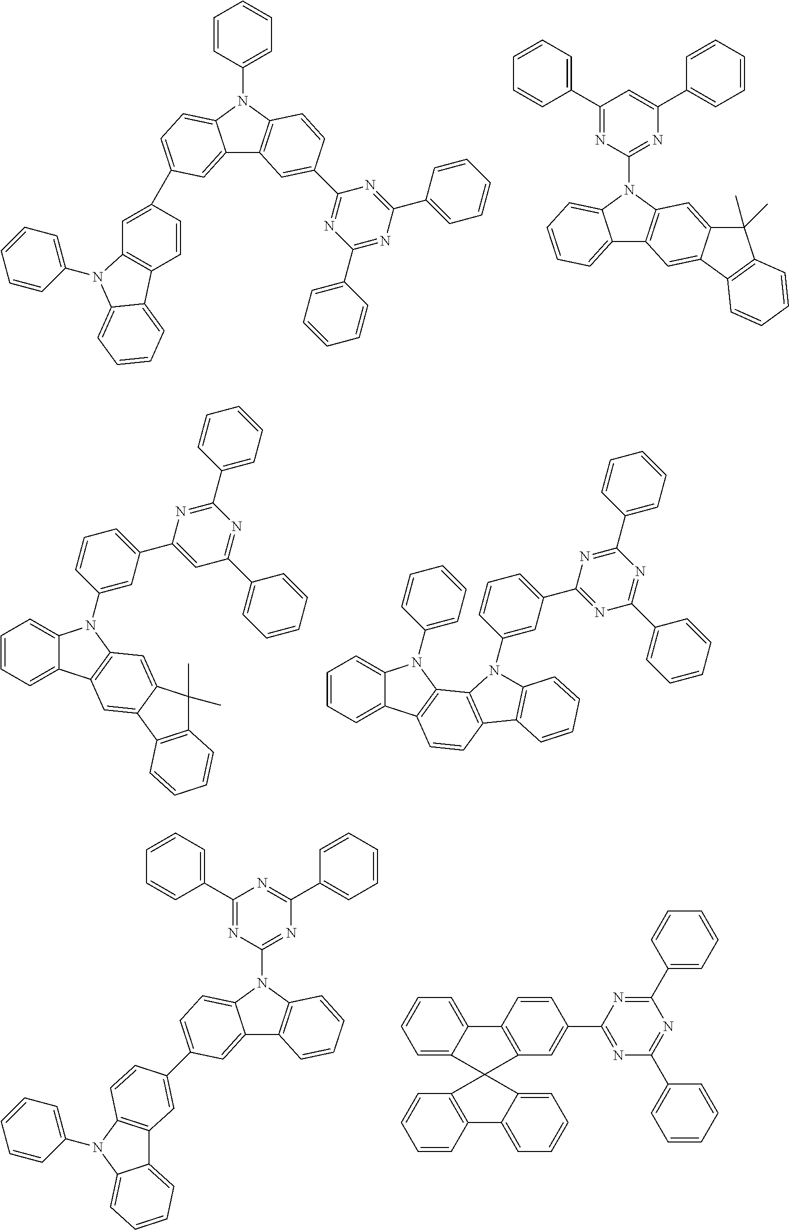

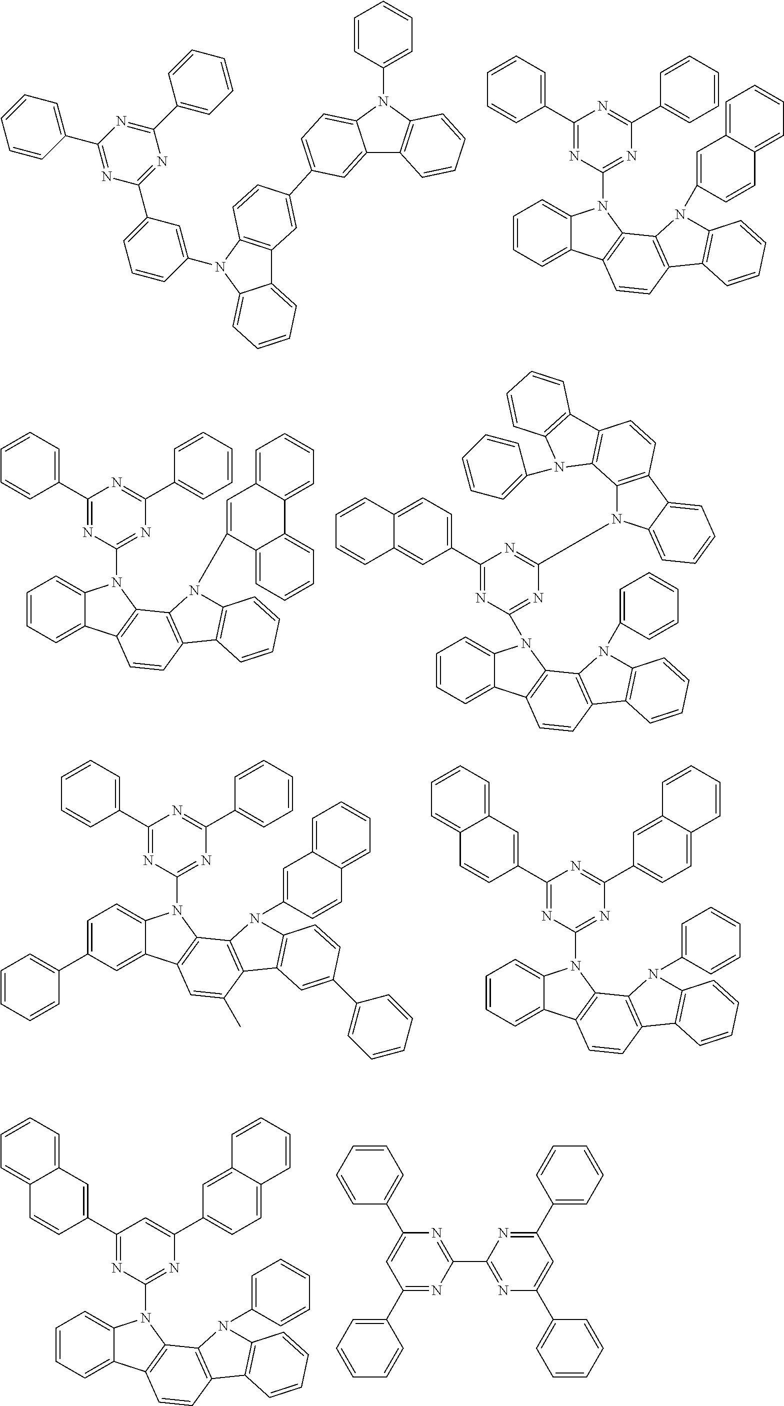

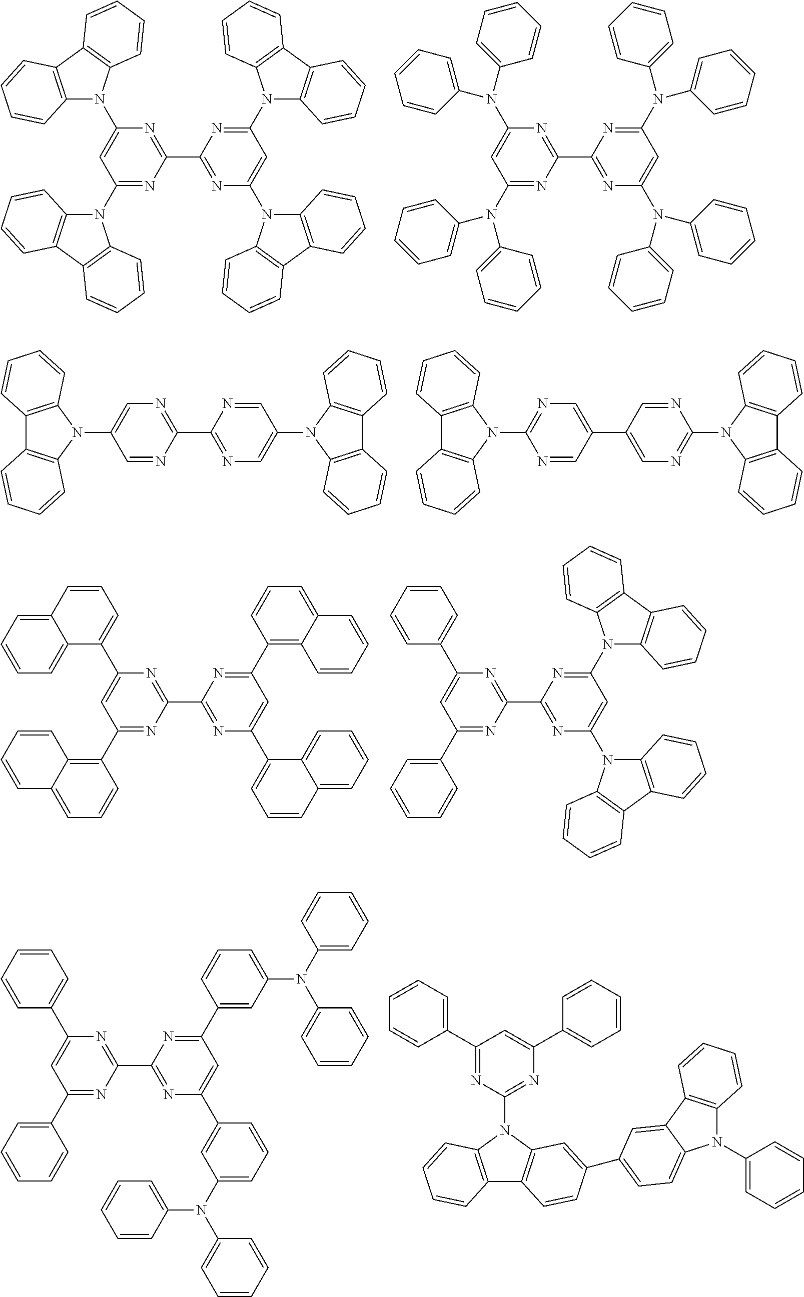

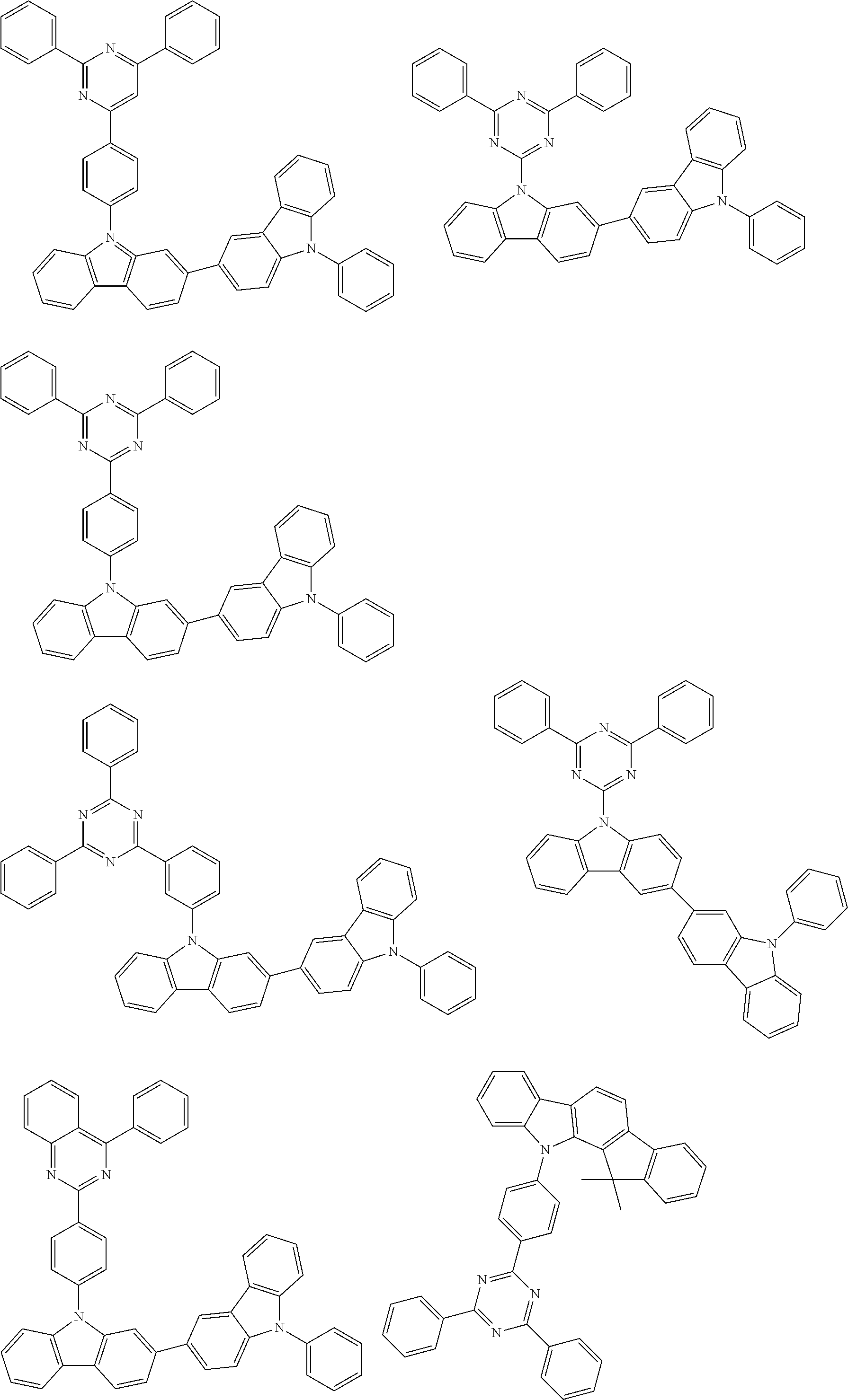

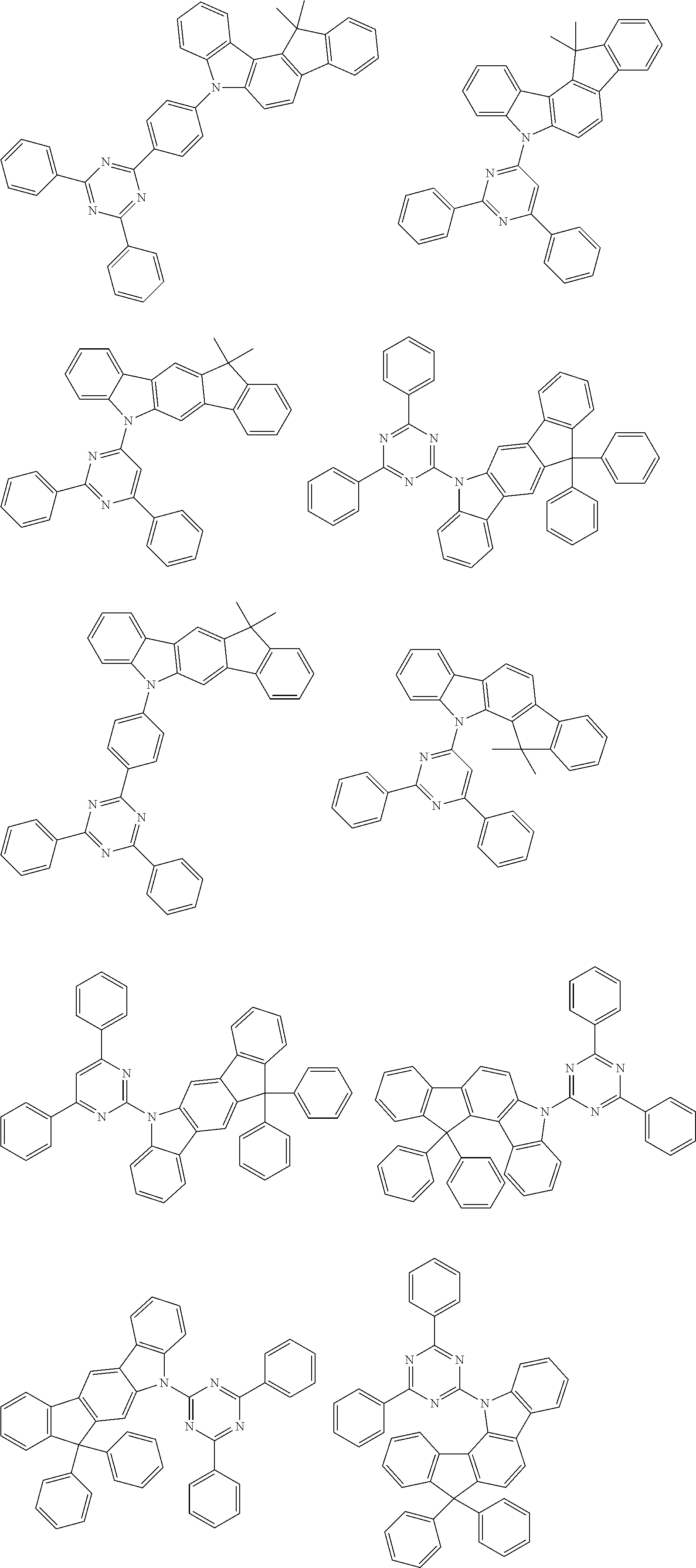

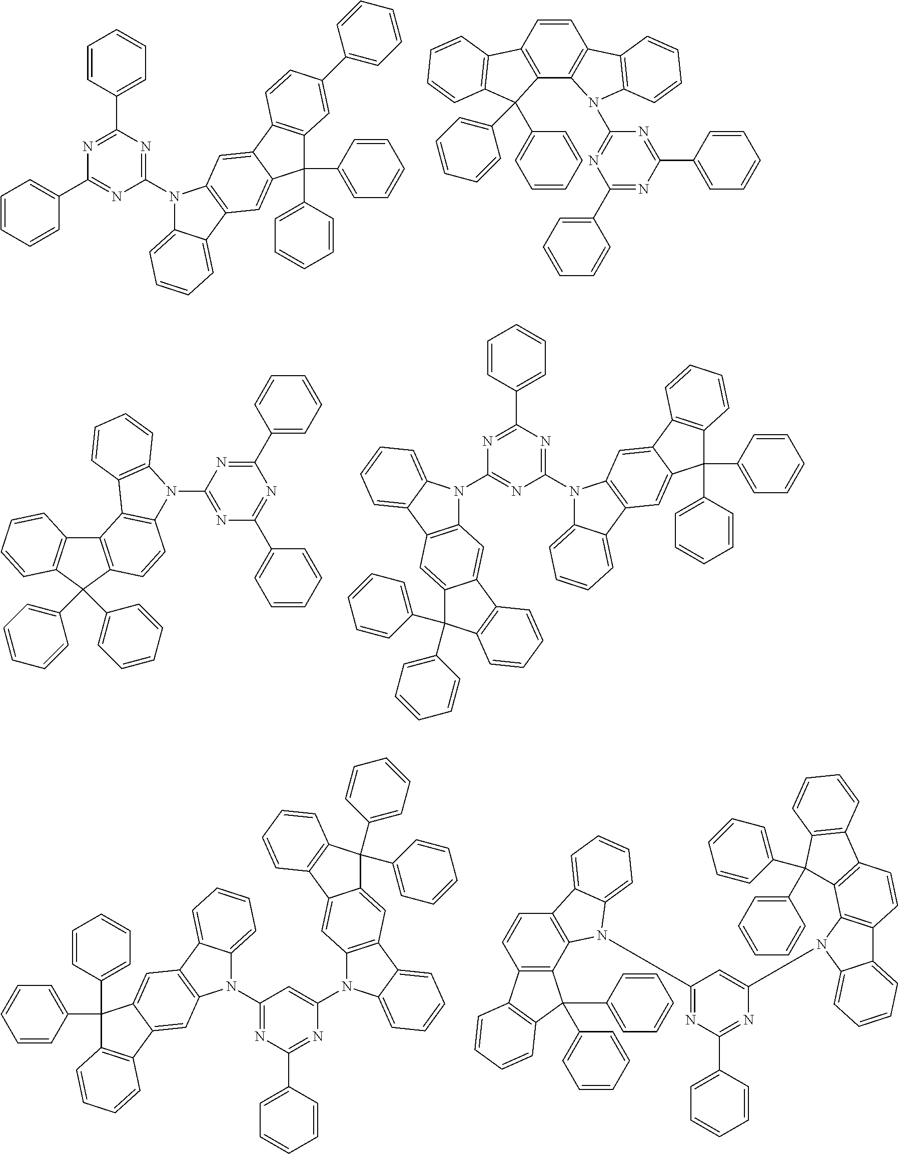

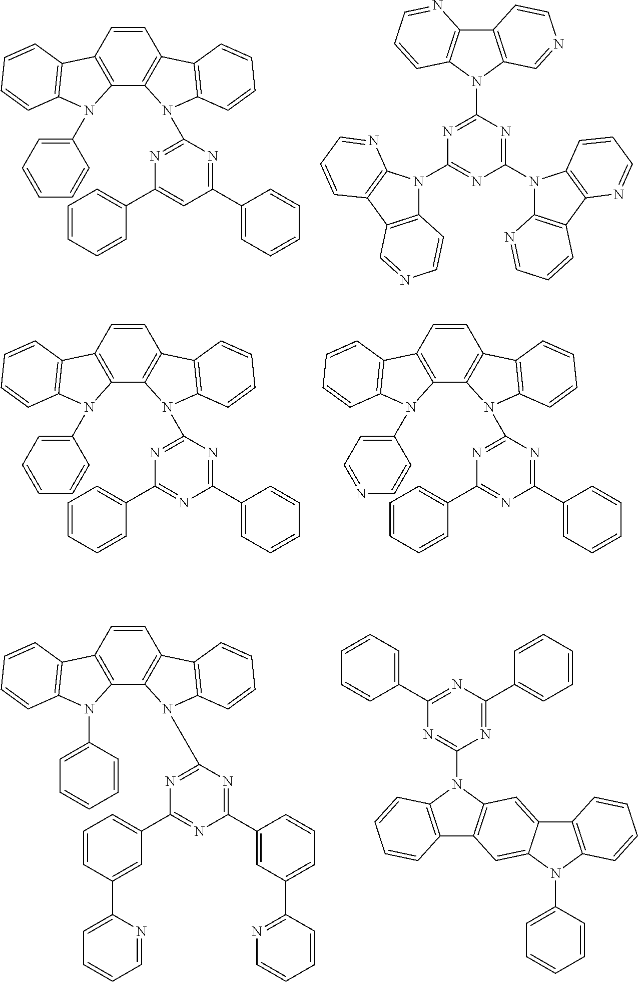

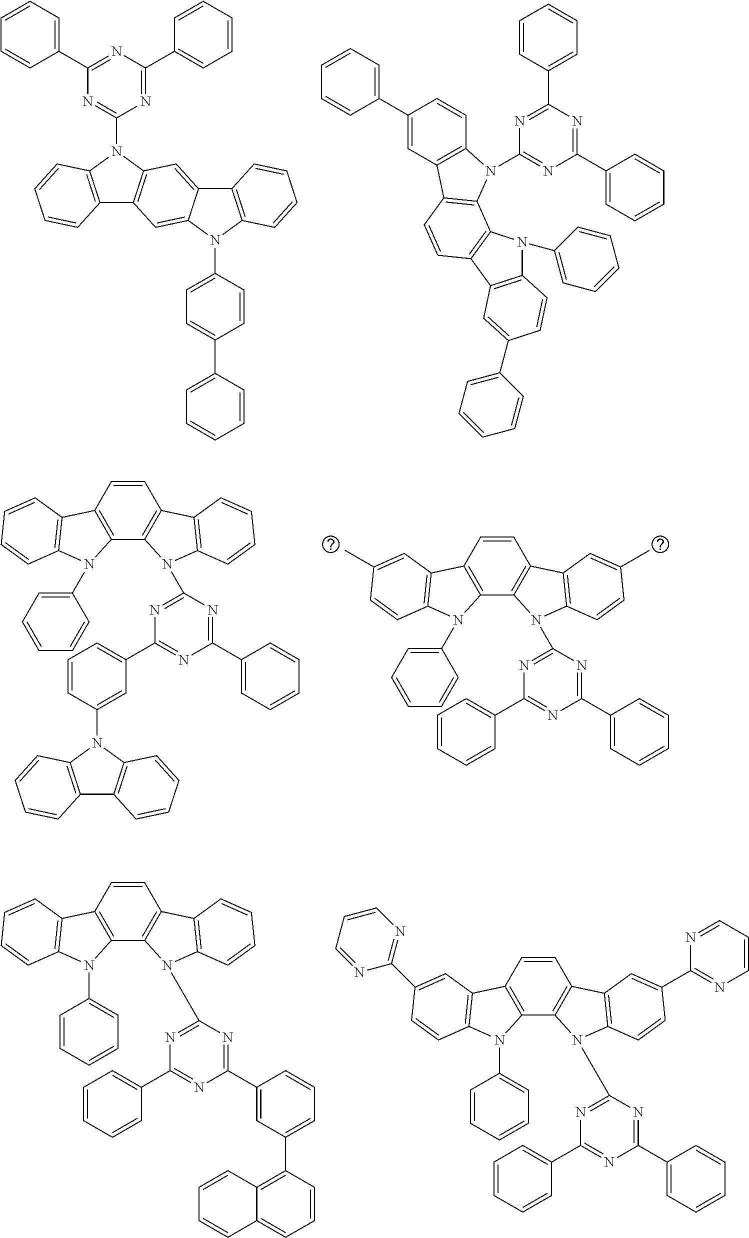

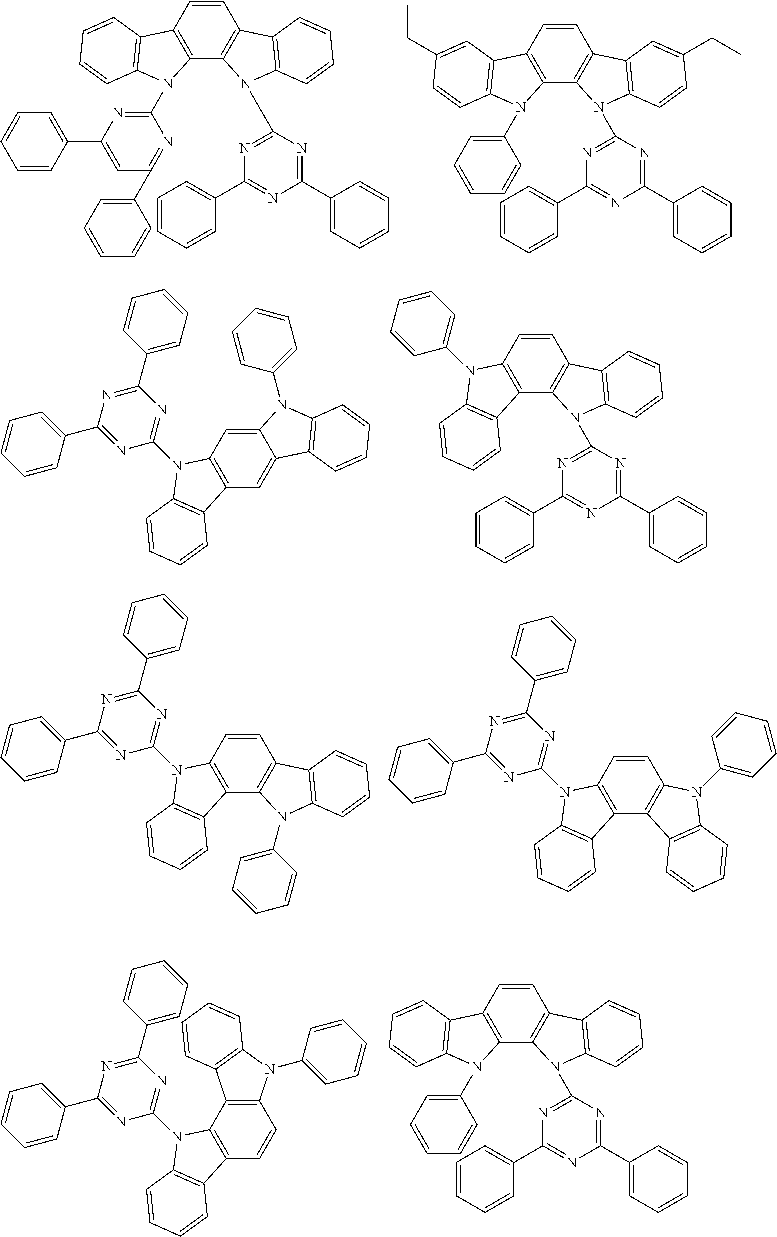

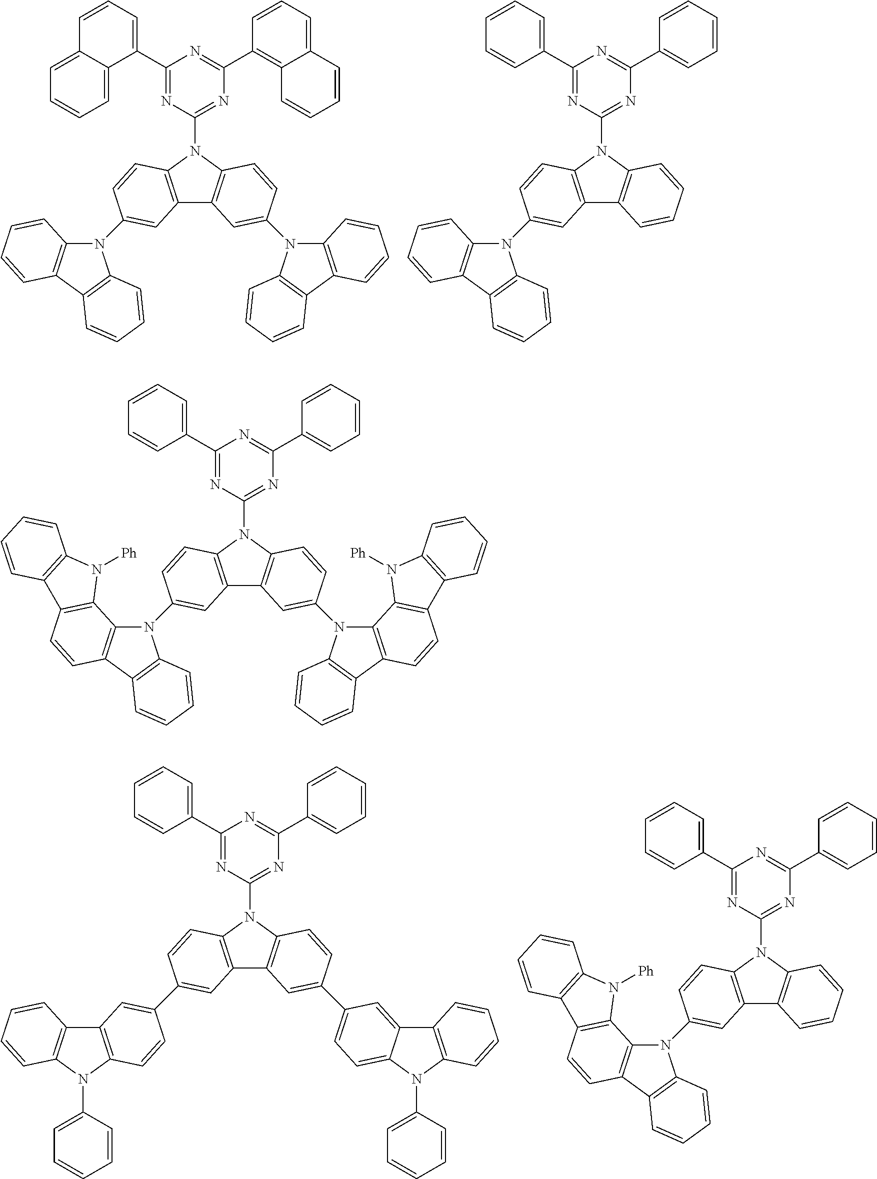

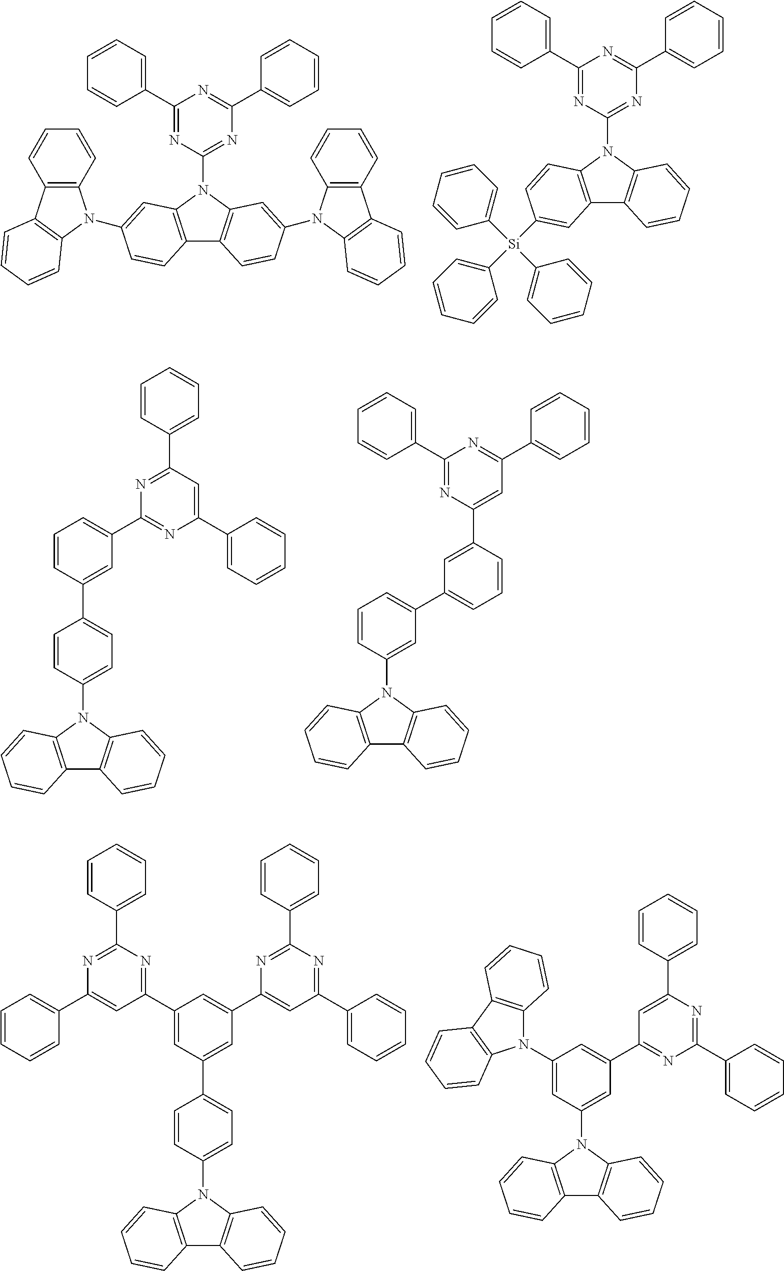

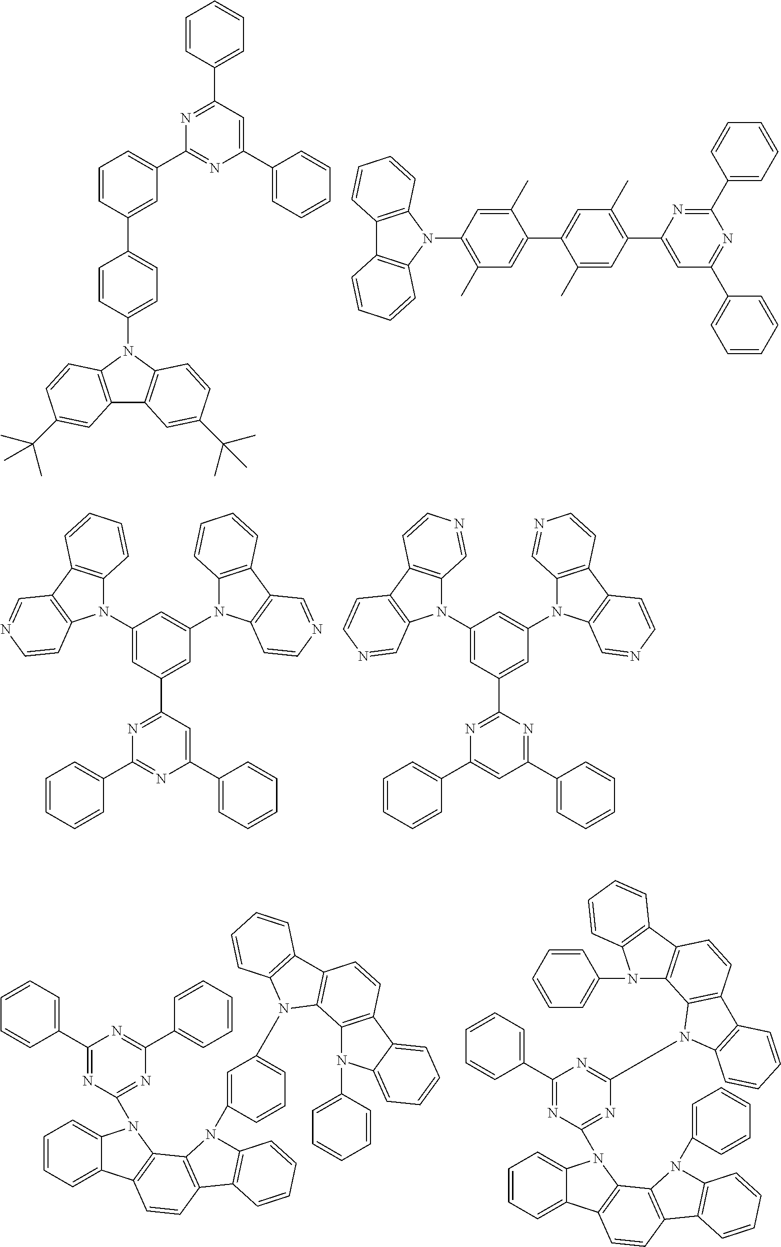

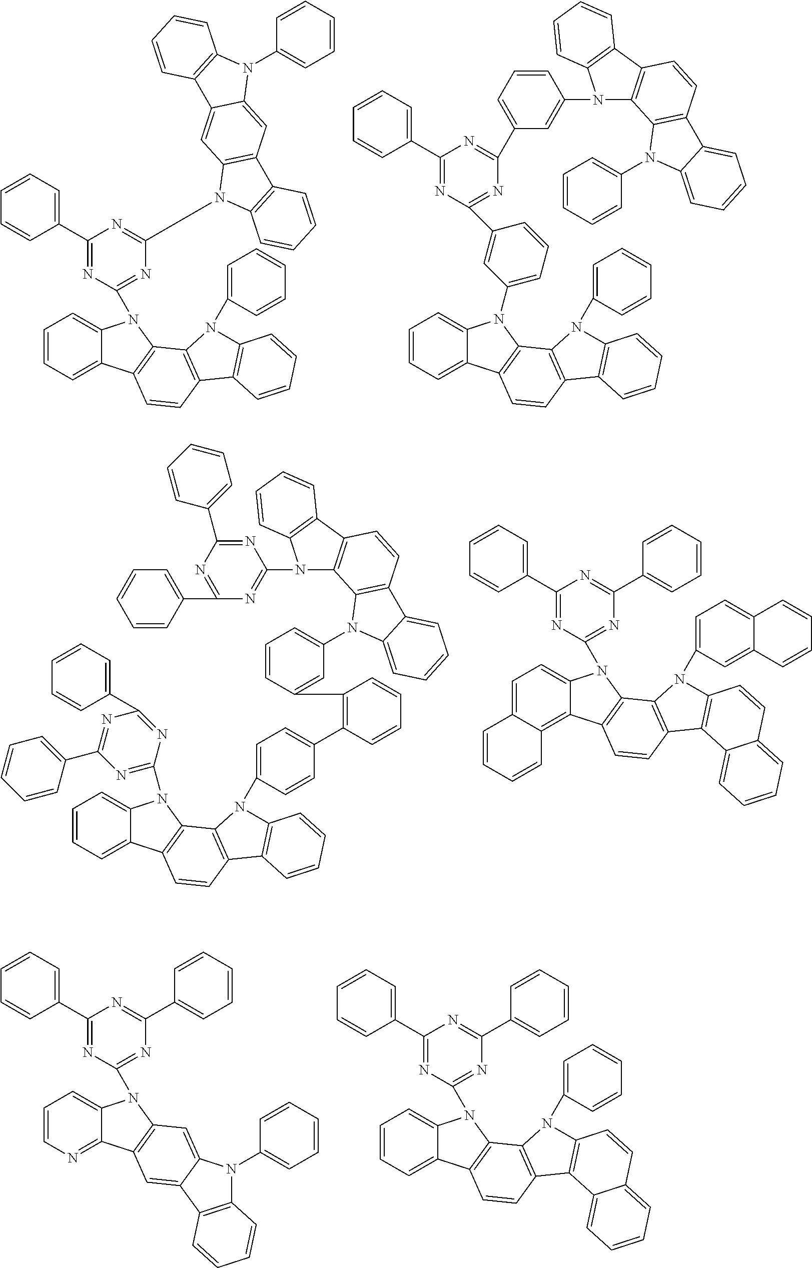

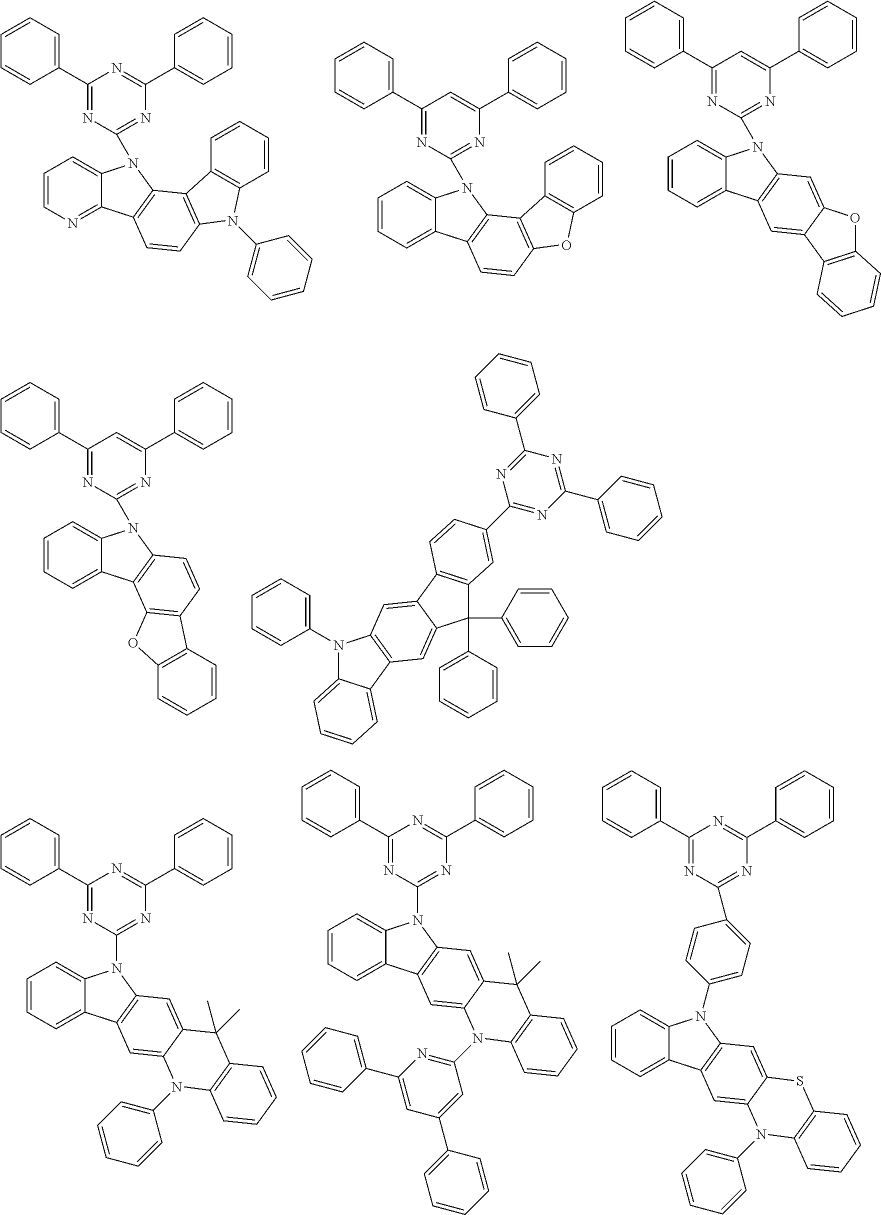

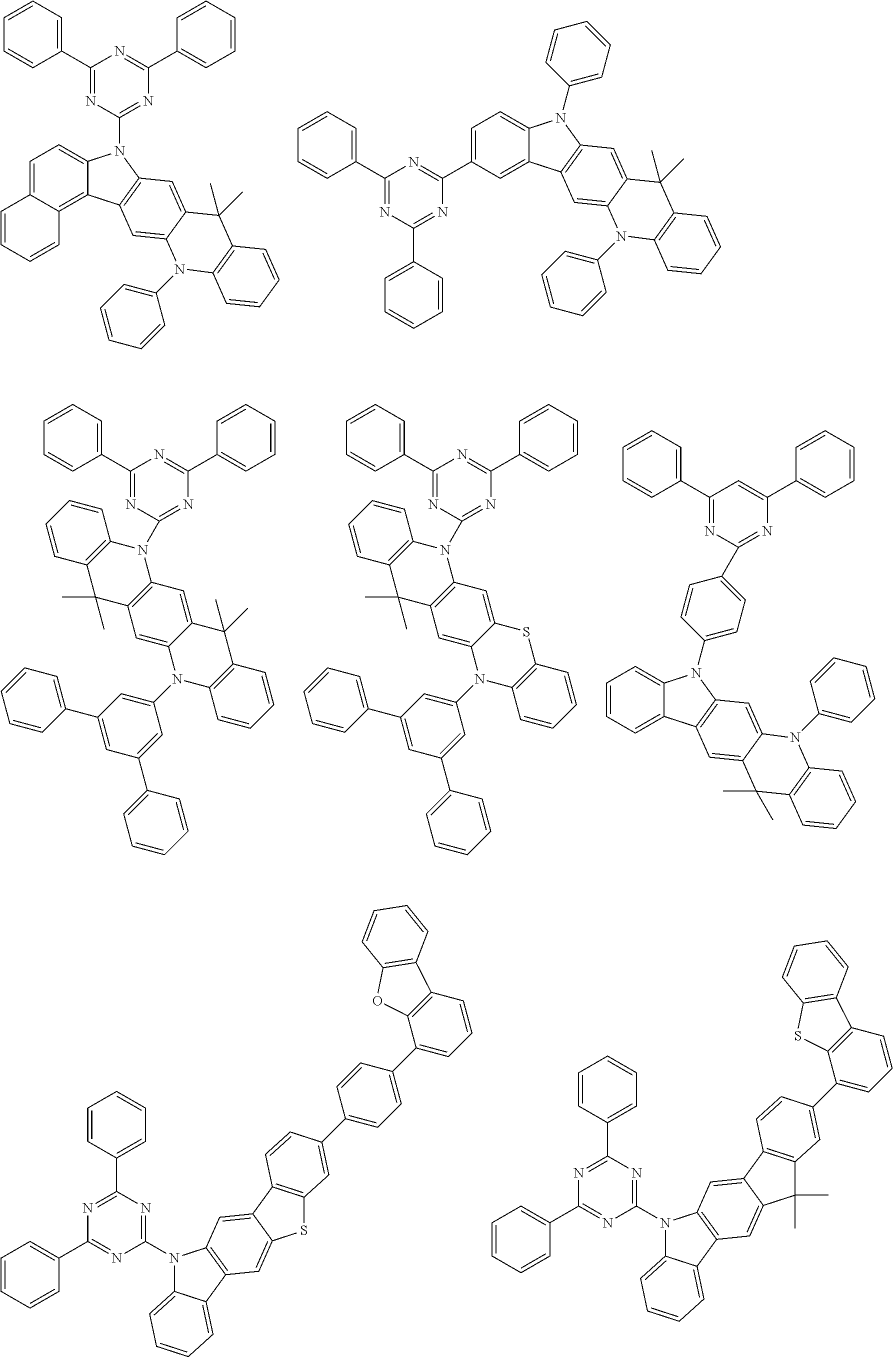

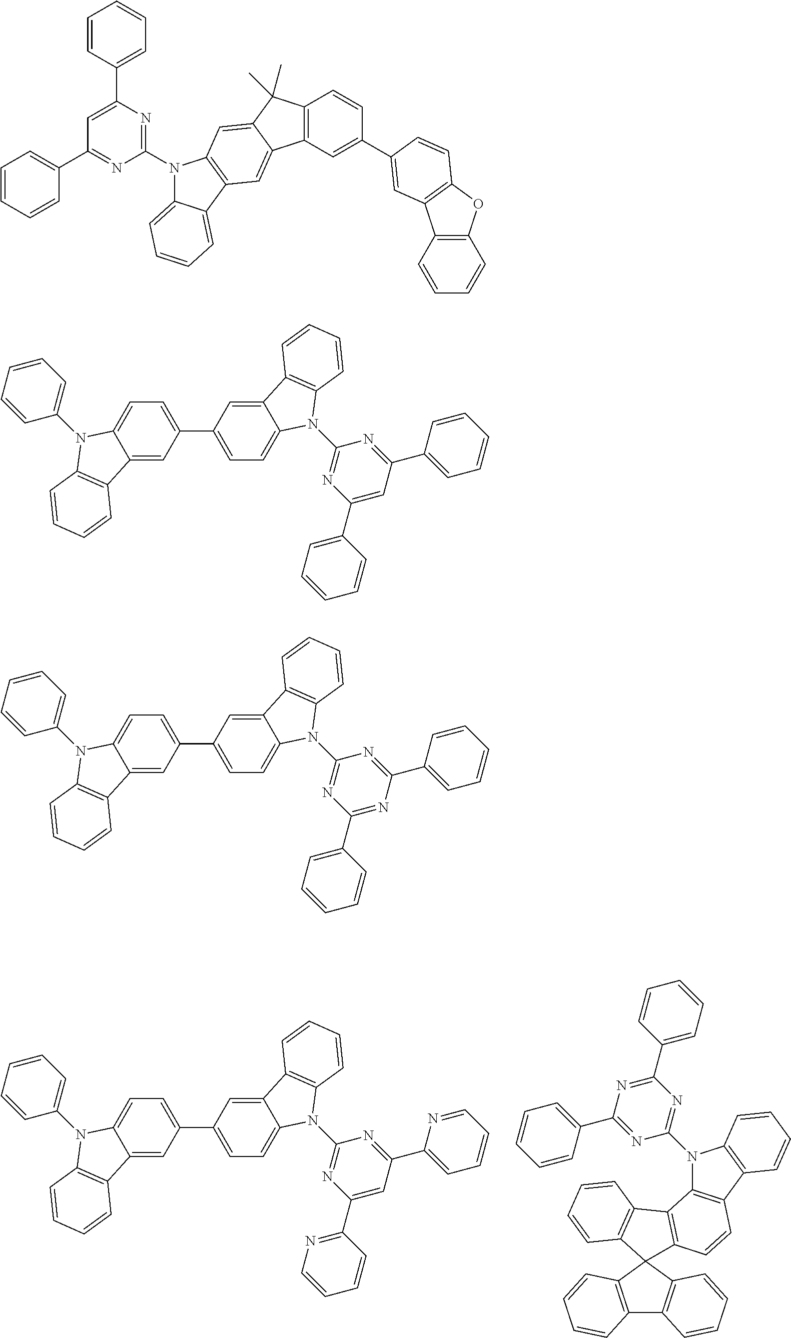

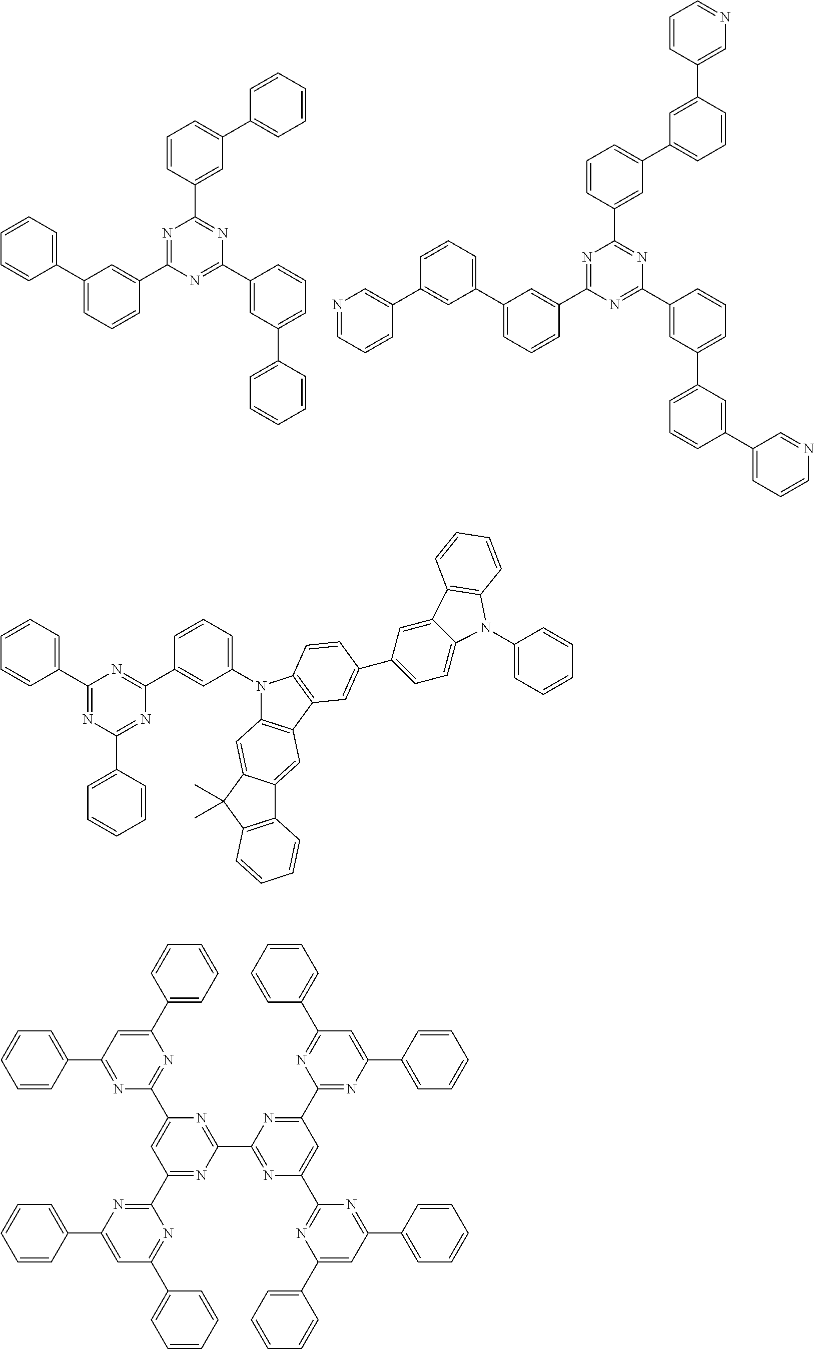

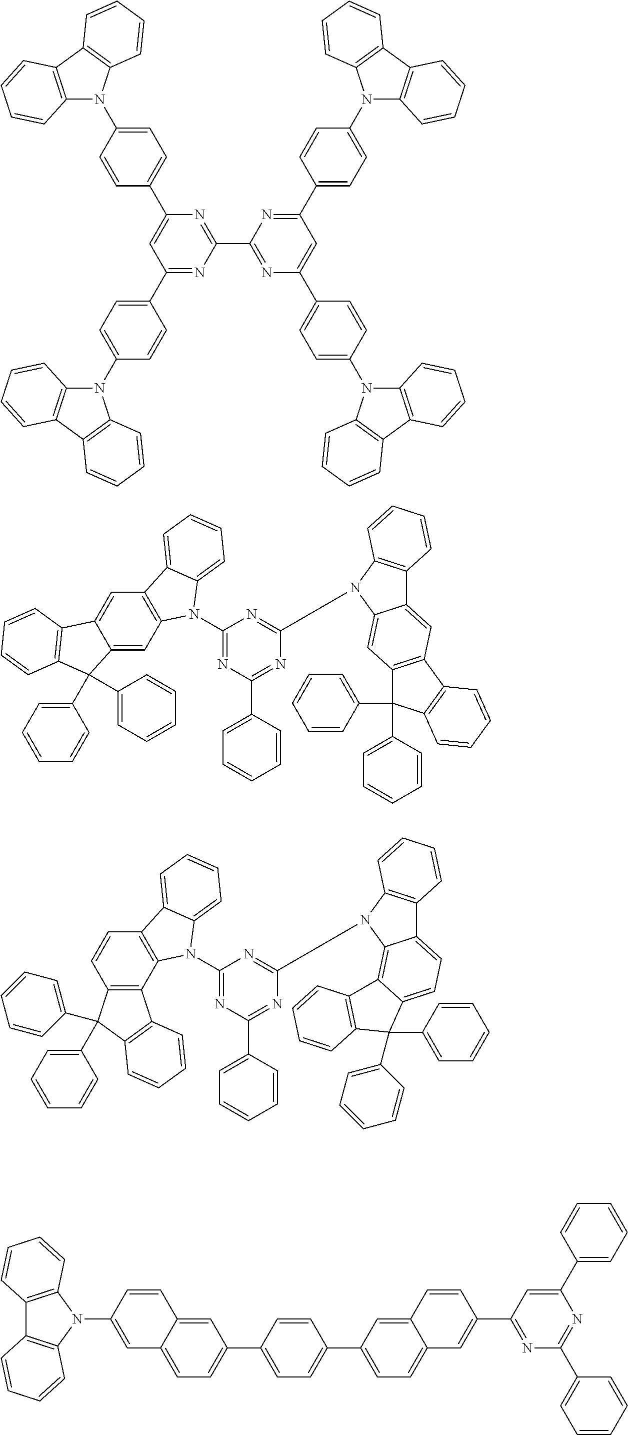

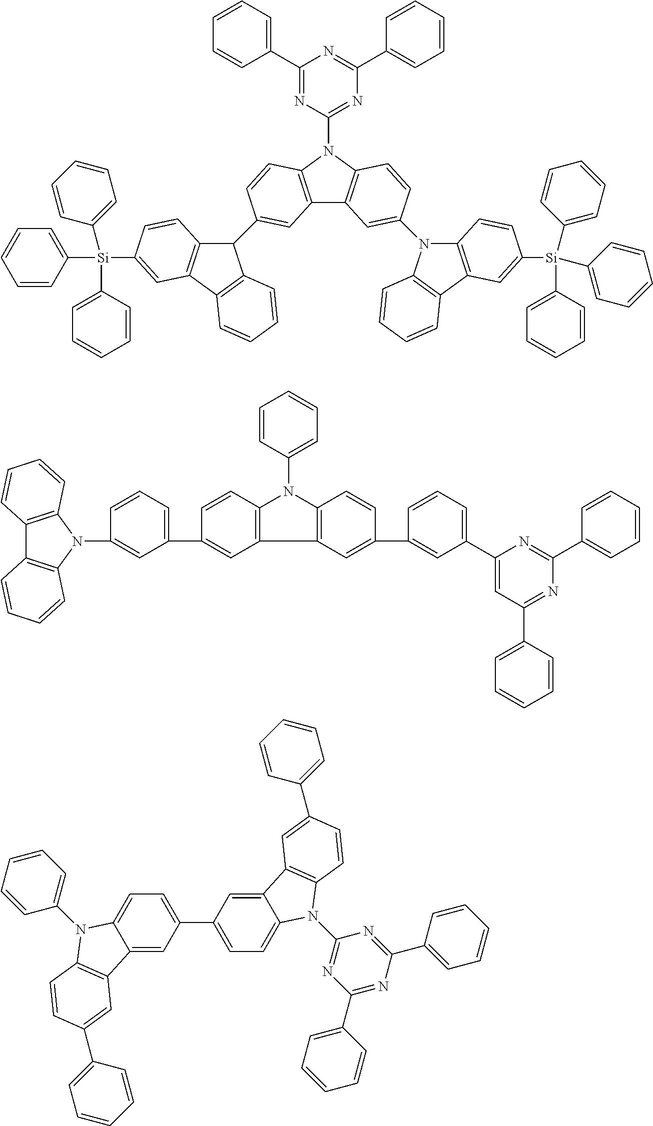 [SMILES: c1ccc(-c2nc(-c3ccccc3)nc(-n3c4ccc(C5c6ccccc6-c6cc([Si](c7ccccc7)(c7ccccc7)c7ccccc7)ccc65)cc4c4cc(-n5c6ccccc6c6cc([Si](c7ccccc7)(c7ccccc7)c7ccccc7)ccc65)ccc43)n2)cc1 ; c1ccc(-c2cc(-c3cccc(-c4ccc5c(c4)c4cc(-c6cccc(-n7c8ccccc8c8ccccc87)c6)ccc4n5-c4ccccc4)c3)nc(-c3ccccc3)n2)cc1 ; c1ccc(-c2ccc3c(c2)c2cc(-c4ccc5c(c4)c4cc(-c6ccccc6)ccc4n5-c4nc(-c5ccccc5)nc(-c5ccccc5)n4)ccc2n3-c2ccccc2)cc1]

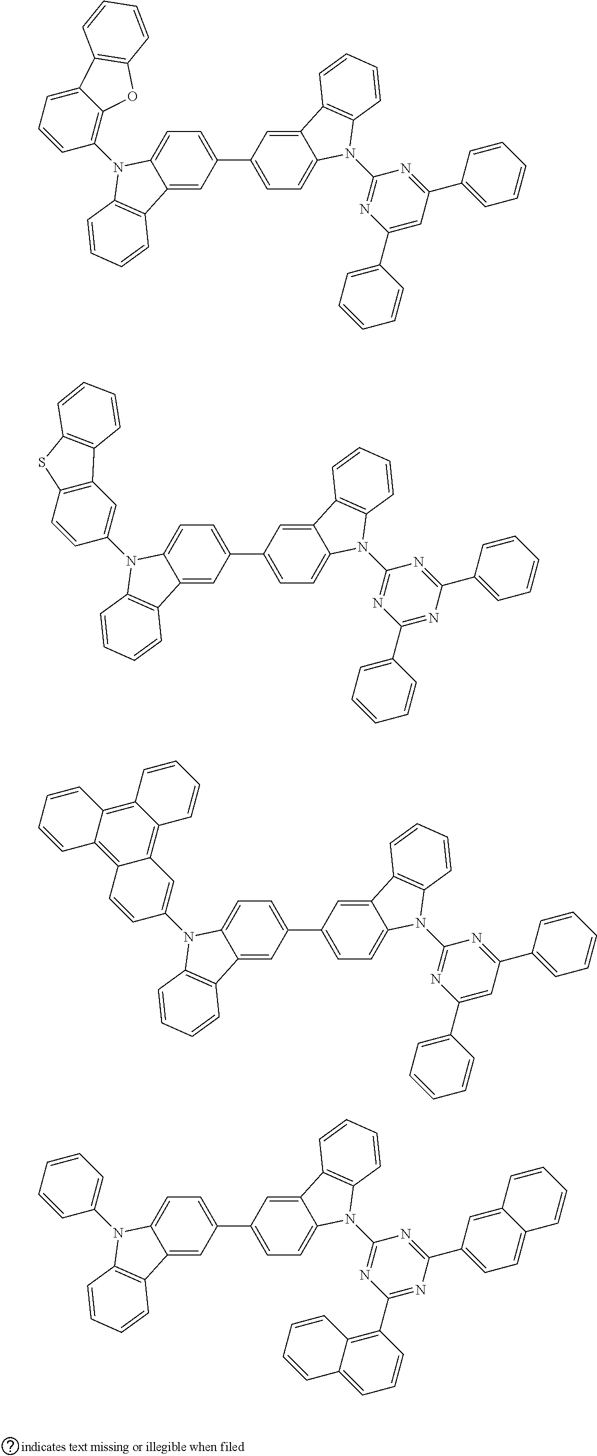 [SMILES: c1ccc(-c2cc(-c3ccccc3)nc(-n3c4ccccc4c4cc(-c5ccc6c(c5)c5ccccc5n6-c5cccc6c5oc5ccccc56)ccc43)n2)cc1 ; c1ccc(-c2nc(-c3ccccc3)nc(-n3c4ccccc4c4cc(-c5ccc6c(c5)c5ccccc5n6-c5ccc6sc7ccccc7c6c5)ccc43)n2)cc1 ; c1ccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)cc1 ; c1ccc(-n2c3ccccc3c3cc(-c4ccc5c(c4)c4ccccc4n5-c4nc(-c5ccc6ccccc6c5)nc(-c5cccc6ccccc56)n4)ccc32)cc1]

If the electron-conducting compound is a lactam, this compound is then preferably selected from the compounds of the following formulae (45) and (46),

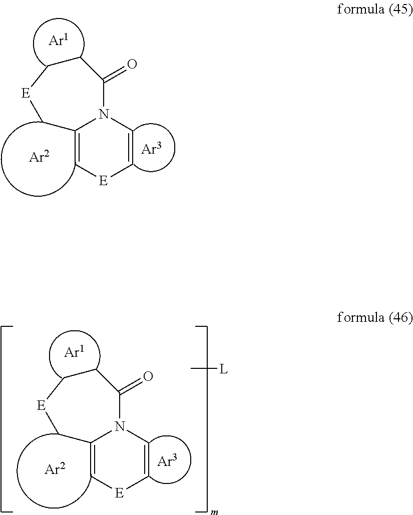

where R, R¹, R² and Ar have the above-mentioned meanings, and the following applies to the other symbols and indices used:
E is, identically or differently on each occurrence, a single bond, NR, CR₂, O, S, SiR₂, BR, PR or P(O)R;
Ar¹, Ar², Ar³ are, identically or differently on each occurrence, together with the carbon atoms explicitly depicted, an aromatic or heteroaromatic ring system having 5 to 30 aromatic ring atoms, which may be substituted by one or more radicals R;
L is for m=2 a single bond or a divalent group, or for m=3 a trivalent group or for m=4 a tetravalent group, which is in each case bonded to Ar¹, Ar² or Ar³ at any desired position or is bonded to E in place of a radical R;
m is 2, 3 or 4.

In a preferred embodiment of the compound of the formula (45) or (46), the group Ar¹ stands for a group of the following formula (47), (48), (49) or (50),

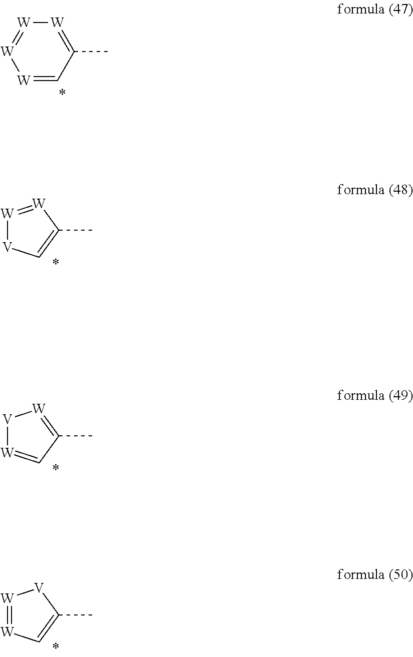

where the dashed bond indicates the link to the carbonyl group, * indicates the position of the link to E or Ar², and furthermore:
W is, identically or differently on each occurrence, CR or N; or two adjacent groups W stand for a group of the following formula (51) or (52),

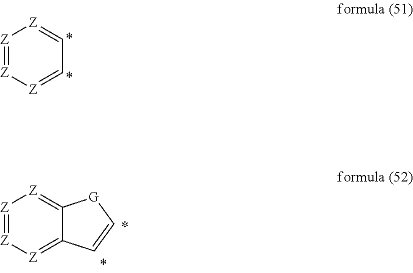

where G stands for CR₂, NR, O or S, Z stands, identically or differently on each occurrence, for CR or N, and ̂ indicate the corresponding adjacent groups W in the formulae (47) to (50);
V is NR, O or S.

In a further preferred embodiment of the invention, the group Ar² stands for a group of one of the following formulae (53), (54) and (55),

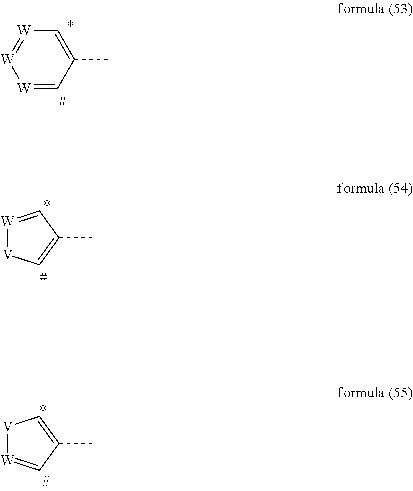

where the dashed bond indicates the link to N, # indicates the position of the link to E or Ar³, * indicates the link to E or Ar¹, and W and V have the above-mentioned meanings.

In a further preferred embodiment of the invention, the group Ar³ stands for a group of one of the following formulae (56), (57), (58) and (59),

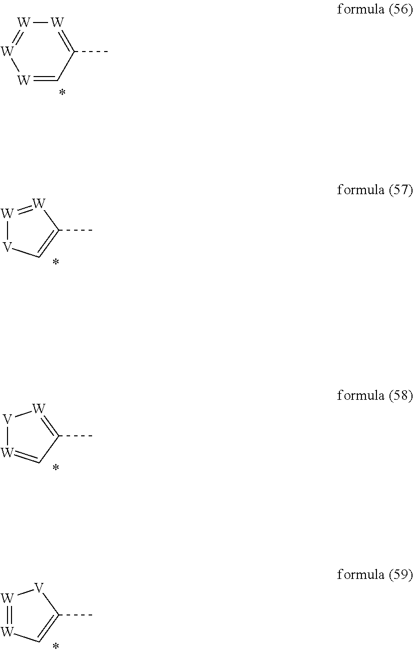

where the dashed bond indicates the link to N, * indicates the link to E or Ar², and W and V have the above-mentioned meanings.

The above-mentioned preferred groups Ar¹, Ar² and Ar³ can be combined with one another as desired here.

In a further preferred embodiment of the invention, at least one group E stands for a single bond.

In a preferred embodiment of the invention, the above-mentioned preferences occur simultaneously. Particular preference is therefore given to compounds of the formulae (45) and (46) for which:
Ar¹ is selected from the groups of the above-mentioned formulae (47), (48), (49) and (50);
Ar² is selected from the groups of the above-mentioned formulae (53), (54) and (55);
Ar³ is selected from the groups of the above-mentioned formulae (56), (57), (58) and (59).

Particularly preferably, at least two of the groups Ar¹, Ar² and Ar³ stand for a 6-membered aryl or 6-membered heteroaryl ring group. Particularly preferably, Ar¹ thus stands for a group of the formula (47) and at the same time Ar² stands for a group of the formula (53), or Ar¹ stands for a group of the formula (47) and at the same time Ar³ stands for a group of the formula (56), or Ar² stands for a group of the formula (53) and at the same time Ar³ stands for a group of the formula (59).

Particularly preferred embodiments of the formula (45) are therefore the compounds of the following formulae (60) to (69),

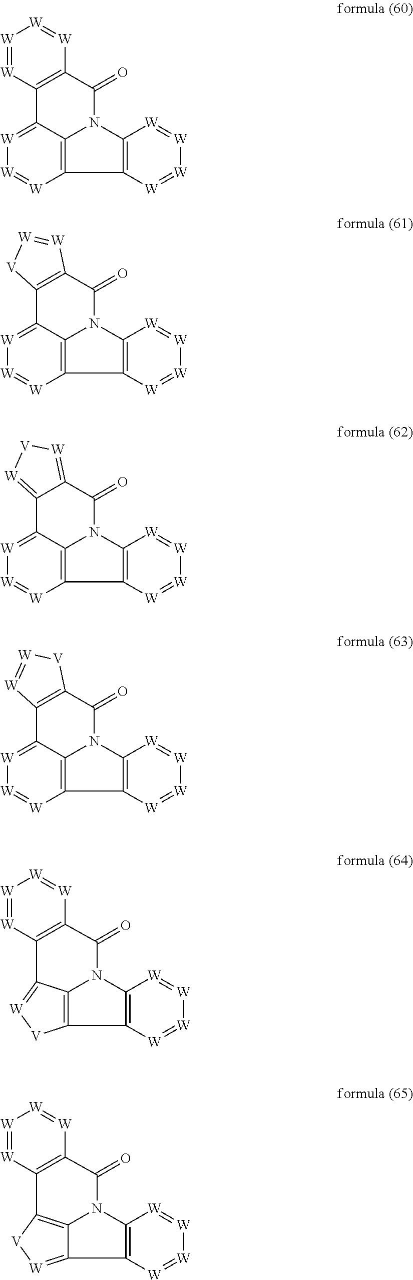

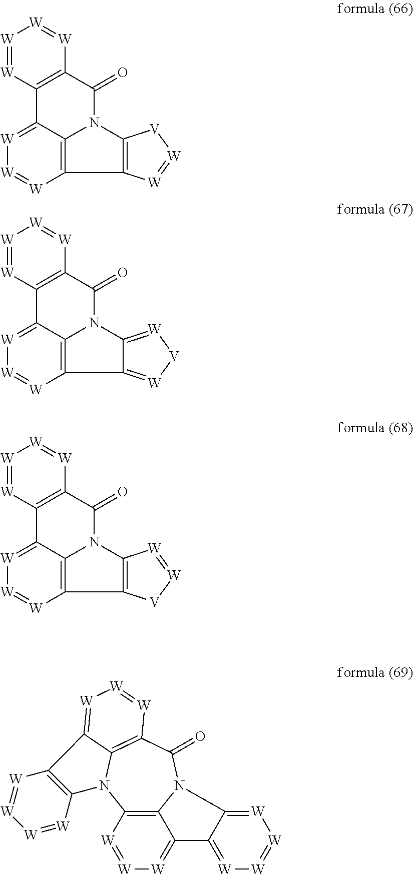

where the symbols used have the above-mentioned meanings.

It is furthermore preferred for W to stand for CR or N and not for a group of the formula (51) or (52). In a preferred embodiment of the compounds of the formulae (60) to (69), in total a maximum of one symbol W per ring stands for N, and the remaining symbols W stand for CR. In a particularly preferred embodiment of the invention, all symbols W stand for CR. Particular preference is therefore given to the compounds of the following formulae (60a) to (69a),

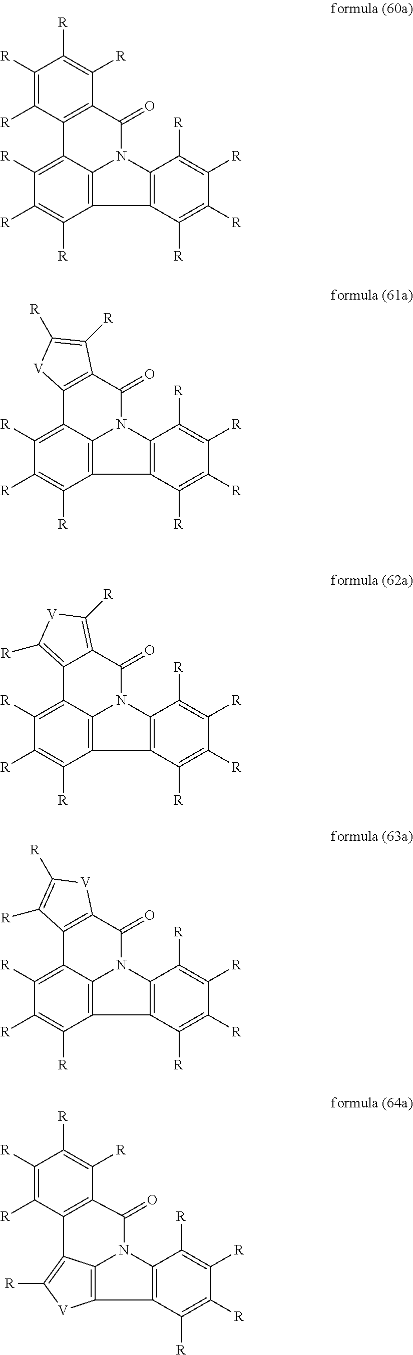

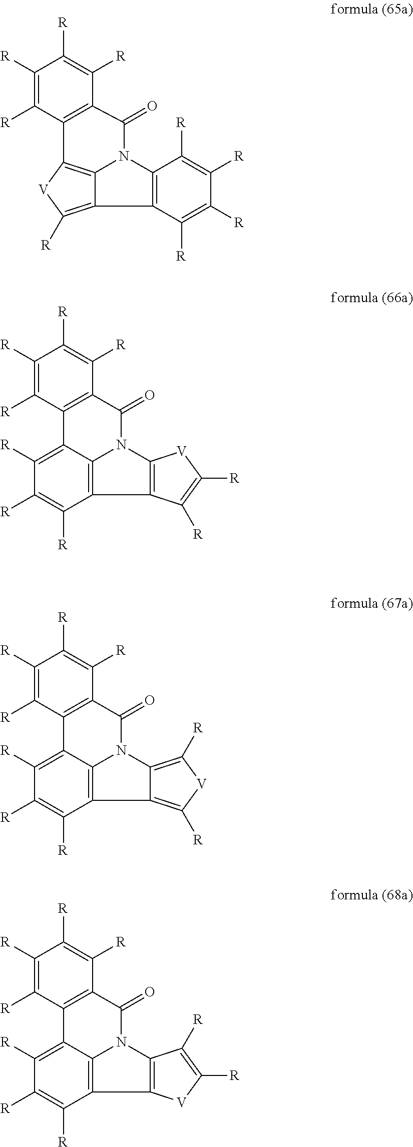

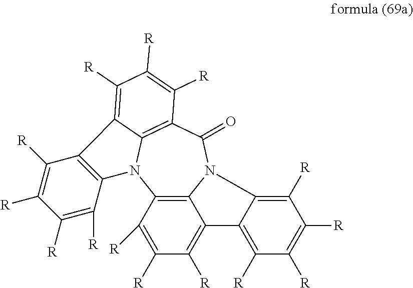

where the symbols used have the above-mentioned meanings.

Very particular preference is given to the structures of the formulae (60b) to (69b),

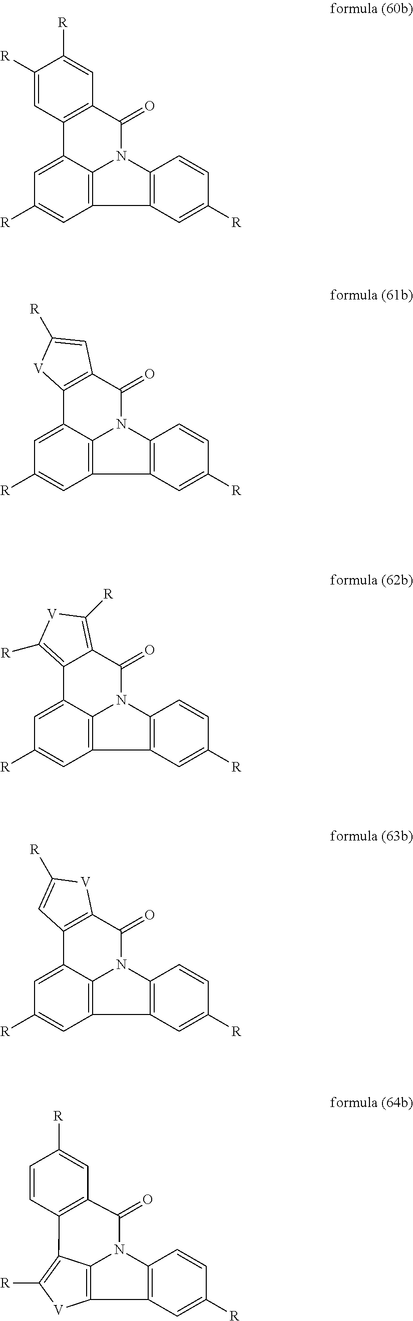

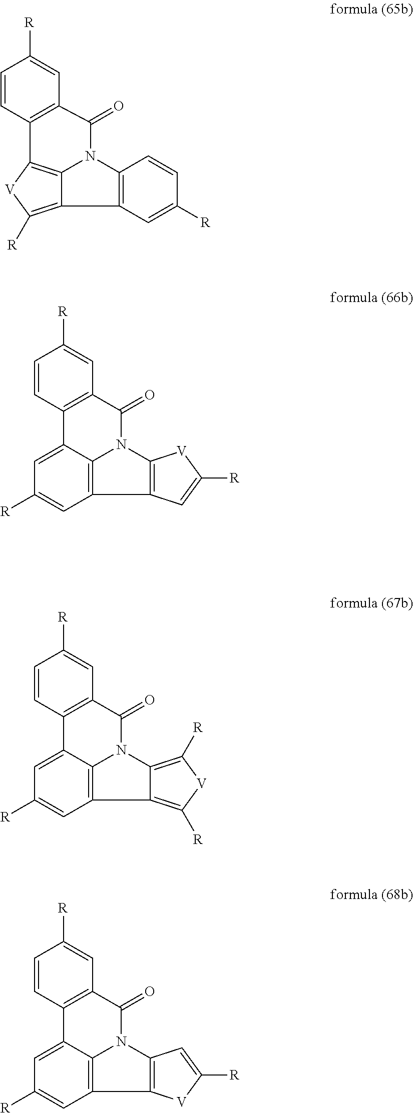

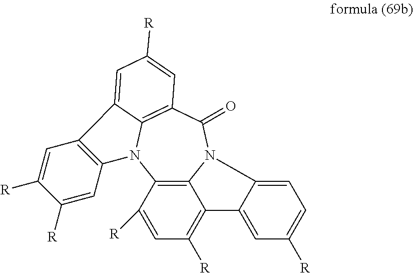

where the symbols used have the above-mentioned meanings.

Very particular preference is given to the compounds of the formulae (60) and (60a) and (60b).

The bridging group L in the compounds of the formula (46a) is preferably selected from a single bond or an aromatic or heteroaromatic ring system having 5 to 30 aromatic ring atoms, which may be substituted by one or more radicals R. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another.

In a further preferred embodiment of the invention, the index m in compounds of the formula (46)=2 or 3, in particular equals 2. Very particular preference is given to compounds of the formula (1).

In a preferred embodiment of the invention, R in the formulae (45) and (46) and the preferred embodiments is selected, identically or differently on each occurrence, from the group consisting of H, D, F, Cl, Br, CN, N(Ar)₂, C(═O)Ar, a straight-chain alkyl or alkoxy group having 1 to 10 C atoms or a branched or cyclic alkyl or alkoxy group having 3 to 10 C atoms or an alkenyl group having 2 to 10 C atoms, each of which may be substituted by one or more radicals R¹, where one or more non-adjacent CH₂ groups may be replaced by O and where one or more H atoms may be replaced by D or F, an aromatic or heteroaromatic ring system having 5 to 30 aromatic ring atoms, which may in each case be substituted by one or more radicals R¹, an aryloxy or heteroaryloxy group having 5 to 30 aromatic ring atoms, which may be substituted by one or more radicals R¹, or a combination of these systems.

In a particularly preferred embodiment of the invention, R in the above-mentioned formulae is selected, identically or differently on each occurrence, from the group consisting of H, D, F, Cl, Br, ON, a straight-chain alkyl group having 1 to 10 C atoms or a branched or cyclic alkyl group having 3 to 10 C atoms, each of which may be substituted by one or more radicals R¹, where one or more H atoms may be replaced by D or F, an aromatic or heteroaromatic ring system having 5 to 18 aromatic ring atoms, which may in each case be substituted by one or more radicals R¹, or a combination of these systems.

The radicals R, if these contain aromatic or heteroaromatic ring systems, preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. Especial preference is given here to phenyl, biphenyl, terphenyl, quaterphenyl, carbazole, dibenzothiophene, dibenzofuran, indenocarbazole, indolocarbazole, triazine or pyrimidine, each of which may also be substituted by one or more radicals R¹.

For compounds which are processed by vacuum evaporation, the alkyl groups preferably have not more than five C atoms, particularly preferably not more than 4 C atoms, very particularly preferably not more than 1 C atom.

The compounds of the formulae (45) and (46) are known in principle. The synthesis of these compounds can be carried out by the processes described in WO 2011/116865 and WO 2011/137951.

Examples of preferred compounds in accordance with the above-mentioned embodiments are the compounds shown in the following table.

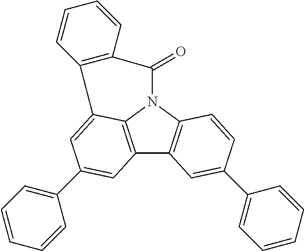 [SMILES: O=c1c2ccccc2c2cc(-c3ccccc3)cc3c4cc(-c5ccccc5)ccc4n1c23]

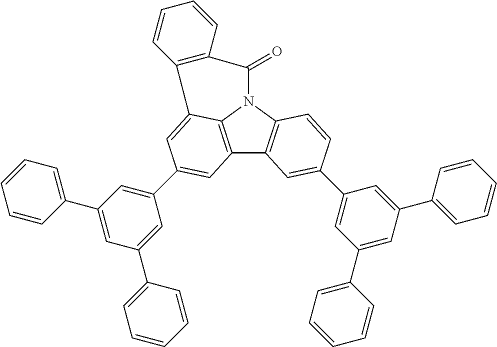 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

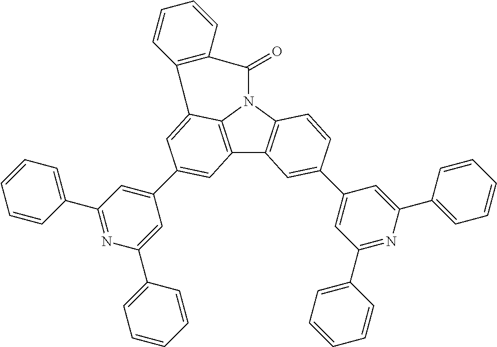 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

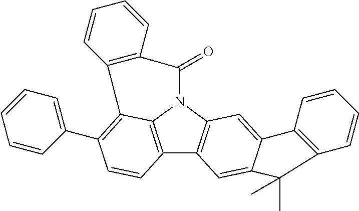 [SMILES: CC1(C)c2ccccc2-c2cc3c(cc21)c1ccc(-c2ccccc2)c2c4ccccc4c(=O)n3c12]

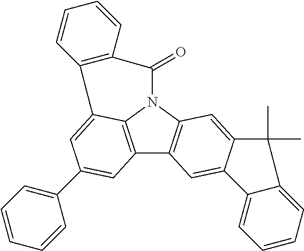 [SMILES: CC1(C)c2ccccc2-c2cc3c4cc(-c5ccccc5)cc5c6ccccc6c(=O)n(c3cc21)c54]

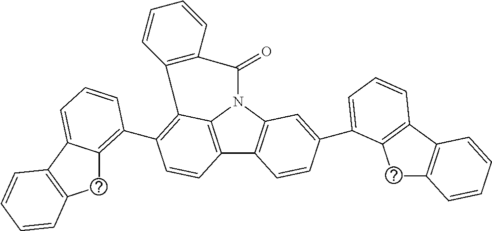 [SMILES: O=c1c2ccccc2c2c(-c3cccc4c3Cc3ccccc3-4)ccc3c4ccc(-c5cccc6c5Cc5ccccc5-6)cc4n1c32]

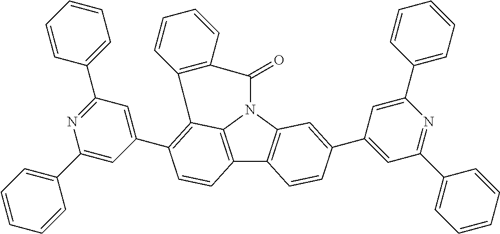 [SMILES: O=c1c2ccccc2c2c(-c3cc(-c4ccccc4)nc(-c4ccccc4)c3)ccc3c4ccc(-c5cc(-c6ccccc6)nc(-c6ccccc6)c5)cc4n1c32]

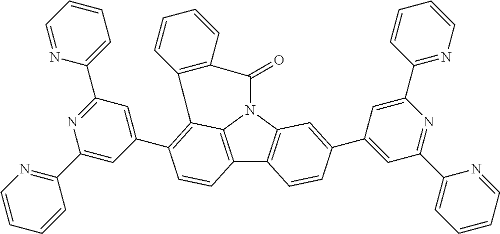 [SMILES: O=c1c2ccccc2c2c(-c3cc(-c4ccccn4)nc(-c4ccccn4)c3)ccc3c4ccc(-c5cc(-c6ccccn6)nc(-c6ccccn6)c5)cc4n1c32]

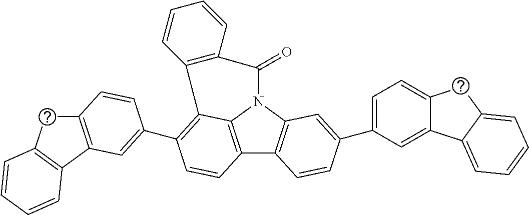 [SMILES: O=c1c2ccccc2c2c(-c3ccc4c(c3)-c3ccccc3C4)ccc3c4ccc(-c5ccc6c(c5)-c5ccccc5C6)cc4n1c32]

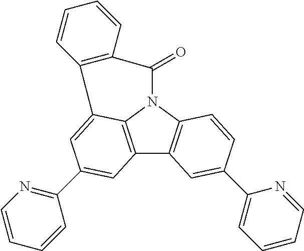 [SMILES: O=c1c2ccccc2c2cc(-c3ccccn3)cc3c4cc(-c5ccccn5)ccc4n1c23]

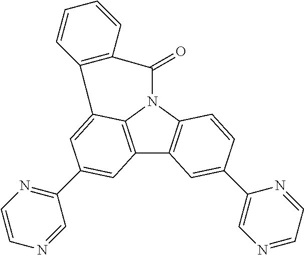 [SMILES: O=c1c2ccccc2c2cc(-c3cnccn3)cc3c4cc(-c5cnccn5)ccc4n1c23]

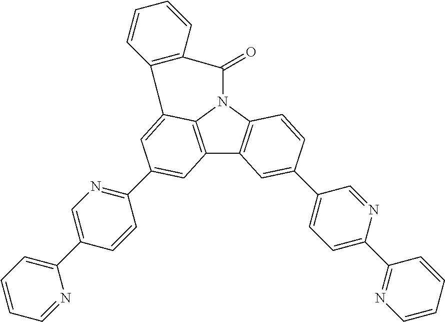 [SMILES: O=c1c2ccccc2c2cc(-c3ccc(-c4ccccn4)cn3)cc3c4cc(-c5ccc(-c6ccccn6)nc5)ccc4n1c23]

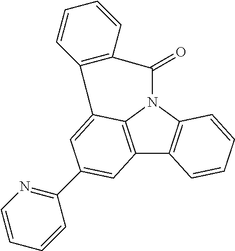 [SMILES: O=c1c2ccccc2c2cc(-c3ccccn3)cc3c4ccccc4n1c23]

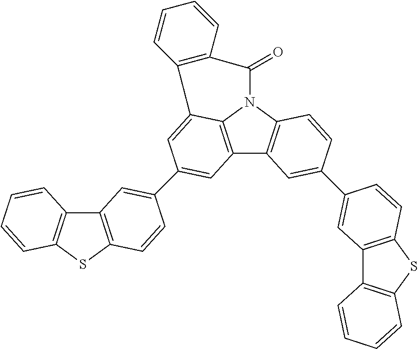 [SMILES: O=c1c2ccccc2c2cc(-c3ccc4sc5ccccc5c4c3)cc3c4cc(-c5ccc6sc7ccccc7c6c5)ccc4n1c23]

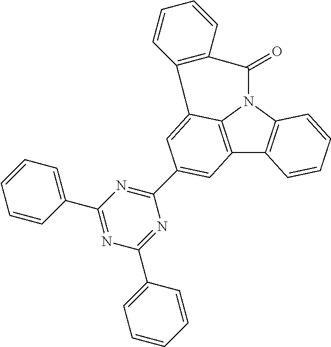 [SMILES: O=c1c2ccccc2c2cc(-c3nc(-c4ccccc4)nc(-c4ccccc4)n3)cc3c4ccccc4n1c23]

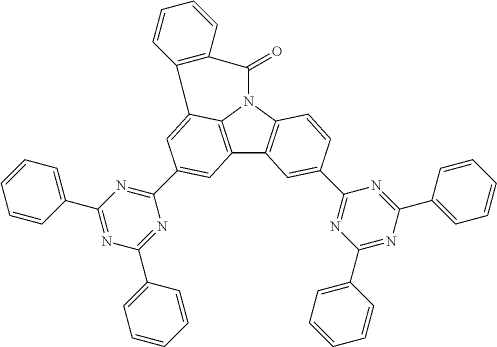 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

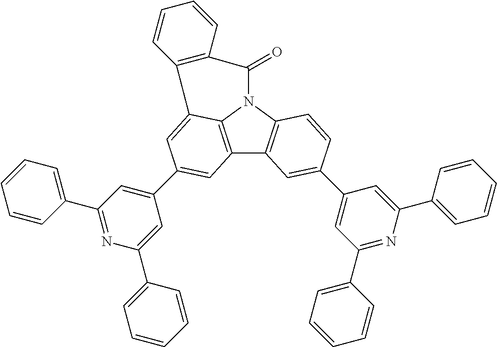 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

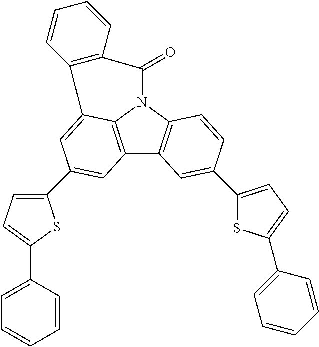 [SMILES: O=c1c2ccccc2c2cc(-c3ccc(-c4ccccc4)s3)cc3c4cc(-c5ccc(-c6ccccc6)s5)ccc4n1c23]

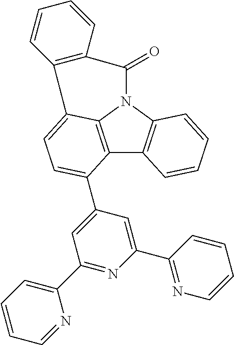 [SMILES: O=c1c2ccccc2c2ccc(-c3cc(-c4ccccn4)nc(-c4ccccn4)c3)c3c4ccccc4n1c23]

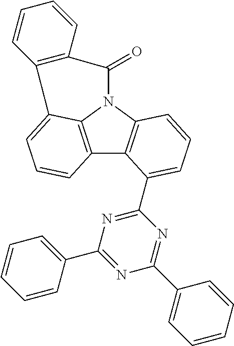 [SMILES: O=c1c2ccccc2c2cccc3c4c(-c5nc(-c6ccccc6)nc(-c6ccccc6)n5)cccc4n1c23]

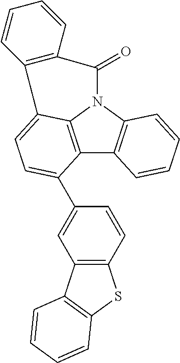 [SMILES: O=c1c2ccccc2c2ccc(-c3ccc4sc5ccccc5c4c3)c3c4ccccc4n1c23]

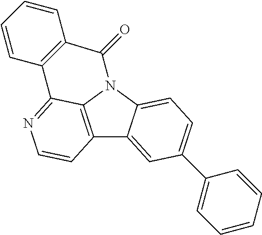 [SMILES: O=c1c2ccccc2c2nccc3c4cc(-c5ccccc5)ccc4n1c32]

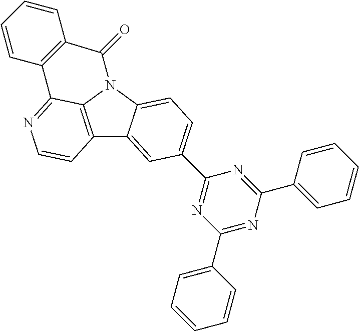 [SMILES: O=c1c2ccccc2c2nccc3c4cc(-c5nc(-c6ccccc6)nc(-c6ccccc6)n5)ccc4n1c32]

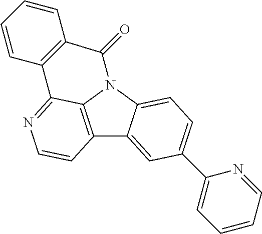 [SMILES: O=c1c2ccccc2c2nccc3c4cc(-c5ccccn5)ccc4n1c32]

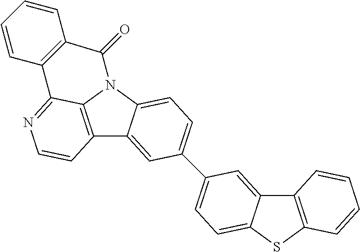 [SMILES: O=c1c2ccccc2c2nccc3c4cc(-c5ccc6sc7ccccc7c6c5)ccc4n1c32]

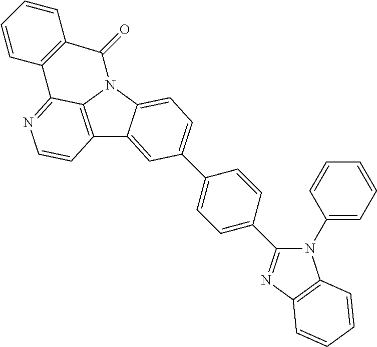 [SMILES: O=c1c2ccccc2c2nccc3c4cc(-c5ccc(-c6nc7ccccc7n6-c6ccccc6)cc5)ccc4n1c32]

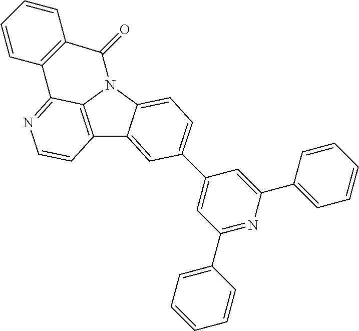 [SMILES: O=c1c2ccccc2c2nccc3c4cc(-c5cc(-c6ccccc6)nc(-c6ccccc6)c5)ccc4n1c32]

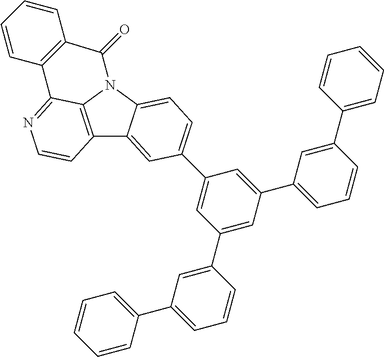 [SMILES: O=c1c2ccccc2c2nccc3c4cc(-c5cc(-c6cccc(-c7ccccc7)c6)cc(-c6cccc(-c7ccccc7)c6)c5)ccc4n1c32]

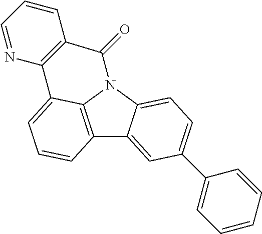 [SMILES: O=c1c2cccnc2c2cccc3c4cc(-c5ccccc5)ccc4n1c32]

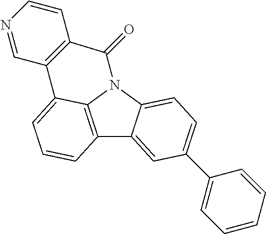 [SMILES: O=c1c2ccncc2c2cccc3c4cc(-c5ccccc5)ccc4n1c23]

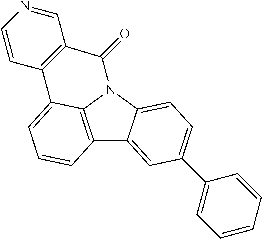 [SMILES: O=c1c2cnccc2c2cccc3c4cc(-c5ccccc5)ccc4n1c23]

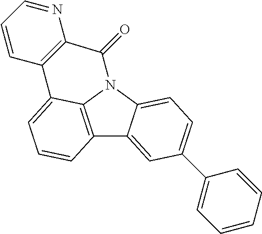 [SMILES: O=c1c2ncccc2c2cccc3c4cc(-c5ccccc5)ccc4n1c23]

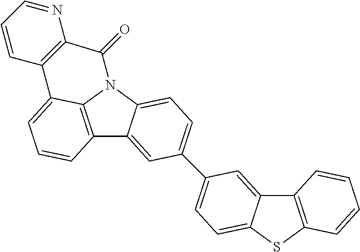 [SMILES: O=c1c2ncccc2c2cccc3c4cc(-c5ccc6sc7ccccc7c6c5)ccc4n1c23]

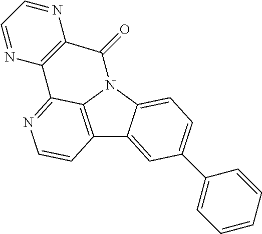 [SMILES: O=c1c2nccnc2c2nccc3c4cc(-c5ccccc5)ccc4n1c32]

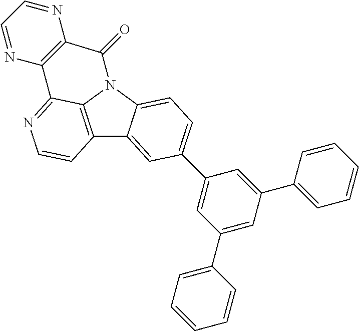 [SMILES: O=c1c2nccnc2c2nccc3c4cc(-c5cc(-c6ccccc6)cc(-c6ccccc6)c5)ccc4n1c32]

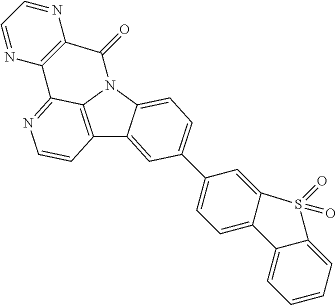 [SMILES: O=c1c2nccnc2c2nccc3c4cc(-c5ccc6c(c5)S(=O)(=O)c5ccccc5-6)ccc4n1c32]

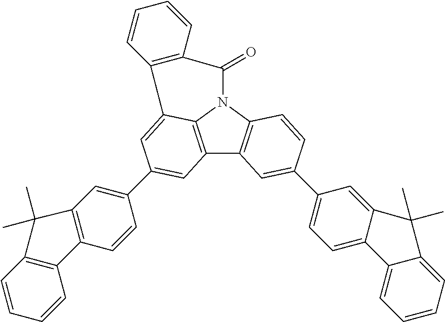 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

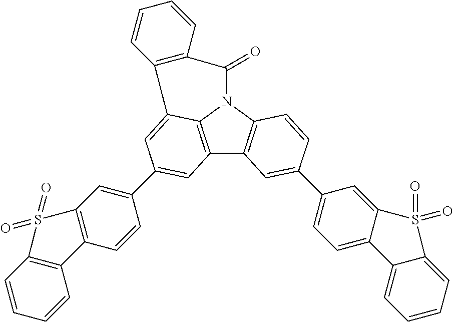 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

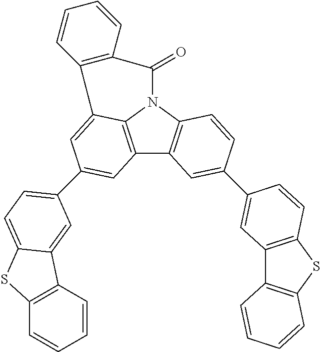 [SMILES: O=c1c2ccccc2c2cc(-c3ccc4sc5ccccc5c4c3)cc3c4cc(-c5ccc6sc7ccccc7c6c5)ccc4n1c23]

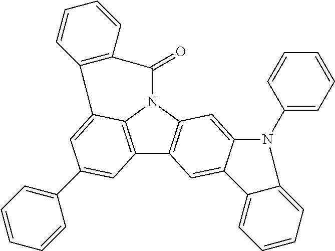 [SMILES: O=c1c2ccccc2c2cc(-c3ccccc3)cc3c4cc5c6ccccc6n(-c6ccccc6)c5cc4n1c23]

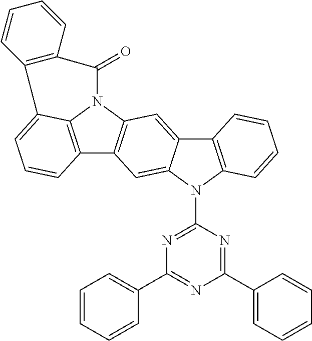 [SMILES: O=c1c2ccccc2c2cccc3c4cc5c(cc4n1c23)c1ccccc1n5-c1nc(-c2ccccc2)nc(-c2ccccc2)n1]

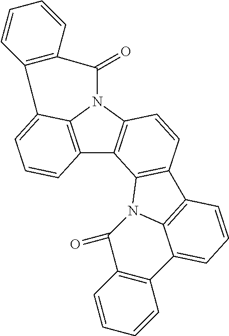 [SMILES: O=c1c2ccccc2c2cccc3c4c(ccc5c6cccc7c8ccccc8c(=O)n(c76)c54)n1c23]

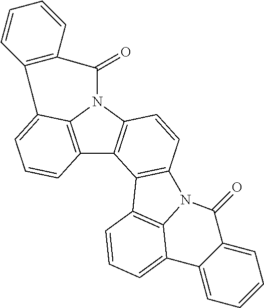 [SMILES: O=c1c2ccccc2c2cccc3c4c5c6cccc7c8ccccc8c(=O)n(c5ccc4n1c23)c76]

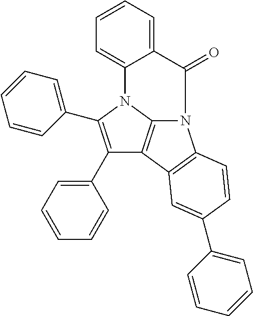 [SMILES: O=c1c2ccccc2n2c(-c3ccccc3)c(-c3ccccc3)c3c4cc(-c5ccccc5)ccc4n1c32]

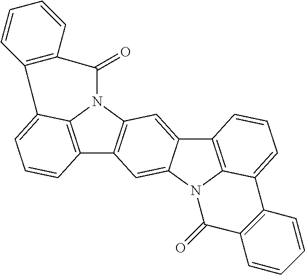 [SMILES: O=c1c2ccccc2c2cccc3c4cc5c(cc4n1c23)c1cccc2c3ccccc3c(=O)n5c21]

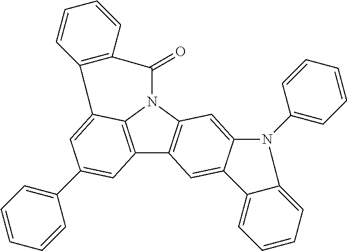 [SMILES: O=c1c2ccccc2c2cc(-c3ccccc3)cc3c4cc5c6ccccc6n(-c6ccccc6)c5cc4n1c23]

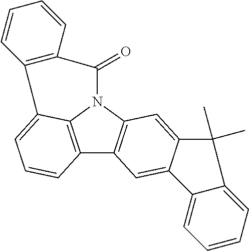 [SMILES: CC1(C)c2ccccc2-c2cc3c4cccc5c6ccccc6c(=O)n(c3cc21)c54]

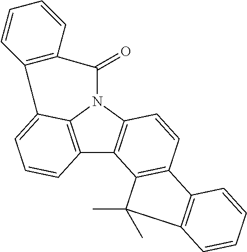 [SMILES: CC1(C)c2ccccc2-c2ccc3c(c21)c1cccc2c4ccccc4c(=O)n3c21]

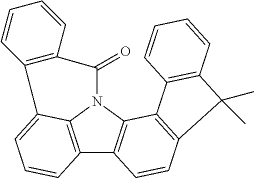 [SMILES: CC1(C)c2ccccc2-c2c1ccc1c3cccc4c5ccccc5c(=O)n(c21)c43]

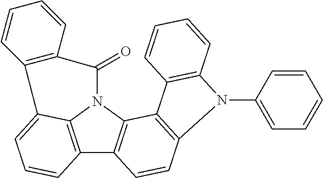 [SMILES: O=c1c2ccccc2c2cccc3c4ccc5c(c6ccccc6n5-c5ccccc5)c4n1c23]

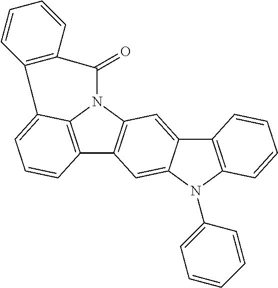 [SMILES: O=c1c2ccccc2c2cccc3c4cc5c(cc4n1c23)c1ccccc1n5-c1ccccc1]

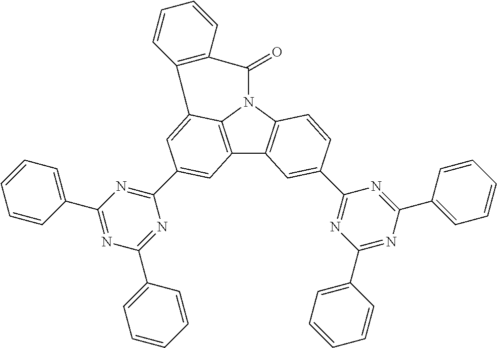 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

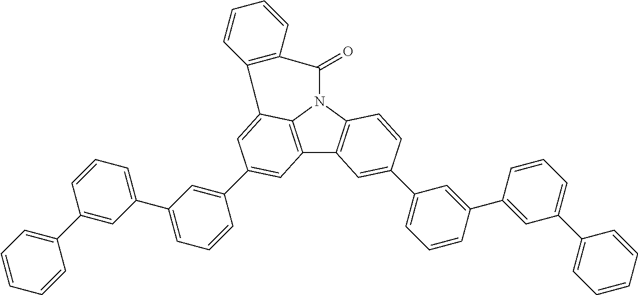 [SMILES: O=c1c2ccccc2c2cc(-c3cccc(-c4cccc(-c5ccccc5)c4)c3)cc3c4cc(-c5cccc(-c6cccc(-c7ccccc7)c6)c5)ccc4n1c23]

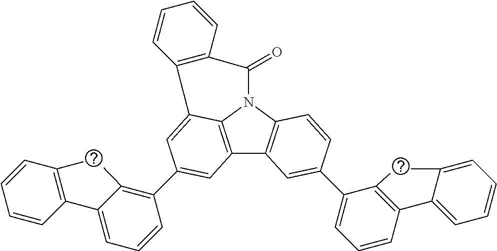 [SMILES: O=c1c2ccccc2c2cc(-c3cccc4c3Cc3ccccc3-4)cc3c4cc(-c5cccc6c5Cc5ccccc5-6)ccc4n1c23]

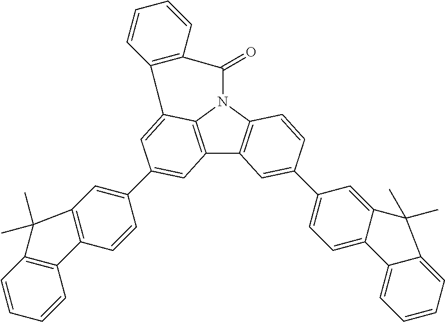 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

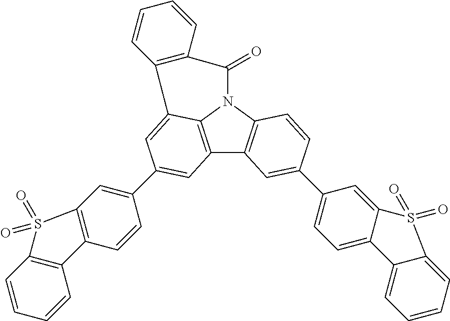 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

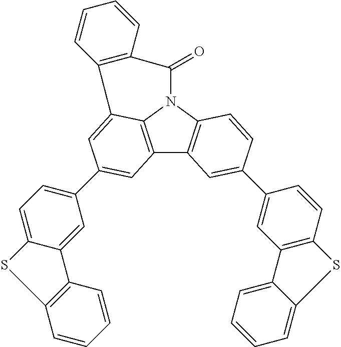 [SMILES: O=c1c2ccccc2c2cc(-c3ccc4sc5ccccc5c4c3)cc3c4cc(-c5ccc6sc7ccccc7c6c5)ccc4n1c23]

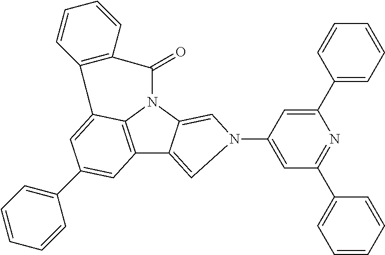 [SMILES: O=c1c2ccccc2c2cc(-c3ccccc3)cc3c4cn(-c5cc(-c6ccccc6)nc(-c6ccccc6)c5)cc4n1c23]

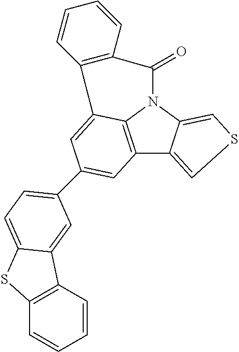 [SMILES: O=c1c2ccccc2c2cc(-c3ccc4sc5ccccc5c4c3)cc3c4cscc4n1c23]

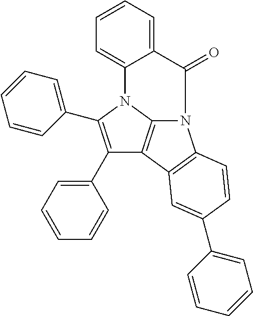 [SMILES: O=c1c2ccccc2n2c(-c3ccccc3)c(-c3ccccc3)c3c4cc(-c5ccccc5)ccc4n1c32]

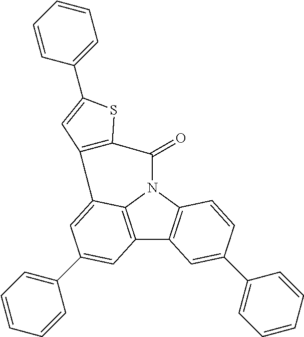 [SMILES: O=c1c2sc(-c3ccccc3)cc2c2cc(-c3ccccc3)cc3c4cc(-c5ccccc5)ccc4n1c23]

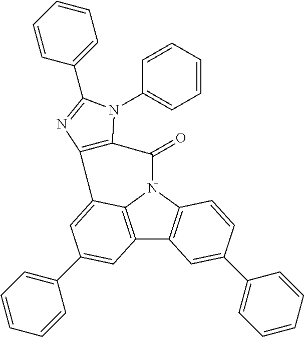 [SMILES: O=c1c2c(nc(-c3ccccc3)n2-c2ccccc2)c2cc(-c3ccccc3)cc3c4cc(-c5ccccc5)ccc4n1c32]

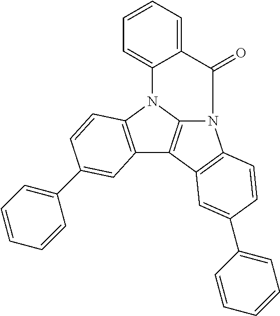 [SMILES: O=c1c2ccccc2n2c3ccc(-c4ccccc4)cc3c3c4cc(-c5ccccc5)ccc4n1c32]

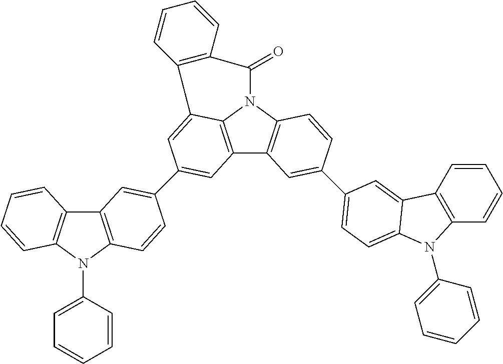 [SMILES: O=c1c2ccccc2c2cc(-c3ccc4c(c3)c3ccccc3n4-c3ccccc3)cc3c4cc(-c5ccc6c(c5)c5ccccc5n6-c5ccccc5)ccc4n1c23]

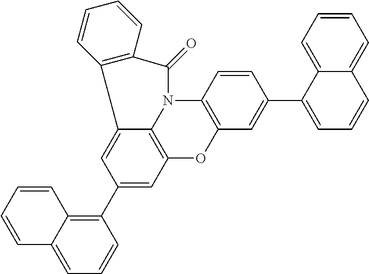 [SMILES: O=c1c2ccccc2c2cc(-c3cccc4ccccc34)cc3c2n1-c1ccc(-c2cccc4ccccc24)cc1O3]

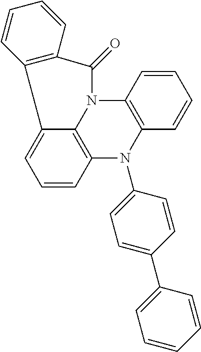 [SMILES: O=c1c2ccccc2c2cccc3c2n1-c1ccccc1N3c1ccc(-c2ccccc2)cc1]

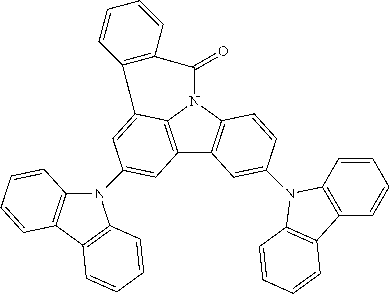 [SMILES: O=c1c2ccccc2c2cc(-n3c4ccccc4c4ccccc43)cc3c4cc(-n5c6ccccc6c6ccccc65)ccc4n1c23]

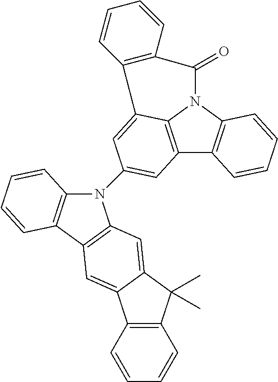 [SMILES: CC1(C)c2ccccc2-c2cc3c4ccccc4n(-c4cc5c6ccccc6c(=O)n6c7ccccc7c(c4)c56)c3cc21]

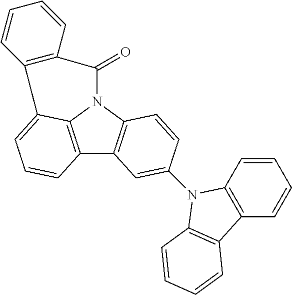 [SMILES: O=c1c2ccccc2c2cccc3c4cc(-n5c6ccccc6c6ccccc65)ccc4n1c23]

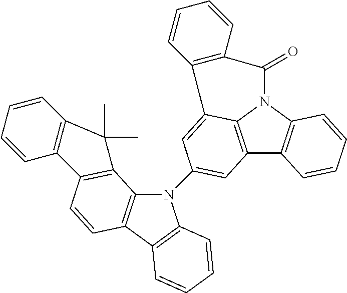 [SMILES: CC1(C)c2ccccc2-c2ccc3c4ccccc4n(-c4cc5c6ccccc6c(=O)n6c7ccccc7c(c4)c56)c3c21]

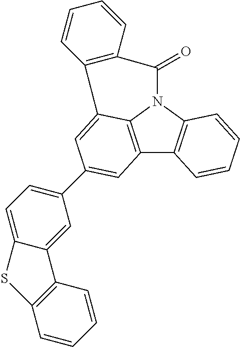 [SMILES: O=c1c2ccccc2c2cc(-c3ccc4sc5ccccc5c4c3)cc3c4ccccc4n1c23]

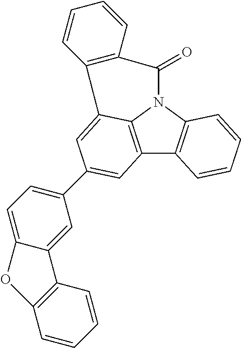 [SMILES: O=c1c2ccccc2c2cc(-c3ccc4oc5ccccc5c4c3)cc3c4ccccc4n1c23]

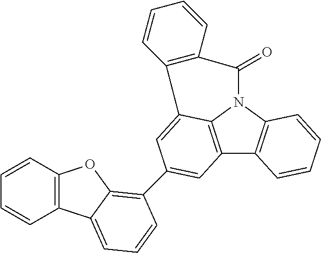 [SMILES: O=c1c2ccccc2c2cc(-c3cccc4c3oc3ccccc34)cc3c4ccccc4n1c23]

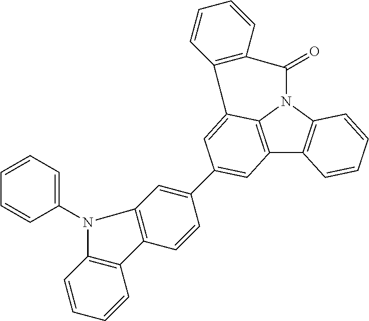 [SMILES: O=c1c2ccccc2c2cc(-c3ccc4c5ccccc5n(-c5ccccc5)c4c3)cc3c4ccccc4n1c23]

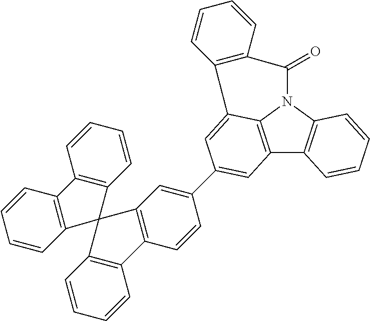 [SMILES: O=c1c2ccccc2c2cc(-c3ccc4c(c3)C3(c5ccccc5-c5ccccc53)c3ccccc3-4)cc3c4ccccc4n1c23]

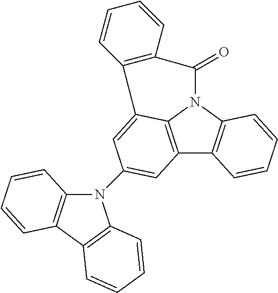 [SMILES: O=c1c2ccccc2c2cc(-n3c4ccccc4c4ccccc43)cc3c4ccccc4n1c23]

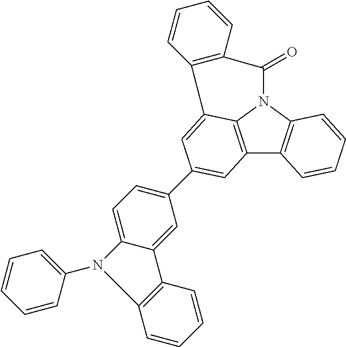 [SMILES: O=c1c2ccccc2c2cc(-c3ccc4c(c3)c3ccccc3n4-c3ccccc3)cc3c4ccccc4n1c23]

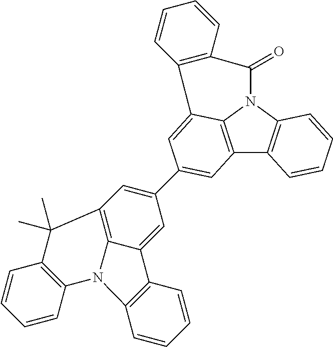 [SMILES: CC1(C)c2ccccc2-n2c3ccccc3c3cc(-c4cc5c6ccccc6c(=O)n6c7ccccc7c(c4)c56)cc1c32]

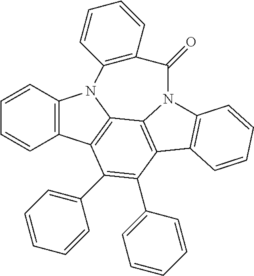 [SMILES: O=c1c2ccccc2n2c3ccccc3c3c(-c4ccccc4)c(-c4ccccc4)c4c5ccccc5n1c4c32]

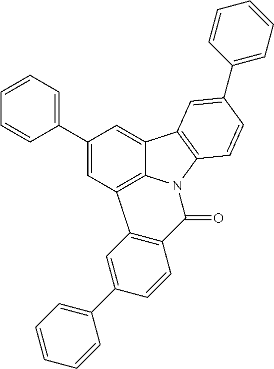 [SMILES: O=c1c2ccc(-c3ccccc3)cc2c2cc(-c3ccccc3)cc3c4cc(-c5ccccc5)ccc4n1c23]

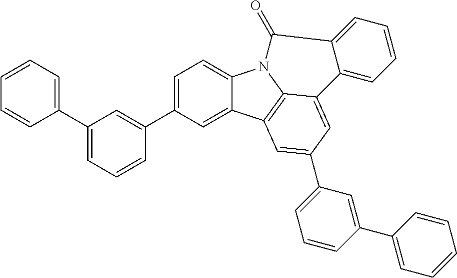 [SMILES: O=c1c2ccccc2c2cc(-c3cccc(-c4ccccc4)c3)cc3c4cc(-c5cccc(-c6ccccc6)c5)ccc4n1c23]

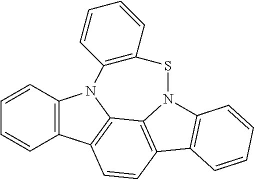 [SMILES: c1ccc2c(c1)sn1c3ccccc3c3ccc4c5ccccc5n2c4c31]

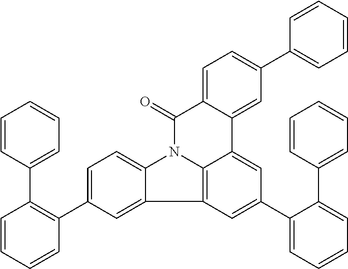 [SMILES: O=c1c2ccc(-c3ccccc3)cc2c2cc(-c3ccccc3-c3ccccc3)cc3c4cc(-c5ccccc5-c5ccccc5)ccc4n1c23]

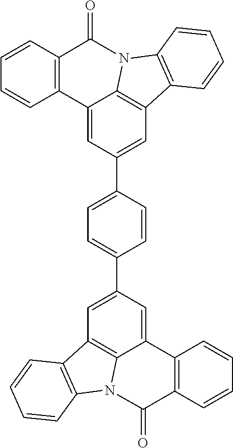 [SMILES: O=c1c2ccccc2c2cc(-c3ccc(-c4cc5c6ccccc6c(=O)n6c7ccccc7c(c4)c56)cc3)cc3c4ccccc4n1c23]

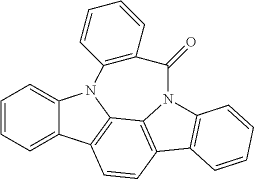 [SMILES: O=c1c2ccccc2n2c3ccccc3c3ccc4c5ccccc5n1c4c32]

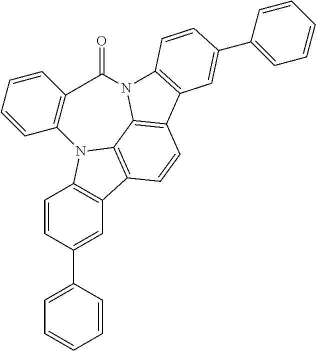 [SMILES: O=c1c2ccccc2n2c3ccc(-c4ccccc4)cc3c3ccc4c5cc(-c6ccccc6)ccc5n1c4c32]

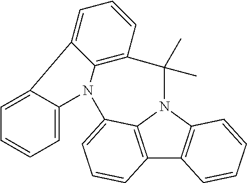 [SMILES: CC1(C)c2cccc3c4ccccc4n(c23)-c2cccc3c4ccccc4n1c23]

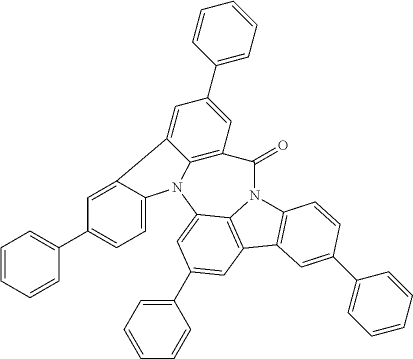 [SMILES: O=c1c2cc(-c3ccccc3)cc3c4cc(-c5ccccc5)ccc4n(c4cc(-c5ccccc5)cc5c6cc(-c7ccccc7)ccc6n1c54)c23]

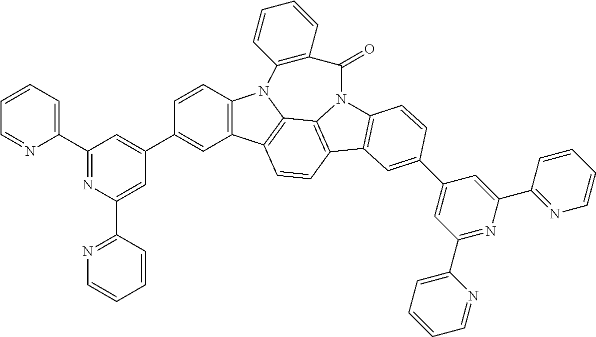 [SMILES: O=c1c2ccccc2n2c3ccc(-c4cc(-c5ccccn5)nc(-c5ccccn5)c4)cc3c3ccc4c5cc(-c6cc(-c7ccccn7)nc(-c7ccccn7)c6)ccc5n1c4c32]

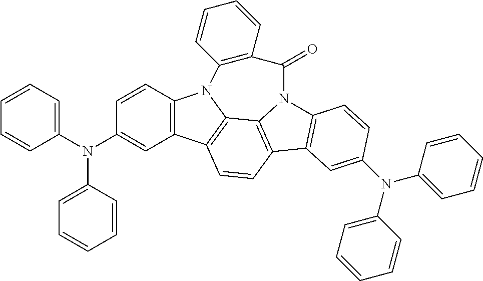 [SMILES: O=c1c2ccccc2n2c3ccc(N(c4ccccc4)c4ccccc4)cc3c3ccc4c5cc(N(c6ccccc6)c6ccccc6)ccc5n1c4c32]

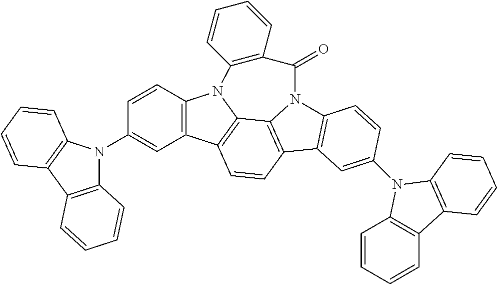 [SMILES: O=c1c2ccccc2n2c3ccc(-n4c5ccccc5c5ccccc54)cc3c3ccc4c5cc(-n6c7ccccc7c7ccccc76)ccc5n1c4c32]

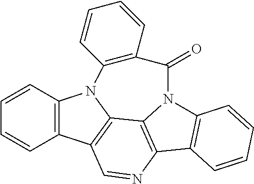 [SMILES: O=c1c2ccccc2n2c3ccccc3c3cnc4c5ccccc5n1c4c32]

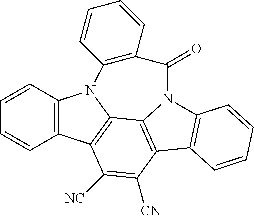 [SMILES: N#Cc1c(C#N)c2c3ccccc3n3c4ccccc4c(=O)n4c5ccccc5c1c4c23]

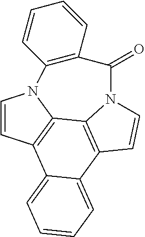 [SMILES: O=c1c2ccccc2n2ccc3c4ccccc4c4ccn1c4c32]

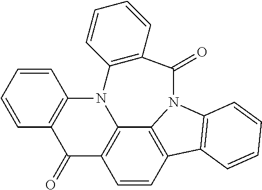 [SMILES: O=c1c2ccccc2n2c3ccccc3c(=O)n3c4ccccc4c4ccc1c2c43]

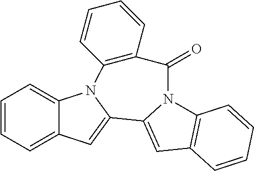 [SMILES: O=c1c2ccccc2n2c3ccccc3cc2c2cc3ccccc3n12]

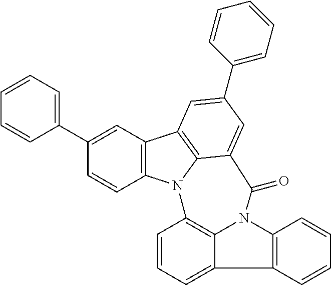 [SMILES: O=c1c2cc(-c3ccccc3)cc3c4cc(-c5ccccc5)ccc4n(c4cccc5c6ccccc6n1c54)c23]

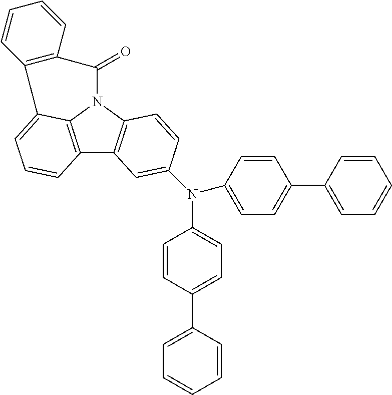 [SMILES: O=c1c2ccccc2c2cccc3c4cc(N(c5ccc(-c6ccccc6)cc5)c5ccc(-c6ccccc6)cc5)ccc4n1c23]

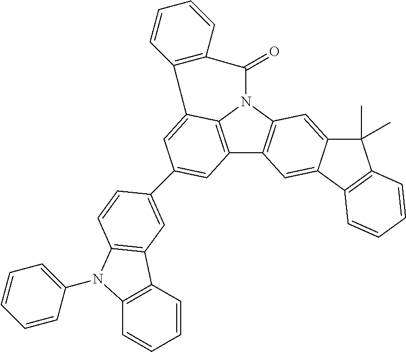 [SMILES: CC1(C)c2ccccc2-c2cc3c4cc(-c5ccc6c(c5)c5ccccc5n6-c5ccccc5)cc5c6ccccc6c(=O)n(c3cc21)c54]

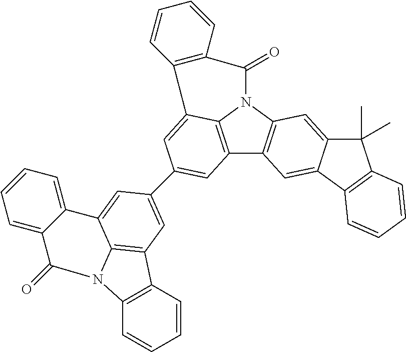 [SMILES: CC1(C)c2ccccc2-c2cc3c4cc(-c5cc6c7ccccc7c(=O)n7c8ccccc8c(c5)c67)cc5c6ccccc6c(=O)n(c3cc21)c54]

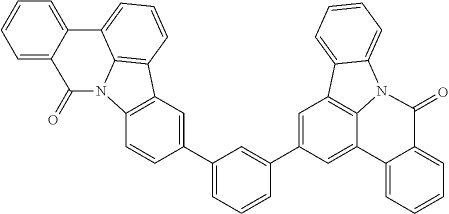 [SMILES: O=c1c2ccccc2c2cccc3c4cc(-c5cccc(-c6cc7c8ccccc8c(=O)n8c9ccccc9c(c6)c78)c5)ccc4n1c23]

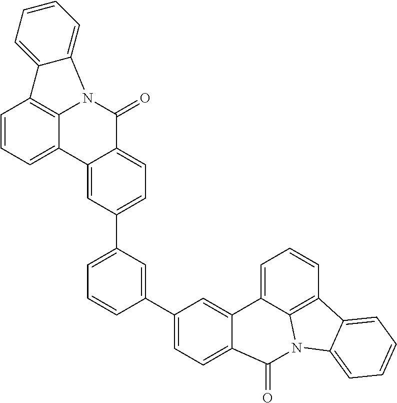 [SMILES: O=c1c2ccc(-c3cccc(-c4ccc5c(=O)n6c7ccccc7c7cccc(c5c4)c76)c3)cc2c2cccc3c4ccccc4n1c23]

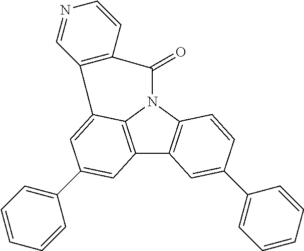 [SMILES: O=c1c2ccncc2c2cc(-c3ccccc3)cc3c4cc(-c5ccccc5)ccc4n1c23]

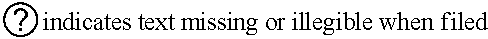

Furthermore, aromatic ketones or aromatic phosphine oxides are suitable as electron-conducting compound. An aromatic ketone in the sense of this application is taken to mean a carbonyl group to which two aromatic or heteroaromatic groups or aromatic or heteroaromatic ring systems are bonded directly. An aromatic phosphine oxide in the sense of this application is taken to mean a P═O group to which three aromatic or heteroaromatic groups or aromatic or heteroaromatic ring systems are bonded directly.

If the electron-conducting compound is an aromatic ketone or an aromatic phosphine oxide, this compound is then preferably selected from the compounds of the following formulae (70) and (71),

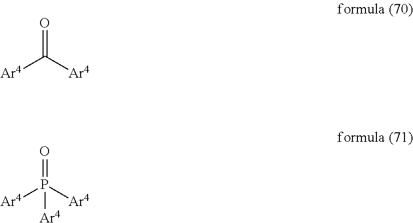

where R, R¹, R² and Ar have the above-mentioned meanings, and the following applies to the other symbols used:
Ar⁴ is on each occurrence, identically or differently, an aromatic or heteroaromatic ring system having 5 to 80 aromatic ring atoms, preferably up to 60 aromatic ring atoms, which may in each case be substituted by one or more groups R.

Suitable compounds of the formulae (70) and (71) are, in particular, the ketones disclosed in WO 2004/093207 and WO 2010/006680 and the phosphine oxides disclosed in WO 2005/003253. These are incorporated into the present invention by way of reference.

It is evident from the definition of the compounds of the formulae (70) and (71) that they do not have to contain just one carbonyl group or phosphine oxide group, but instead may also contain a plurality of these groups.

The group Ar⁴ in compounds of the formulae (70) and (71) is preferably an aromatic ring system having 6 to 40 aromatic ring atoms, i.e. it does not contain any heteroaryl groups. As defined above, the aromatic ring system does not necessarily have to contain only aromatic groups, but instead two aryl groups may also be interrupted by a non-aromatic group, for example by a further carbonyl group or phosphine oxide group.

In a further preferred embodiment of the invention, the group Ar⁴ contains not more than two condensed rings. It is thus preferably built up only from phenyl and/or naphthyl groups, particularly preferably only from phenyl groups, but does not contain any larger condensed aromatic groups, such as, for example, anthracene.

Preferred groups Ar⁴ which are bonded to the carbonyl group are, identically or differently on each occurrence, phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridanzinyl, 2-(1,3,5-triazin)yl-, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl), and combinations of one or more of these radicals.

The groups Ar⁴ may be substituted by one or more radicals R. These radicals R are preferably selected, identically or differently on each occurrence, from the group consisting of H, D, F, C(═O)Ar, P(═O)(Ar)₂, S(═O)Ar, S(═O)₂Ar, a straight-chain alkyl group having 1 to 4 C atoms or a branched or cyclic alkyl group having 3 to 5 C atoms, each of which may be substituted by one or more radicals R¹, where one or more H atoms may be replaced by F, or an aromatic ring system having 6 to 24 aromatic ring atoms, which may be substituted by one or more radicals R¹, or a combination of these systems; two or more adjacent substituents R here may also form a mono- or polycyclic, aliphatic or aromatic ring system with one another. If the organic electroluminescent device is applied from solution, straight-chain, branched or cyclic alkyl groups having up to 10 C atoms are also preferred as substituents R. The radicals R are particularly preferably selected, identically or differently on each occurrence, from the group consisting of H, C(═O)Ar or an aromatic ring system having 6 to 24 aromatic ring atoms, which may be substituted by one or more radicals R¹, but is preferably unsubstituted.

In a further preferred embodiment of the invention, the group Ar is, identically or differently on each occurrence, an aromatic ring system having 6 to 24 aromatic ring atoms, which may be substituted by one or more radicals R¹. Ar is particularly preferably, identically or differently on each occurrence, an aromatic ring system having 6 to 12 aromatic ring atoms.

Preference is furthermore given to benzophenone derivatives which are substituted in each of the 3,5,3′,5′-positions by an aromatic or heteroaromatic ring system having 5 to 30 aromatic ring atoms, which may in turn be substituted by one or more radicals R in accordance with the above definition. Preference is furthermore given to ketones which are substituted by at least one spirobifluorene group.

Preferred aromatic ketones and phosphine oxides are therefore the compounds of the following formulae (72) to (75),

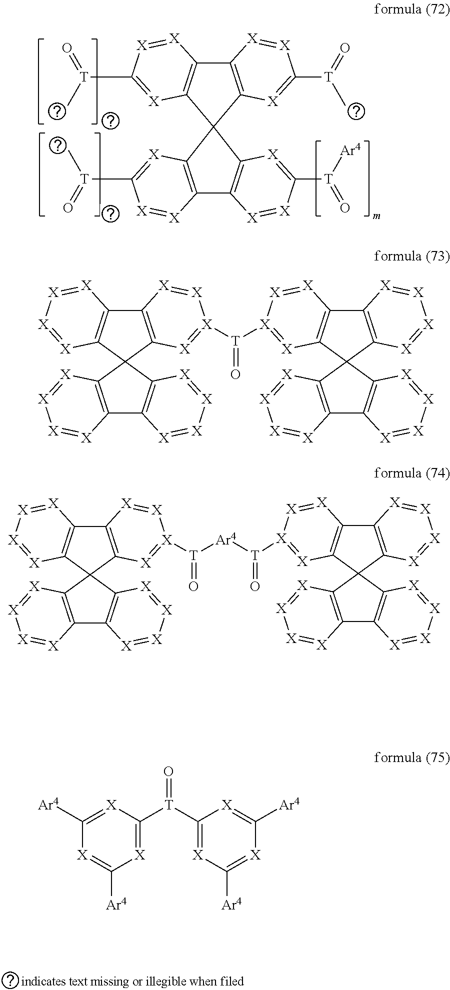

where X, Ar⁴, R, R¹ and R² have the same meaning as described above, and furthermore:
T is, identically or differently on each occurrence, C or P(Ar⁴);
n is, identically or differently on each occurrence, 0 or 1.

Ar⁴ in the above-mentioned formulae (72) and (75) preferably stands for an aromatic or heteroaromatic ring system having 5 to 30 aromatic ring atoms, which may be substituted by one or more radicals R¹. Particular preference is given to the groups Ar⁴ mentioned above.

Examples of suitable compounds of the formulae (70) and (71) are the compounds depicted in the following table.

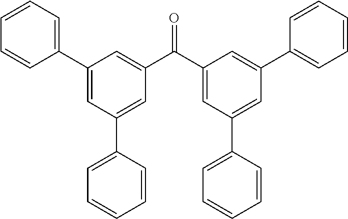 [SMILES: O=C(c1cc(-c2ccccc2)cc(-c2ccccc2)c1)c1cc(-c2ccccc2)cc(-c2ccccc2)c1]

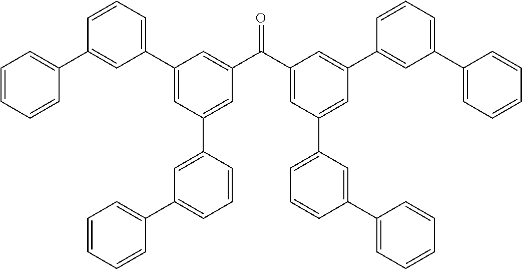 [SMILES: O=C(c1cc(-c2cccc(-c3ccccc3)c2)cc(-c2cccc(-c3ccccc3)c2)c1)c1cc(-c2cccc(-c3ccccc3)c2)cc(-c2cccc(-c3ccccc3)c2)c1]

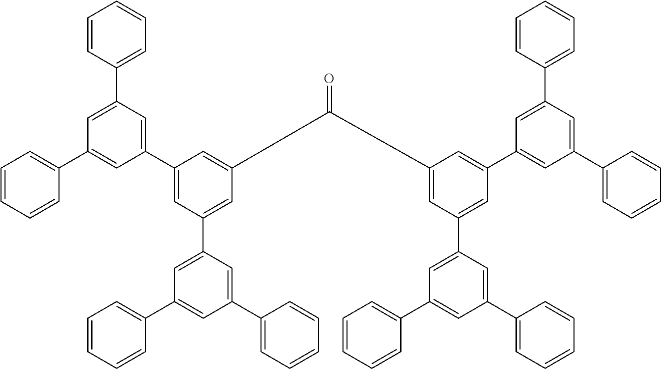 [SMILES: O=C(c1cc(-c2cc(-c3ccccc3)cc(-c3ccccc3)c2)cc(-c2cc(-c3ccccc3)cc(-c3ccccc3)c2)c1)c1cc(-c2cc(-c3ccccc3)cc(-c3ccccc3)c2)cc(-c2cc(-c3ccccc3)cc(-c3ccccc3)c2)c1]

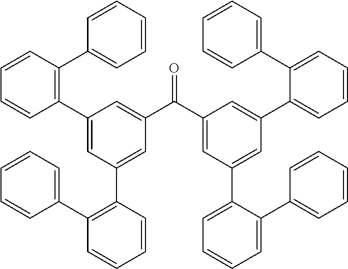 [SMILES: O=C(c1cc(-c2ccccc2-c2ccccc2)cc(-c2ccccc2-c2ccccc2)c1)c1cc(-c2ccccc2-c2ccccc2)cc(-c2ccccc2-c2ccccc2)c1]

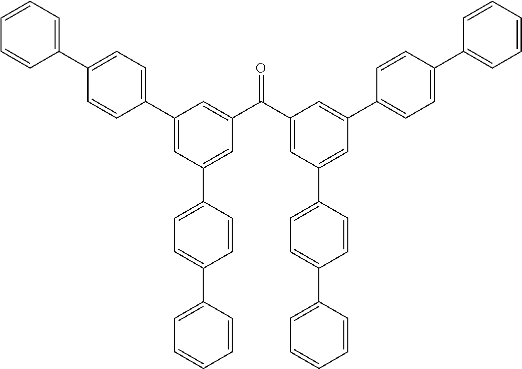 [SMILES: O=C(c1cc(-c2ccc(-c3ccccc3)cc2)cc(-c2ccc(-c3ccccc3)cc2)c1)c1cc(-c2ccc(-c3ccccc3)cc2)cc(-c2ccc(-c3ccccc3)cc2)c1]

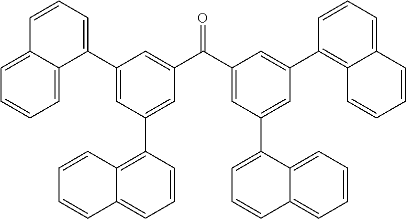 [SMILES: O=C(c1cc(-c2cccc3ccccc23)cc(-c2cccc3ccccc23)c1)c1cc(-c2cccc3ccccc23)cc(-c2cccc3ccccc23)c1]

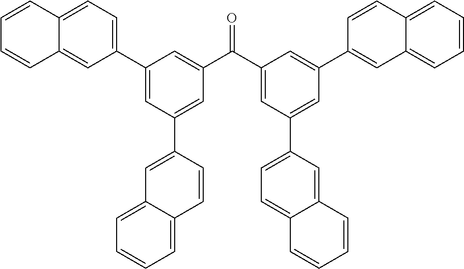 [SMILES: O=C(c1cc(-c2ccc3ccccc3c2)cc(-c2ccc3ccccc3c2)c1)c1cc(-c2ccc3ccccc3c2)cc(-c2ccc3ccccc3c2)c1]

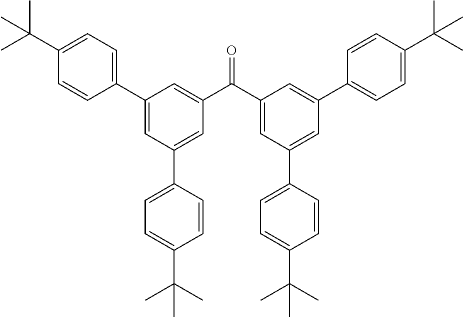 [SMILES: CC(C)(C)c1ccc(-c2cc(C(=O)c3cc(-c4ccc(C(C)(C)C)cc4)cc(-c4ccc(C(C)(C)C)cc4)c3)cc(-c3ccc(C(C)(C)C)cc3)c2)cc1]

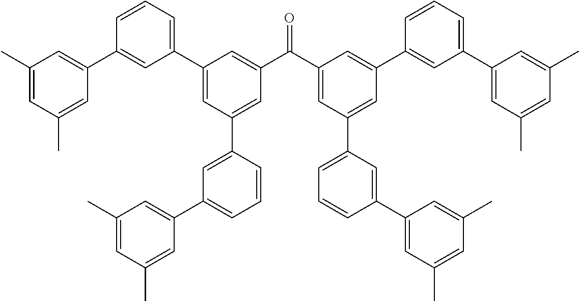

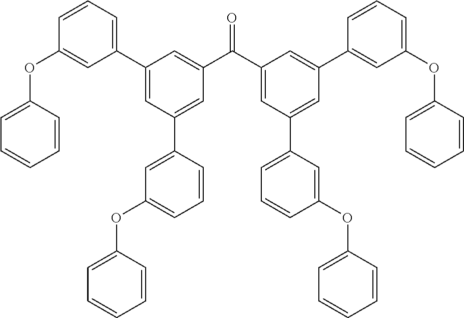 [SMILES: O=C(c1cc(-c2cccc(Oc3ccccc3)c2)cc(-c2cccc(Oc3ccccc3)c2)c1)c1cc(-c2cccc(Oc3ccccc3)c2)cc(-c2cccc(Oc3ccccc3)c2)c1]

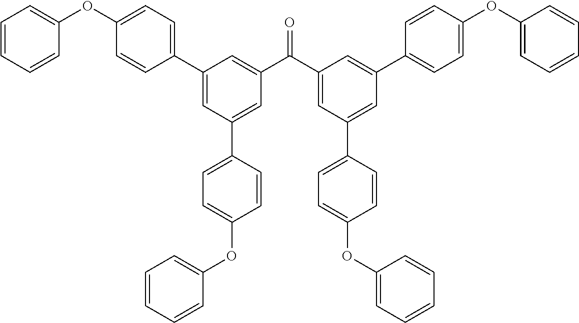 [SMILES: O=C(c1cc(-c2ccc(Oc3ccccc3)cc2)cc(-c2ccc(Oc3ccccc3)cc2)c1)c1cc(-c2ccc(Oc3ccccc3)cc2)cc(-c2ccc(Oc3ccccc3)cc2)c1]

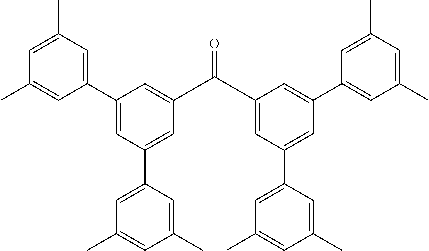

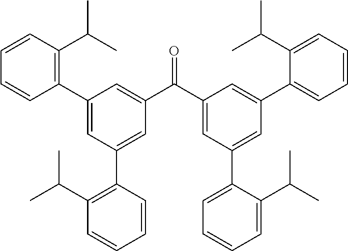 [SMILES: CC(C)c1ccccc1-c1cc(C(=O)c2cc(-c3ccccc3C(C)C)cc(-c3ccccc3C(C)C)c2)cc(-c2ccccc2C(C)C)c1]

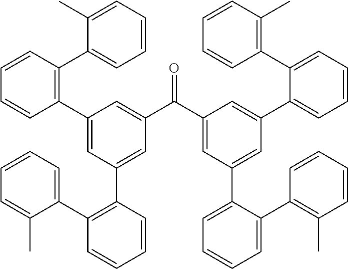 [SMILES: Cc1ccccc1-c1ccccc1-c1cc(C(=O)c2cc(-c3ccccc3-c3ccccc3C)cc(-c3ccccc3-c3ccccc3C)c2)cc(-c2ccccc2-c2ccccc2C)c1]

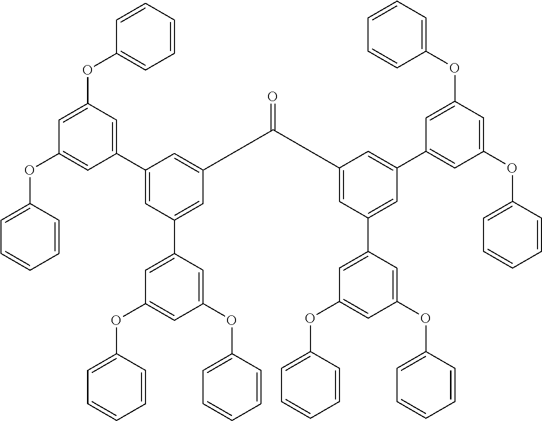 [SMILES: O=C(c1cc(-c2cc(Oc3ccccc3)cc(Oc3ccccc3)c2)cc(-c2cc(Oc3ccccc3)cc(Oc3ccccc3)c2)c1)c1cc(-c2cc(Oc3ccccc3)cc(Oc3ccccc3)c2)cc(-c2cc(Oc3ccccc3)cc(Oc3ccccc3)c2)c1]

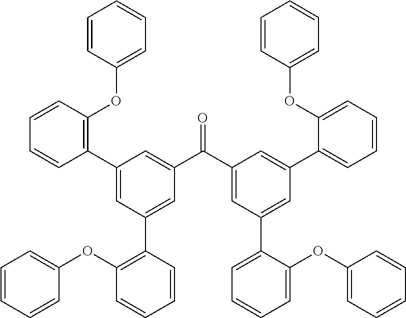 [SMILES: O=C(c1cc(-c2ccccc2Oc2ccccc2)cc(-c2ccccc2Oc2ccccc2)c1)c1cc(-c2ccccc2Oc2ccccc2)cc(-c2ccccc2Oc2ccccc2)c1]

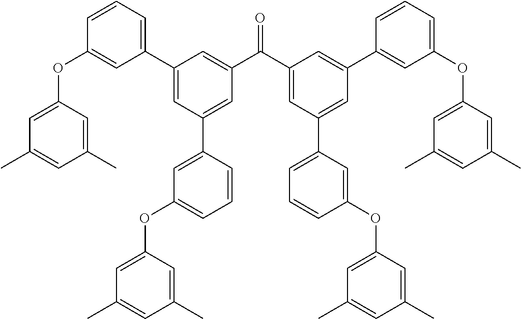

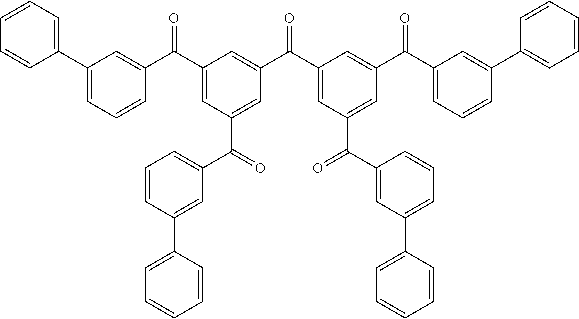 [SMILES: O=C(c1cc(C(=O)c2cccc(-c3ccccc3)c2)cc(C(=O)c2cccc(-c3ccccc3)c2)c1)c1cc(C(=O)c2cccc(-c3ccccc3)c2)cc(C(=O)c2cccc(-c3ccccc3)c2)c1]

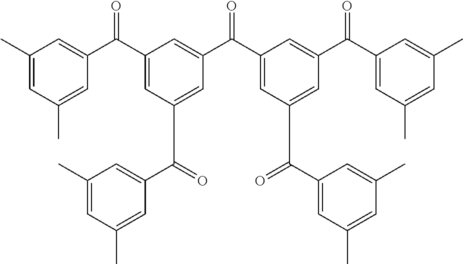

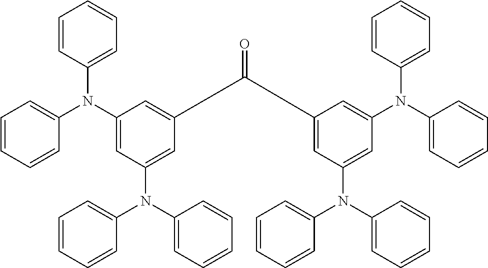 [SMILES: O=C(c1cc(N(c2ccccc2)c2ccccc2)cc(N(c2ccccc2)c2ccccc2)c1)c1cc(N(c2ccccc2)c2ccccc2)cc(N(c2ccccc2)c2ccccc2)c1]

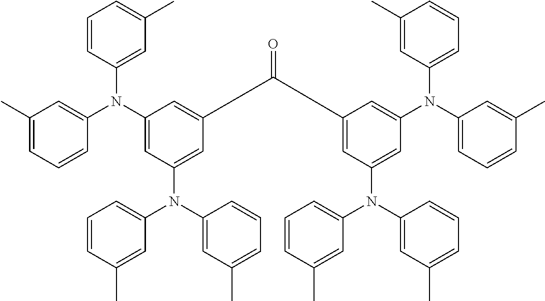

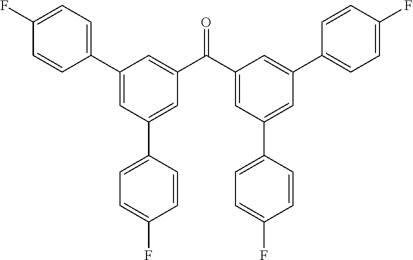 [SMILES: O=C(c1cc(-c2ccc(F)cc2)cc(-c2ccc(F)cc2)c1)c1cc(-c2ccc(F)cc2)cc(-c2ccc(F)cc2)c1]

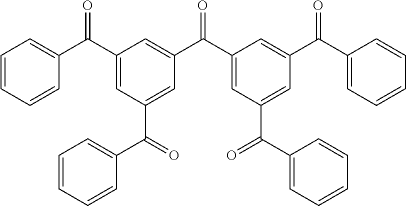 [SMILES: O=C(c1ccccc1)c1cc(C(=O)c2ccccc2)cc(C(=O)c2cc(C(=O)c3ccccc3)cc(C(=O)c3ccccc3)c2)c1]

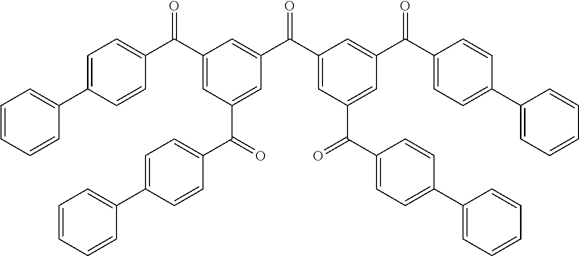 [SMILES: O=C(c1ccc(-c2ccccc2)cc1)c1cc(C(=O)c2ccc(-c3ccccc3)cc2)cc(C(=O)c2cc(C(=O)c3ccc(-c4ccccc4)cc3)cc(C(=O)c3ccc(-c4ccccc4)cc3)c2)c1]

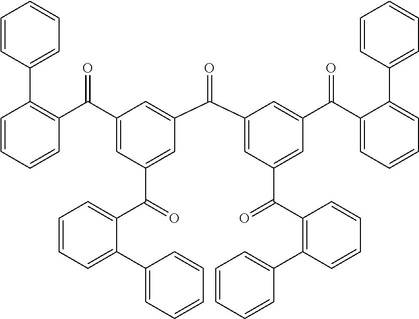 [SMILES: O=C(c1cc(C(=O)c2ccccc2-c2ccccc2)cc(C(=O)c2ccccc2-c2ccccc2)c1)c1cc(C(=O)c2ccccc2-c2ccccc2)cc(C(=O)c2ccccc2-c2ccccc2)c1]

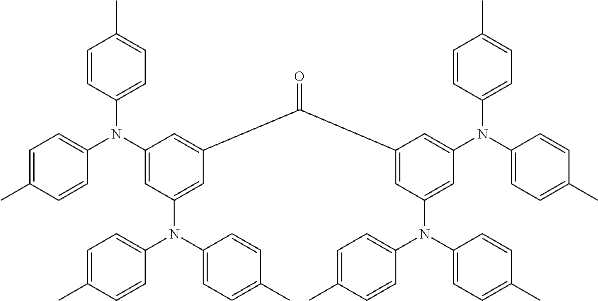

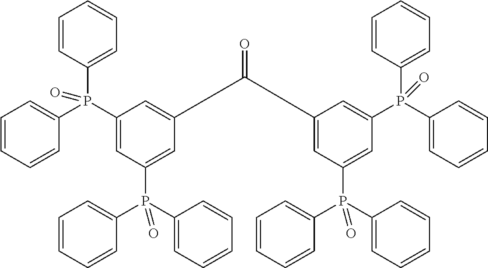 [SMILES: O=C(c1cc(P(=O)(c2ccccc2)c2ccccc2)cc(P(=O)(c2ccccc2)c2ccccc2)c1)c1cc(P(=O)(c2ccccc2)c2ccccc2)cc(P(=O)(c2ccccc2)c2ccccc2)c1]

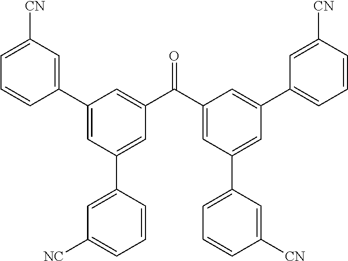 [SMILES: N#Cc1cccc(-c2cc(C(=O)c3cc(-c4cccc(C#N)c4)cc(-c4cccc(C#N)c4)c3)cc(-c3cccc(C#N)c3)c2)c1]

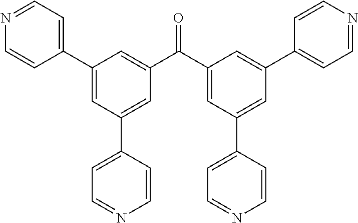 [SMILES: O=C(c1cc(-c2ccncc2)cc(-c2ccncc2)c1)c1cc(-c2ccncc2)cc(-c2ccncc2)c1]

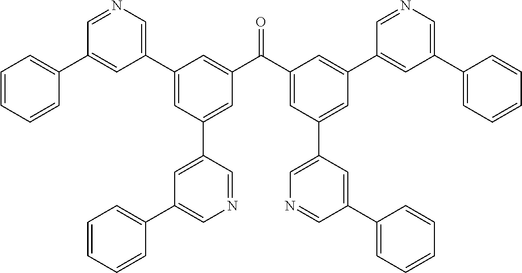 [SMILES: O=C(c1cc(-c2cncc(-c3ccccc3)c2)cc(-c2cncc(-c3ccccc3)c2)c1)c1cc(-c2cncc(-c3ccccc3)c2)cc(-c2cncc(-c3ccccc3)c2)c1]

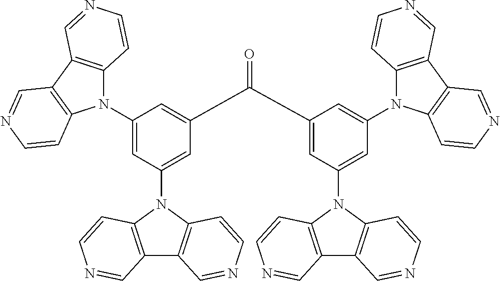 [SMILES: O=C(c1cc(-n2c3ccncc3c3cnccc32)cc(-n2c3ccncc3c3cnccc32)c1)c1cc(-n2c3ccncc3c3cnccc32)cc(-n2c3ccncc3c3cnccc32)c1]

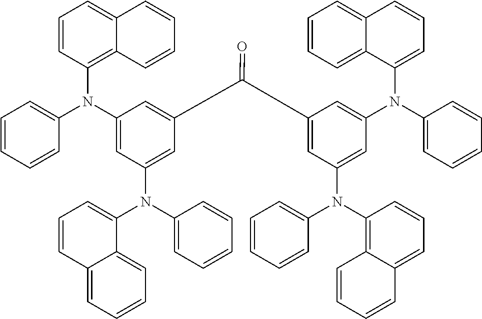 [SMILES: O=C(c1cc(N(c2ccccc2)c2cccc3ccccc23)cc(N(c2ccccc2)c2cccc3ccccc23)c1)c1cc(N(c2ccccc2)c2cccc3ccccc23)cc(N(c2ccccc2)c2cccc3ccccc23)c1]

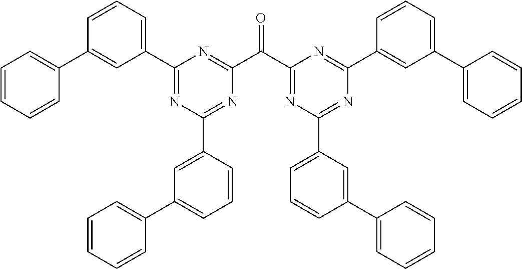 [SMILES: O=C(c1nc(-c2cccc(-c3ccccc3)c2)nc(-c2cccc(-c3ccccc3)c2)n1)c1nc(-c2cccc(-c3ccccc3)c2)nc(-c2cccc(-c3ccccc3)c2)n1]

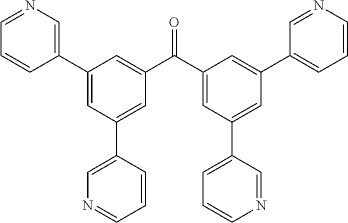 [SMILES: O=C(c1cc(-c2cccnc2)cc(-c2cccnc2)c1)c1cc(-c2cccnc2)cc(-c2cccnc2)c1]

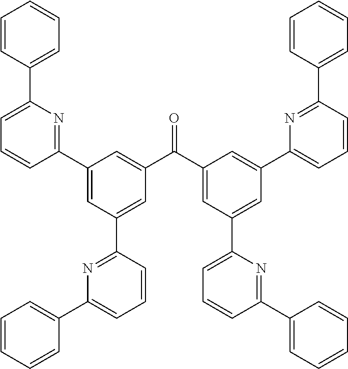 [SMILES: O=C(c1cc(-c2cccc(-c3ccccc3)n2)cc(-c2cccc(-c3ccccc3)n2)c1)c1cc(-c2cccc(-c3ccccc3)n2)cc(-c2cccc(-c3ccccc3)n2)c1]

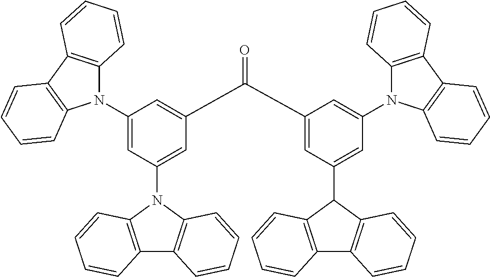 [SMILES: O=C(c1cc(C2c3ccccc3-c3ccccc32)cc(-n2c3ccccc3c3ccccc32)c1)c1cc(-n2c3ccccc3c3ccccc32)cc(-n2c3ccccc3c3ccccc32)c1]

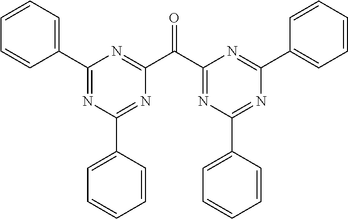 [SMILES: O=C(c1nc(-c2ccccc2)nc(-c2ccccc2)n1)c1nc(-c2ccccc2)nc(-c2ccccc2)n1]

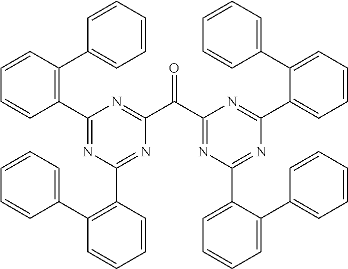 [SMILES: O=C(c1nc(-c2ccccc2-c2ccccc2)nc(-c2ccccc2-c2ccccc2)n1)c1nc(-c2ccccc2-c2ccccc2)nc(-c2ccccc2-c2ccccc2)n1]

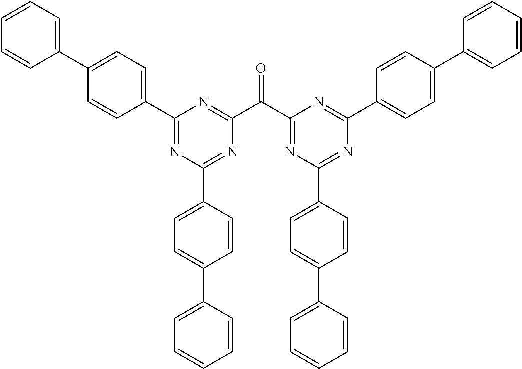 [SMILES: O=C(c1nc(-c2ccc(-c3ccccc3)cc2)nc(-c2ccc(-c3ccccc3)cc2)n1)c1nc(-c2ccc(-c3ccccc3)cc2)nc(-c2ccc(-c3ccccc3)cc2)n1]

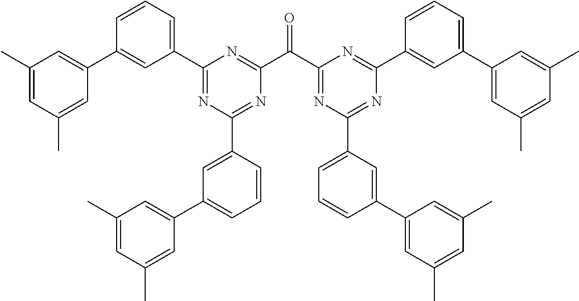

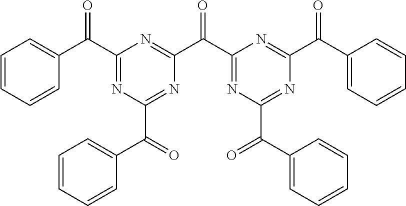 [SMILES: O=C(c1ccccc1)c1nc(C(=O)c2ccccc2)nc(C(=O)c2nc(C(=O)c3ccccc3)nc(C(=O)c3ccccc3)n2)n1]

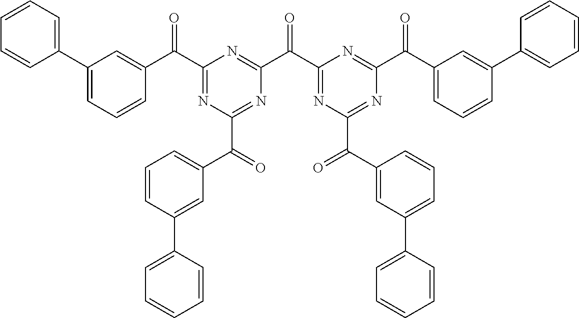 [SMILES: O=C(c1cccc(-c2ccccc2)c1)c1nc(C(=O)c2cccc(-c3ccccc3)c2)nc(C(=O)c2nc(C(=O)c3cccc(-c4ccccc4)c3)nc(C(=O)c3cccc(-c4ccccc4)c3)n2)n1]

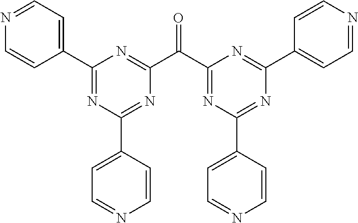 [SMILES: O=C(c1nc(-c2ccncc2)nc(-c2ccncc2)n1)c1nc(-c2ccncc2)nc(-c2ccncc2)n1]

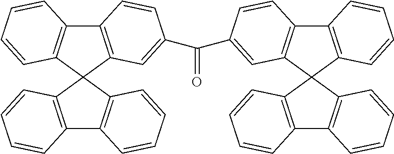 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2]

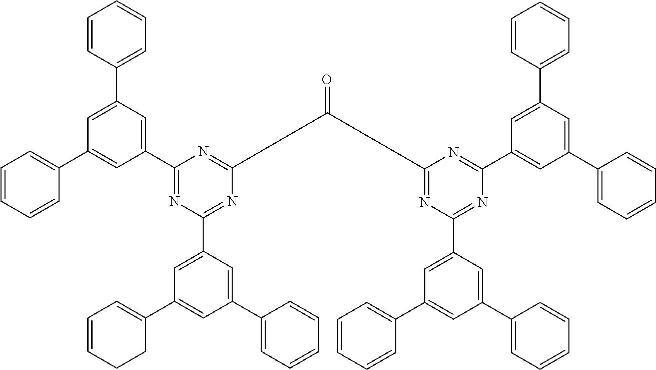 [SMILES: O=C(c1nc(-c2cc(C3=CC=CCC3)cc(-c3ccccc3)c2)nc(-c2cc(-c3ccccc3)cc(-c3ccccc3)c2)n1)c1nc(-c2cc(-c3ccccc3)cc(-c3ccccc3)c2)nc(-c2cc(-c3ccccc3)cc(-c3ccccc3)c2)n1]

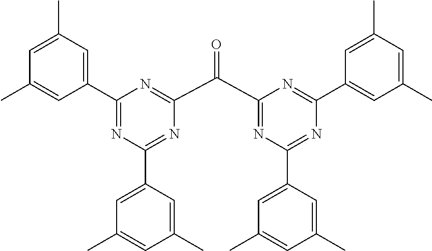

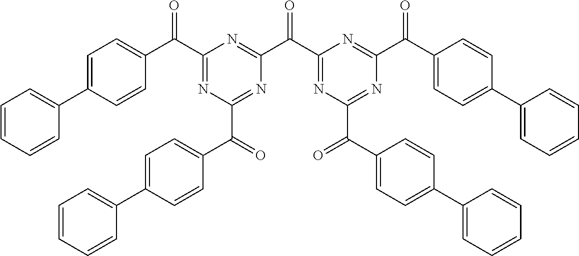 [SMILES: O=C(c1ccc(-c2ccccc2)cc1)c1nc(C(=O)c2ccc(-c3ccccc3)cc2)nc(C(=O)c2nc(C(=O)c3ccc(-c4ccccc4)cc3)nc(C(=O)c3ccc(-c4ccccc4)cc3)n2)n1]

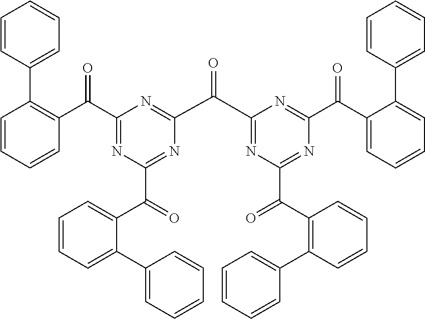 [SMILES: O=C(c1nc(C(=O)c2ccccc2-c2ccccc2)nc(C(=O)c2ccccc2-c2ccccc2)n1)c1nc(C(=O)c2ccccc2-c2ccccc2)nc(C(=O)c2ccccc2-c2ccccc2)n1]

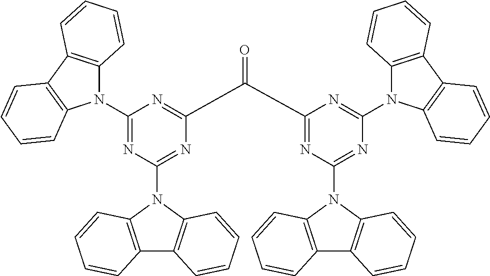 [SMILES: O=C(c1nc(-n2c3ccccc3c3ccccc32)nc(-n2c3ccccc3c3ccccc32)n1)c1nc(-n2c3ccccc3c3ccccc32)nc(-n2c3ccccc3c3ccccc32)n1]

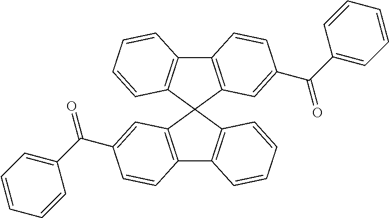 [SMILES: O=C(c1ccccc1)c1ccc2c(c1)C1(c3ccccc3-2)c2ccccc2-c2ccc(C(=O)c3ccccc3)cc21]

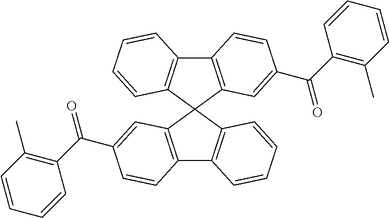 [SMILES: Cc1ccccc1C(=O)c1ccc2c(c1)C1(c3ccccc3-2)c2ccccc2-c2ccc(C(=O)c3ccccc3C)cc21]

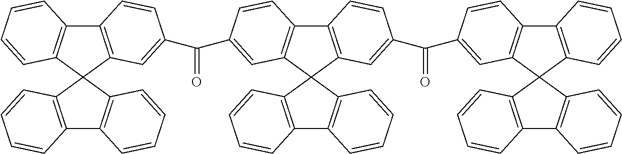 [SMILES: O=C(c1ccc2c(c1)C1(c3ccccc3-c3ccccc31)c1ccccc1-2)c1ccc2c(c1)C1(c3ccccc3-c3ccccc31)c1cc(C(=O)c3ccc4c(c3)C3(c5ccccc5-c5ccccc53)c3ccccc3-4)ccc1-2]

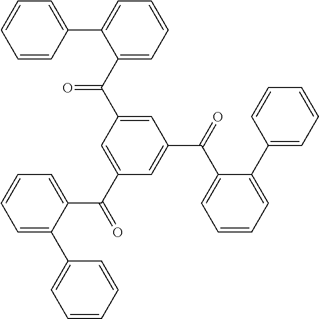 [SMILES: O=C(c1cc(C(=O)c2ccccc2-c2ccccc2)cc(C(=O)c2ccccc2-c2ccccc2)c1)c1ccccc1-c1ccccc1]

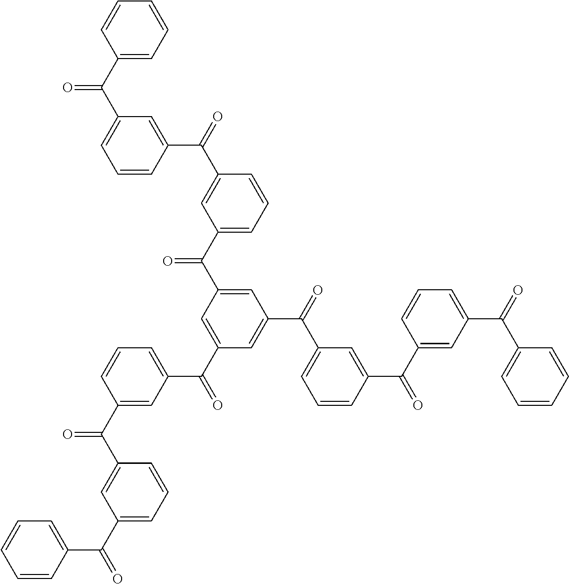 [SMILES: O=C(c1ccccc1)c1cccc(C(=O)c2cccc(C(=O)c3cc(C(=O)c4cccc(C(=O)c5cccc(C(=O)c6ccccc6)c5)c4)cc(C(=O)c4cccc(C(=O)c5cccc(C(=O)c6ccccc6)c5)c4)c3)c2)c1]

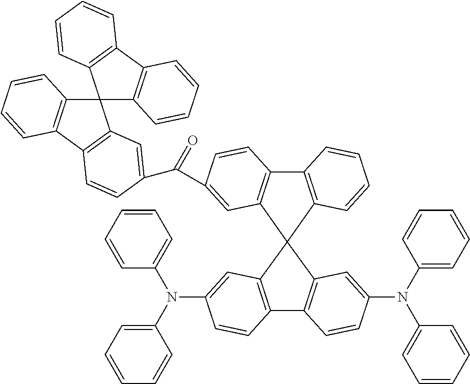 [SMILES: O=C(c1ccc2c(c1)C1(c3ccccc3-c3ccccc31)c1ccccc1-2)c1ccc2c(c1)C1(c3ccccc3-2)c2cc(N(c3ccccc3)c3ccccc3)ccc2-c2ccc(N(c3ccccc3)c3ccccc3)cc21]

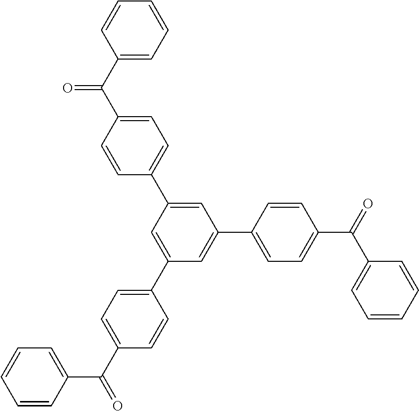 [SMILES: O=C(c1ccccc1)c1ccc(-c2cc(-c3ccc(C(=O)c4ccccc4)cc3)cc(-c3ccc(C(=O)c4ccccc4)cc3)c2)cc1]

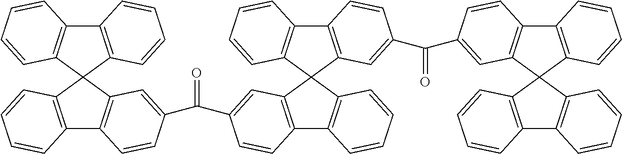 [SMILES: O=C(c1ccc2c(c1)C1(c3ccccc3-c3ccccc31)c1ccccc1-2)c1ccc2c(c1)C1(c3ccccc3-2)c2ccccc2-c2ccc(C(=O)c3ccc4c(c3)C3(c5ccccc5-c5ccccc53)c3ccccc3-4)cc21]

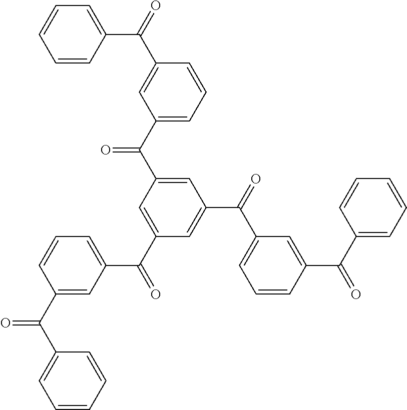 [SMILES: O=C(c1ccccc1)c1cccc(C(=O)c2cc(C(=O)c3cccc(C(=O)c4ccccc4)c3)cc(C(=O)c3cccc(C(=O)c4ccccc4)c3)c2)c1]

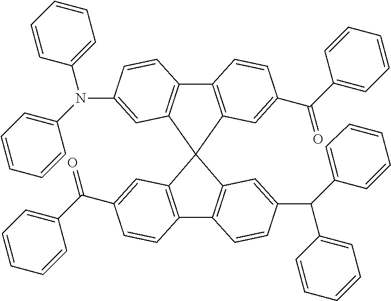 [SMILES: O=C(c1ccccc1)c1ccc2c(c1)C1(c3cc(C(=O)c4ccccc4)ccc3-c3ccc(N(c4ccccc4)c4ccccc4)cc31)c1cc(C(c3ccccc3)c3ccccc3)ccc1-2]

Examples of suitable aromatic phosphine oxide derivatives are the compounds depicted below.

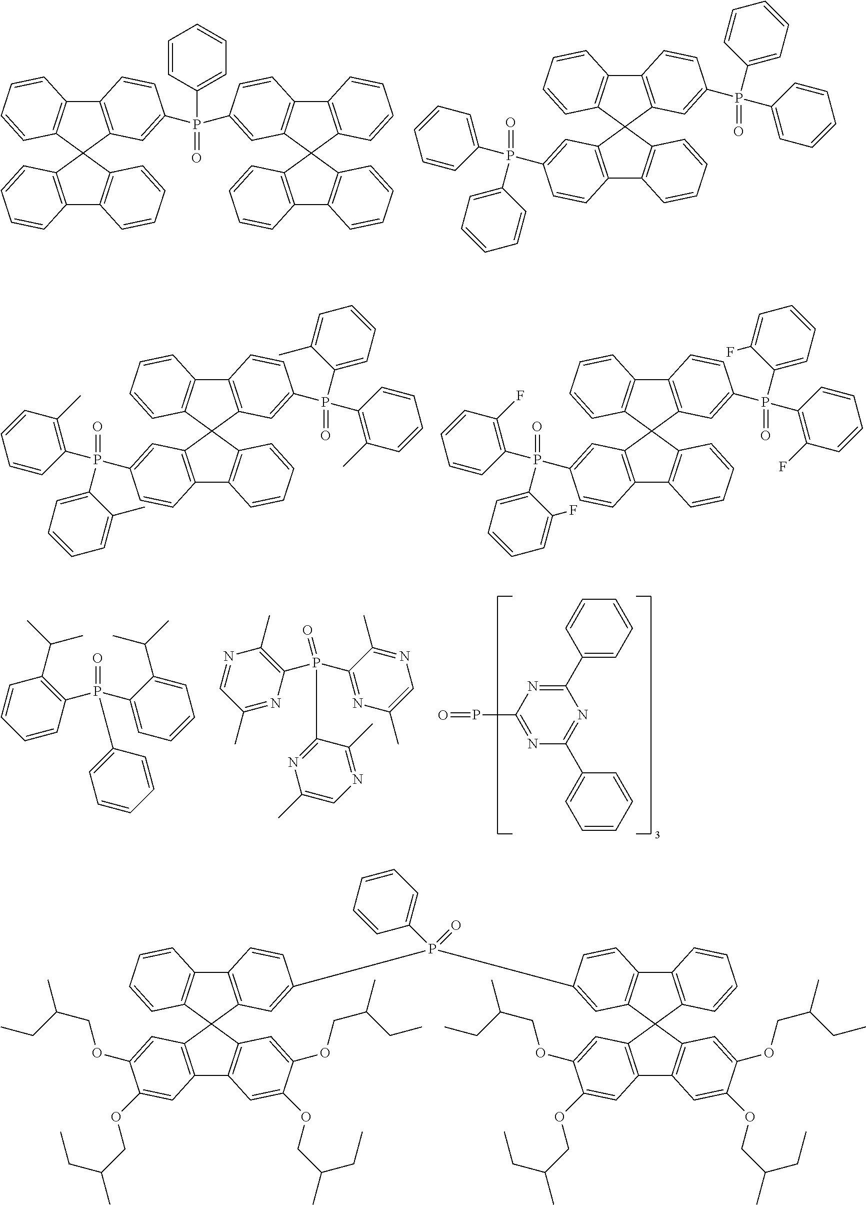

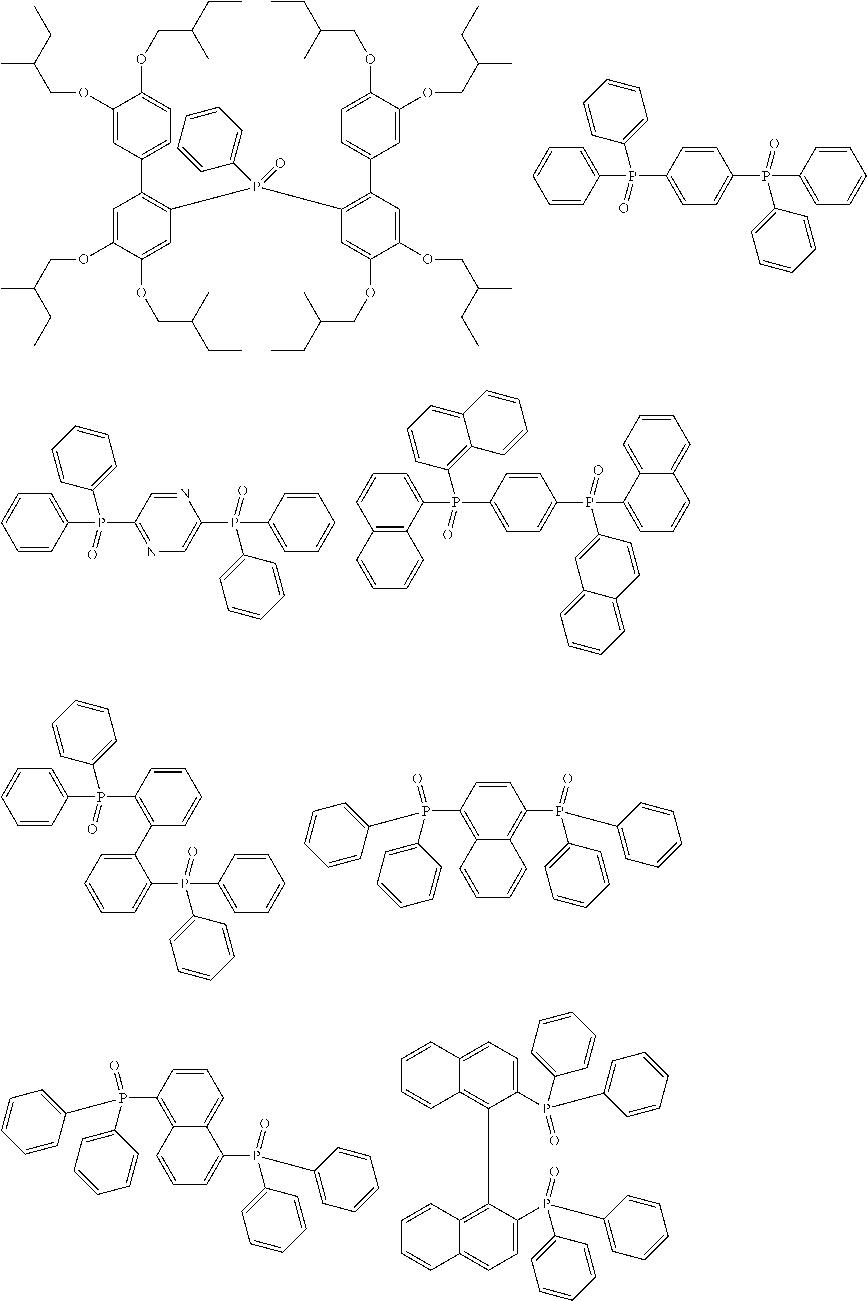

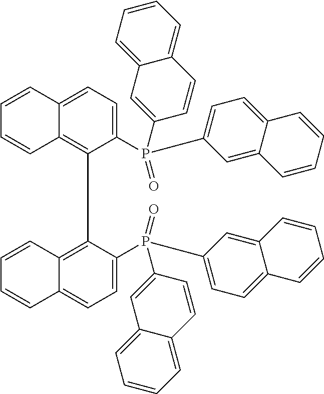 [SMILES: O=P(c1ccc2ccccc2c1)(c1ccc2ccccc2c1)c1ccc2ccccc2c1-c1c(P(=O)(c2ccc3ccccc3c2)c2ccc3ccccc3c2)ccc2ccccc12]

Suitable metal complexes which can be employed as matrix material in the organic electroluminescent device according to the invention are Be, Zn or Al complexes. For example, the Zn complexes disclosed in WO 2009/062578 are suitable.

Examples of suitable metal complexes are the complexes shown in the following table.

| | | |
|---|---|---|
| 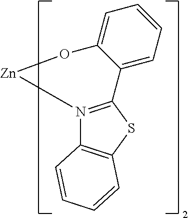 | 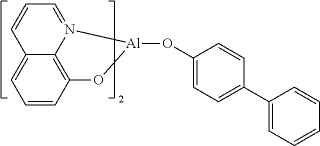 | 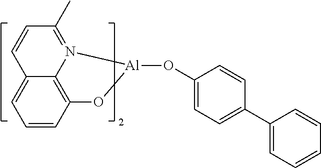 |
| 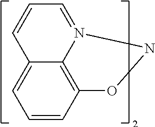 | 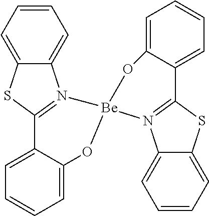 | 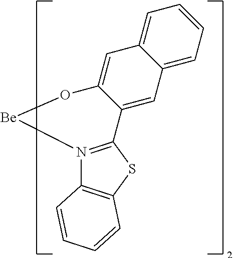 |
| 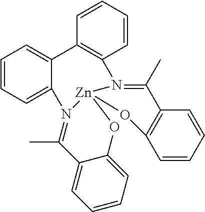 | 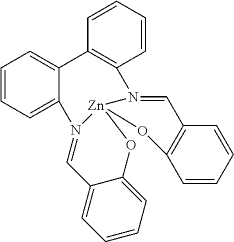 | 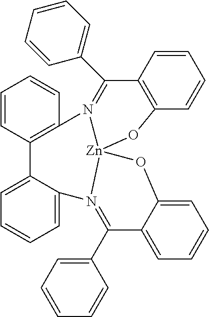 |
| 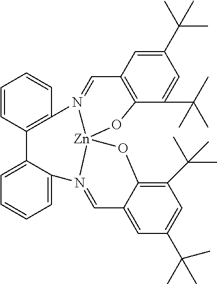 | | |

Suitable azaphospholes which can be employed as matrix material in the organic electroluminescent device according to the invention are compounds as disclosed in WO 2010/054730. This application is incorporated into the present invention by way of reference.

Suitable azaboroles which can be employed as matrix material in the organic electroluminescent device according to the invention are, in particular, azaborole derivatives which are substituted by at least one electron-conducting substituent. Compounds of this type are disclosed in the as yet unpublished application EP 11010103.7. This application is incorporated into the present invention by way of reference.

Suitable matrix compounds are furthermore the compounds of the following formula (76),

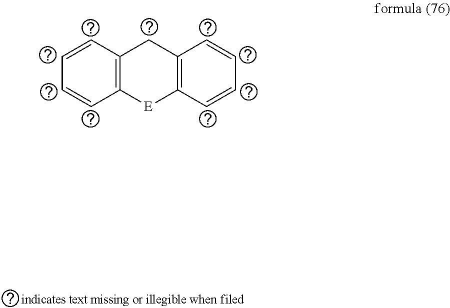

where R, Z and E are as defined above, and the following applies to the other symbols used:
X¹ is on each occurrence, identically or differently, CR or N, or a group X¹—X¹ stands for a group of the following formula (77), with the proviso that at least one group X¹—X¹ in the compound of the formula (76) stands for a group of the formula (77) and that a maximum of one group X¹—X¹ per ring stands for a group of the formula (77),

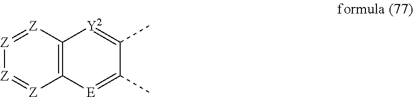

where the C atoms with the dashed bonds indicate the bonding of the group;

Y¹, Y² are selected on each occurrence, identically or differently, from the group consisting of CR₂, NR, 0, S, SiR₂, BR, PR and P(═O)R.

These compounds, depending on the precise structure and substitution, can be hole-transporting, electron-transporting, bipolar or neither hole- nor electron-transporting.

The group X¹—X¹ is indicated here by a single bond. However, since the group X¹—X¹ in the compound of the formula (77) is bonded in an aromatic group, it is clear that this is intended to mean an aromatic bond, i.e. the bond order of the bond between the two atoms X¹ is between 1 and 2. The group of the formula (77) is bonded in any desired position here, and the groups Y¹ and Y² can either be in the cis- or in the trans-configuration to one another. The groups X¹ which do not stand for a group of the formula (77) stand, identically or differently on each occurrence, for CR or N.

In a preferred embodiment of the invention, E is selected on each occurrence, identically or differently, from the group consisting of a single bond, CR₂, NR, O and S. E particularly preferably stands for a single bond.

Preferred compounds of the formula (76) are the compounds of the following formulae (78) to (84),

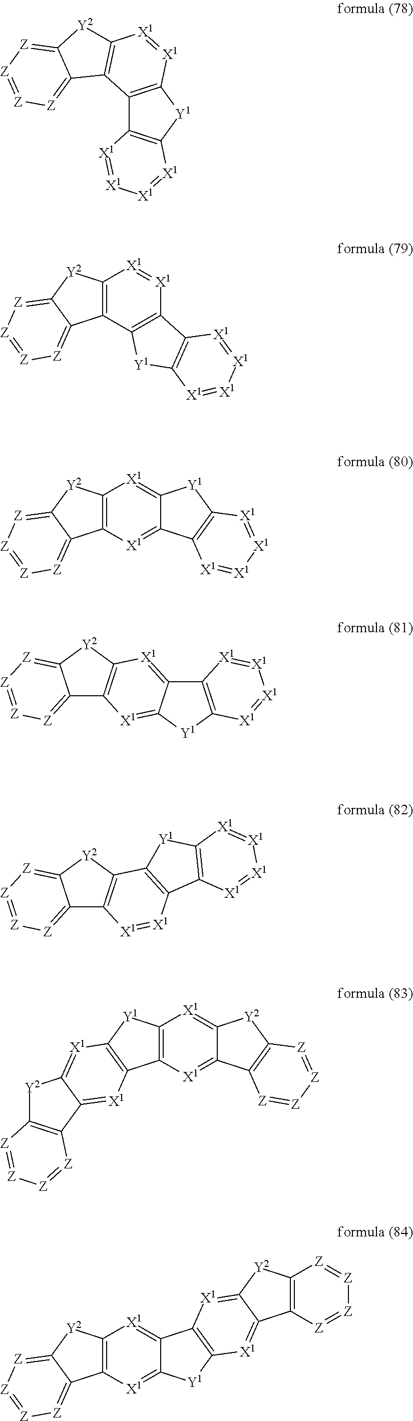

where Z, Y¹, Y², R, R¹ and R² have the above-mentioned meanings, and furthermore:
X¹ is on each occurrence, identically or differently, CR or N.

In preferred groups of the above-mentioned formulae (76) and (78) to (84), a maximum of two symbols X¹ per ring stand for N, particularly preferably a maximum of one symbol X¹ per ring stands for N. Very particularly preferably, the symbol X¹ stands, identically or differently on each occurrence, for CR.

In preferred groups of the above-mentioned formulae (77) to (84), a maximum of two symbols Z per ring stand for N, particularly preferably a maximum of one symbol Z per ring stands for N. Very particularly preferably, the symbol Z stands, identically or differently on each occurrence, for CR.

Especially preferably, all symbols X¹ and all symbols Z in the formulae (78) to (84) stand, identically or differently, for CR.

Preferred embodiments of the formulae (78) to (84) are the compounds of the following formulae (78a) to (84a),

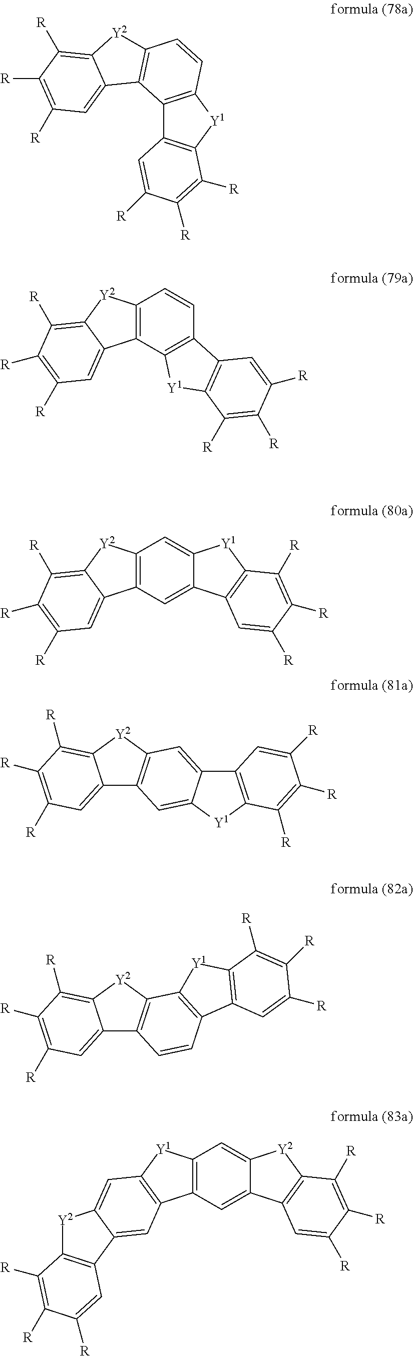

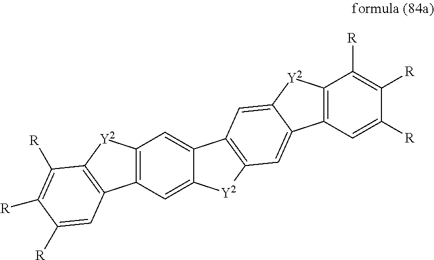

where the symbols used have the above-mentioned meanings.

In a further preferred embodiment of the invention, Y¹ and Y² are selected, identically or differently on each occurrence, from the group consisting of CR₂, NR, O and S.

In the groups of the formulae (76) and (78) to (84) and (78a) to (84a), all combinations are suitable for the groups Y¹ and Y². Preferably, at least one group Y¹ and/or Y² stands for a heteroatom, i.e. at least one of the groups Y¹ and/or Y² is preferably different from CR₂.

Suitable combinations of Y¹ and Y² are the combinations shown in the following table.

| Y¹ | Y² |
|---|---|
| CR₂ | CR₂ |
| CR₂ | NR |
| CR₂ | O |
| CR₂ | S |
| NR | CR₂ |
| NR | NR |
| NR | O |
| NR | S |
| O | CR₂ |
| O | NR |
| O | O |
| O | S |
| S | CR₂ |
| S | NR |
| S | O |
| S | S |

Preference is given to compounds of the formulae (76) and (78) to (84) and (78a) to (84a) in which one of the groups Y¹ and Y² stands for CR₂ and the other of the groups Y¹ and Y² stands for NR or in which both groups Y¹ and Y² stand for NR or in which both groups Y¹ and Y² stand for O.

If Y¹ or Y² stands for NR, the substituent R which is bonded to this nitrogen atom preferably stands for an aromatic or heteroaromatic ring system having 5 to 24 aromatic ring atoms, which may also be substituted by one or more radicals R¹. The aromatic or heteroaromatic ring systems here preferably contain no condensed aryl or heteroaryl groups in which more than two aromatic six-membered rings are condensed directly onto one another. In a particularly preferred embodiment, this substituent R stands, identically or differently on each occurrence, for an aromatic or heteroaromatic ring system having 6 to 24 aromatic ring atoms which has no condensed aryl groups and which has no condensed heteroaryl groups in which two or more aromatic or heteroaromatic 6-membered ring groups are condensed directly onto one another and which may in each case also be substituted by one or more radicals R¹. Thus, it is preferred for R to have, for example, no naphthyl groups or higher condensed aryl groups and likewise no quinoline groups, acridine groups, etc. By contrast, it is possible for R to have, for example, carbazole groups, dibenzofuran groups, fluorene groups, etc., since no 6-membered aromatic or heteroaromatic ring groups in these structures are condensed directly onto one another. Preferred substituents R are selected from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, phenanthrene or combinations of two or three of these groups, each of which may be substituted by one or more radicals R¹. Preferred biphenyl, terphenyl and quaterphenyl groups are the structures of the formulae (Bi-1) to (Bi-3), (Ter-1) to (Ter-3) and (Quater-1) to (Quater-4) depicted above.

If Y¹ or Y² stands for CR₂, R preferably stands, identically or differently on each occurrence, for a linear alkyl group having 1 to 10 C atoms or for a branched or cyclic alkyl group having 3 to 10 C atoms or for an aromatic or heteroaromatic ring system having 5 to 24 aromatic ring atoms, which may also be substituted by one or more radicals R¹. The radicals R here may also form a ring system with one another and thus form a spiro system. R very particularly preferably stands for a methyl group or for a phenyl group.

In a preferred embodiment of the invention, at least one of the groups Y¹ and Y² stands for NR, and the corresponding group R stands for an aromatic or heteroaromatic ring system, as described above. In this case, it may also be preferred for all substituents R which are bonded to the skeleton of the compound of the formula (76) or the preferred embodiments to stand for H.

In a further preferred embodiment of the compound of the formula (76) or the preferred embodiments mentioned above, at least one substituent R which is bonded to the skeleton of the compound of the formula (76) stands for a radical other than H or D. In particular, at least one of the radicals R explicitly drawn-in in the formulae (78a) to (84a) is other than H or D.

This substituent R which is not equal to H or D preferably stands for an aromatic or heteroaromatic ring system having 5 to 24 aromatic ring atoms, which may also be substituted by one or more radicals R¹. The aromatic or heteroaromatic ring systems here preferably contain no condensed aryl or heteroaryl groups in which more than two aromatic six-membered rings are condensed directly onto one another. In a particularly preferred embodiment, this substituent R stands, identically or differently on each occurrence, for an aromatic or heteroaromatic ring system having 6 to 24 aromatic ring atoms which has no condensed aryl groups and which has no condensed heteroaryl groups in which two or more aromatic or heteroaromatic 6-membered ring groups are condensed directly onto one another and which may in each case also be substituted by one or more radicals R¹. Thus, it is preferred for R to have, for example, no naphthyl groups or higher condensed aryl groups and likewise no quinoline groups, acridine groups, etc. By contrast, it is possible for R to have, for example, carbazole groups, dibenzofuran groups, fluorene groups, etc., since no 6-membered aromatic or heteroaromatic ring groups in these structures are condensed directly onto one another. Preferred substituents R are selected from the group consisting of benzene, ortho-, meta- or para-biphenyl, ortho-, meta-, para- or branched terphenyl, ortho-, meta-, para- or branched quaterphenyl, 1-, 2-, 3- or 4-fluorenyl, 1-, 2-, 3- or 4-spirobifluorenyl, 1- or 2-naphthyl, pyrrole, furan, thiophene, indole, benzofuran, benzothiophene, 1-, 2- or 3-carbazole, 1-, 2- or 3-dibenzofuran, 1-, 2- or 3-dibenzothiophene, indenocarbazole, indolocarbazole, 2-, 3- or 4-pyridine, 2-, 4- or 5-pyrimidine, pyrazine, pyridazine, triazine, phenanthrene or combinations of two or three of these groups, each of which may be substituted by one or more radicals R¹. Preferred biphenyl, terphenyl and quaterphenyl groups are the structures of the formulae (Bi-1) to (Bi-3), (Ter-1) to (Ter-3) and (Quater-1) to (Quater-4) depicted above.

In a preferred embodiment of the invention, the above-mentioned preferences occur simultaneously. Preference is thus given to the compounds of the formulae (78a) to (84a) in which Y¹ and Y² are selected, identically or differently on each occurrence, from CR₂, NR, O and S, in particular in the above-mentioned combinations, and in which the above-mentioned preferences apply to R.

Examples of preferred compounds of the formula (76) are the compounds shown in the following table. Further suitable compounds are the structures shown above for the compounds of the formulae (1) and (2) which simultaneously also contain structures of the formula (76).

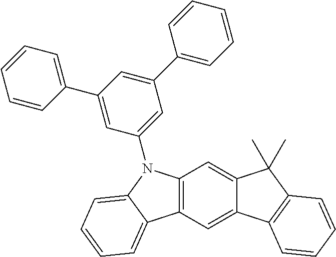 [SMILES: CC1(C)c2ccccc2-c2cc3c4ccccc4n(-c4cc(-c5ccccc5)cc(-c5ccccc5)c4)c3cc21]

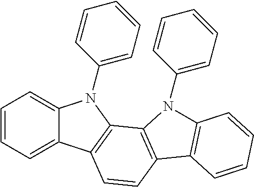 [SMILES: c1ccc(-n2c3ccccc3c3ccc4c5ccccc5n(-c5ccccc5)c4c32)cc1]

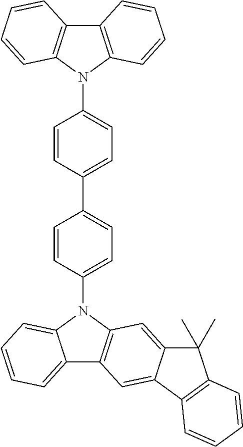 [SMILES: CC1(C)c2ccccc2-c2cc3c4ccccc4n(-c4ccc(-c5ccc(-n6c7ccccc7c7ccccc76)cc5)cc4)c3cc21]

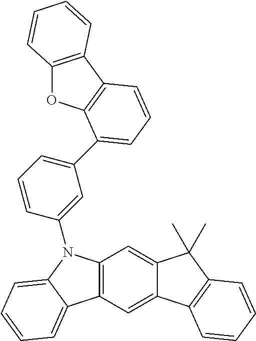 [SMILES: CC1(C)c2ccccc2-c2cc3c4ccccc4n(-c4cccc(-c5cccc6c5oc5ccccc56)c4)c3cc21]

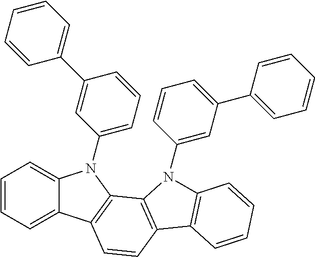 [SMILES: c1ccc(-c2cccc(-n3c4ccccc4c4ccc5c6ccccc6n(-c6cccc(-c7ccccc7)c6)c5c43)c2)cc1]

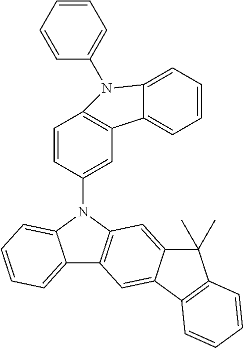 [SMILES: CC1(C)c2ccccc2-c2cc3c4ccccc4n(-c4ccc5c(c4)c4ccccc4n5-c4ccccc4)c3cc21]

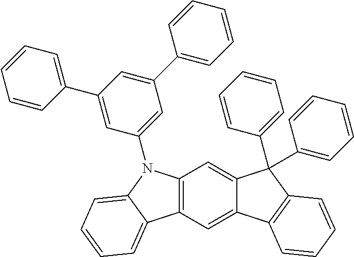 [SMILES: c1ccc(-c2cc(-c3ccccc3)cc(-n3c4ccccc4c4cc5c(cc43)C(c3ccccc3)(c3ccccc3)c3ccccc3-5)c2)cc1]

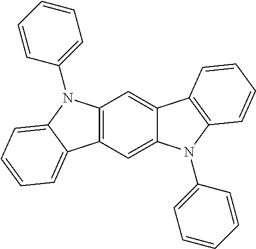 [SMILES: c1ccc(-n2c3ccccc3c3cc4c(cc32)c2ccccc2n4-c2ccccc2)cc1]

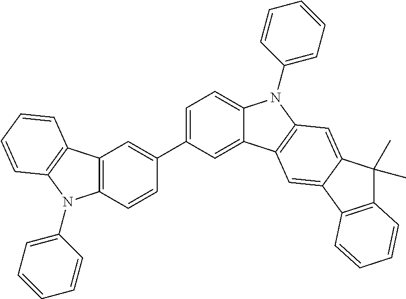 [SMILES: CC1(C)c2ccccc2-c2cc3c4cc(-c5ccc6c(c5)c5ccccc5n6-c5ccccc5)ccc4n(-c4ccccc4)c3cc21]

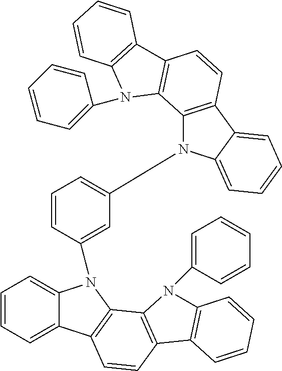 [SMILES: c1ccc(-n2c3ccccc3c3ccc4c5ccccc5n(-c5cccc(-n6c7ccccc7c7ccc8c9ccccc9n(-c9ccccc9)c8c76)c5)c4c32)cc1]

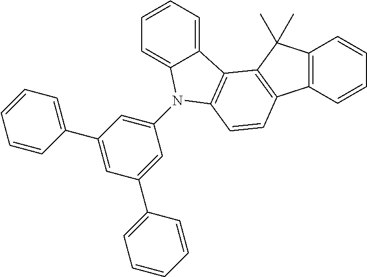 [SMILES: CC1(C)c2ccccc2-c2ccc3c(c21)c1ccccc1n3-c1cc(-c2ccccc2)cc(-c2ccccc2)c1]

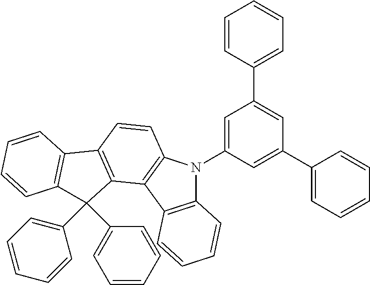 [SMILES: c1ccc(-c2cc(-c3ccccc3)cc(-n3c4ccccc4c4c5c(ccc43)-c3ccccc3C5(c3ccccc3)c3ccccc3)c2)cc1]

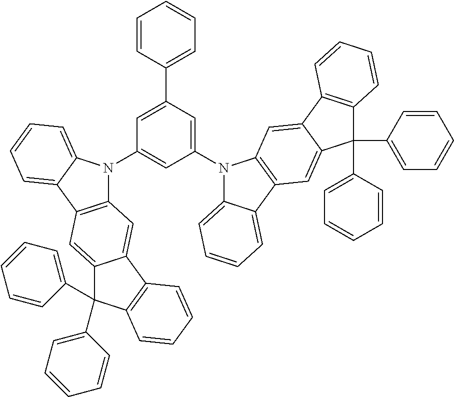 [SMILES: c1ccc(-c2cc(-n3c4ccccc4c4cc5c(cc43)-c3ccccc3C5(c3ccccc3)c3ccccc3)cc(-n3c4ccccc4c4cc5c(cc43)-c3ccccc3C5(c3ccccc3)c3ccccc3)c2)cc1]

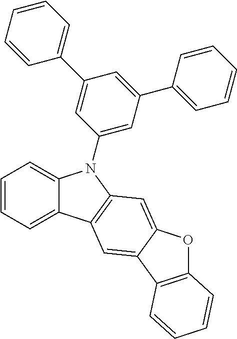 [SMILES: c1ccc(-c2cc(-c3ccccc3)cc(-n3c4ccccc4c4cc5c(cc43)oc3ccccc35)c2)cc1]

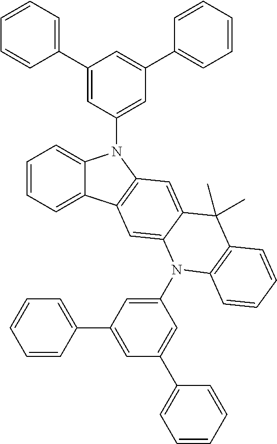 [SMILES: CC1(C)c2ccccc2N(c2cc(-c3ccccc3)cc(-c3ccccc3)c2)c2cc3c4ccccc4n(-c4cc(-c5ccccc5)cc(-c5ccccc5)c4)c3cc21]

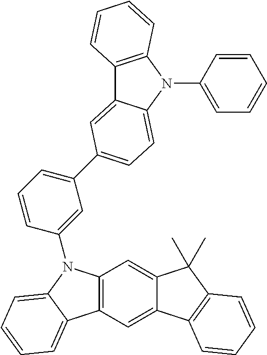 [SMILES: CC1(C)c2ccccc2-c2cc3c4ccccc4n(-c4cccc(-c5ccc6c(c5)c5ccccc5n6-c5ccccc5)c4)c3cc21]

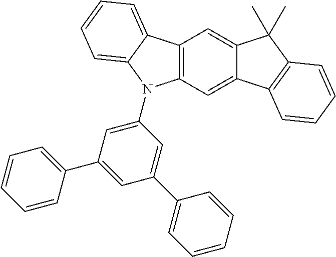 [SMILES: CC1(C)c2ccccc2-c2cc3c(cc21)c1ccccc1n3-c1cc(-c2ccccc2)cc(-c2ccccc2)c1]

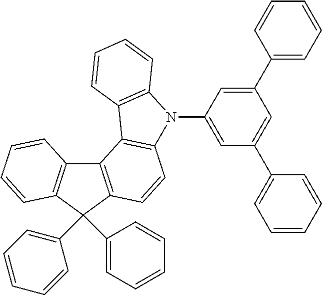 [SMILES: c1ccc(-c2cc(-c3ccccc3)cc(-n3c4ccccc4c4c5c(ccc43)C(c3ccccc3)(c3ccccc3)c3ccccc3-5)c2)cc1]

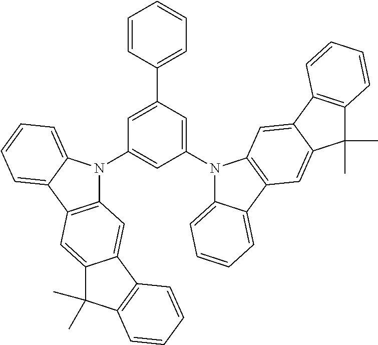 [SMILES: CC1(C)c2ccccc2-c2cc3c(cc21)c1ccccc1n3-c1cc(-c2ccccc2)cc(-n2c3ccccc3c3cc4c(cc32)-c2ccccc2C4(C)C)c1]

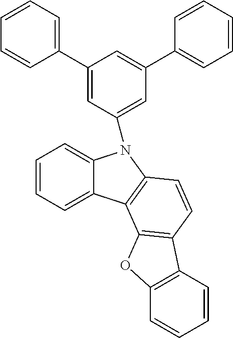 [SMILES: c1ccc(-c2cc(-c3ccccc3)cc(-n3c4ccccc4c4c5oc6ccccc6c5ccc43)c2)cc1]

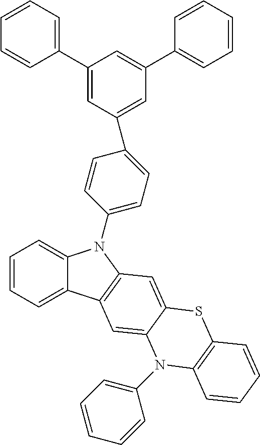 [SMILES: c1ccc(-c2cc(-c3ccccc3)cc(-c3ccc(-n4c5ccccc5c5cc6c(cc54)Sc4ccccc4N6c4ccccc4)cc3)c2)cc1]

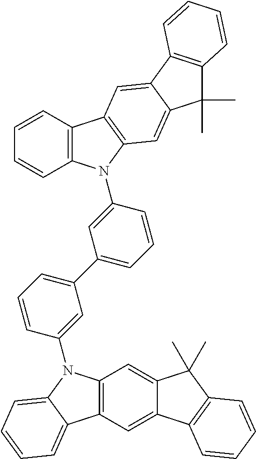 [SMILES: CC1(C)c2ccccc2-c2cc3c4ccccc4n(-c4cccc(-c5cccc(-n6c7ccccc7c7cc8c(cc76)C(C)(C)c6ccccc6-8)c5)c4)c3cc21]

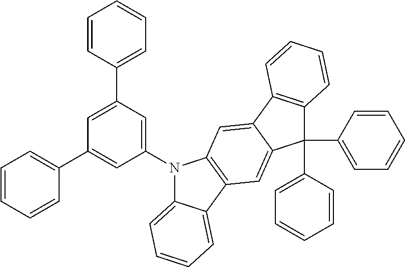 [SMILES: c1ccc(-c2cc(-c3ccccc3)cc(-n3c4ccccc4c4cc5c(cc43)-c3ccccc3C5(c3ccccc3)c3ccccc3)c2)cc1]

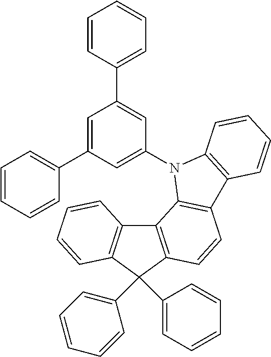 [SMILES: c1ccc(-c2cc(-c3ccccc3)cc(-n3c4ccccc4c4ccc5c(c43)-c3ccccc3C5(c3ccccc3)c3ccccc3)c2)cc1]

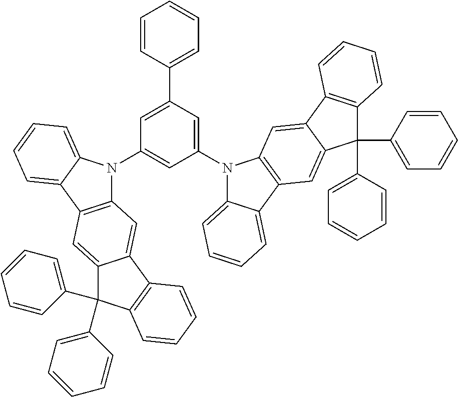 [SMILES: c1ccc(-c2cc(-n3c4ccccc4c4cc5c(cc43)-c3ccccc3C5(c3ccccc3)c3ccccc3)cc(-n3c4ccccc4c4cc5c(cc43)-c3ccccc3C5(c3ccccc3)c3ccccc3)c2)cc1]

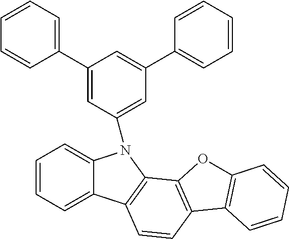 [SMILES: c1ccc(-c2cc(-c3ccccc3)cc(-n3c4ccccc4c4ccc5c6ccccc6oc5c43)c2)cc1]

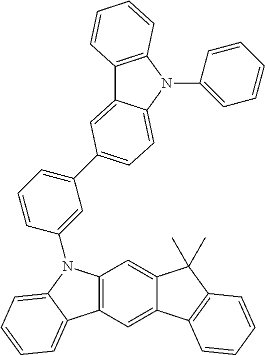 [SMILES: CC1(C)c2ccccc2-c2cc3c4ccccc4n(-c4cccc(-c5ccc6c(c5)c5ccccc5n6-c5ccccc5)c4)c3cc21]

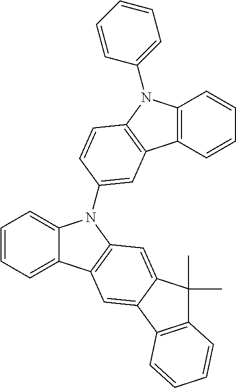 [SMILES: CC1(C)c2ccccc2-c2cc3c4ccccc4n(-c4ccc5c(c4)c4ccccc4n5-c4ccccc4)c3cc21]

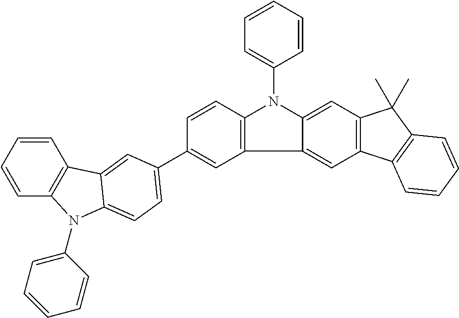 [SMILES: CC1(C)c2ccccc2-c2cc3c4cc(-c5ccc6c(c5)c5ccccc5n6-c5ccccc5)ccc4n(-c4ccccc4)c3cc21]

Preference is again furthermore given to the matrix compounds of the following formulae (85) to (91),

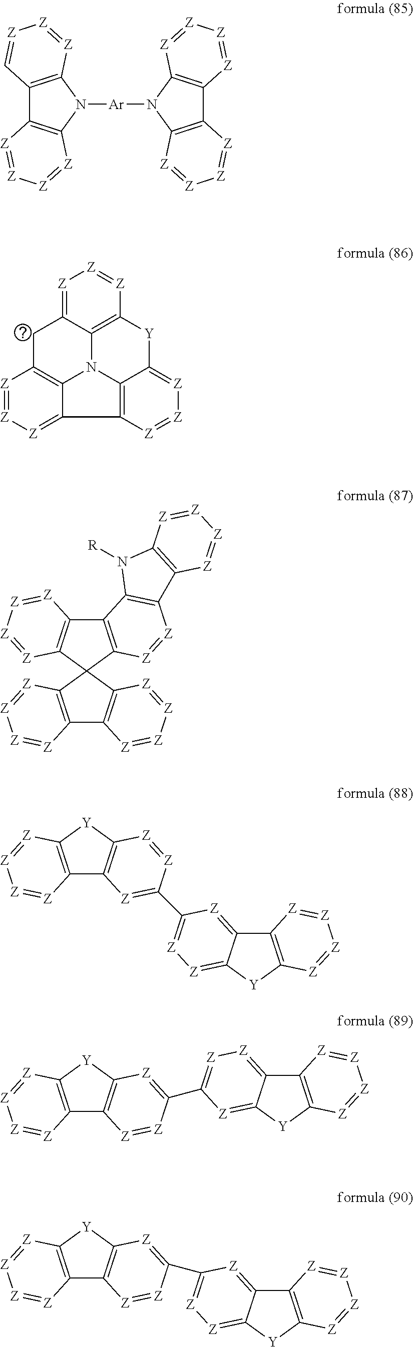

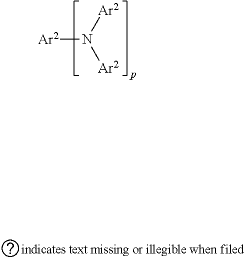

where the symbols and indices used have the same meanings as described above, and p stands for 1, 2, 3, 4, 5 or 6, in particular for 1, 2 or 3. Furthermore, two groups Ar⁴ which are bonded to the same nitrogen atom in the structure of the formula (91) may be bridged to one another by a group selected from NR, O, CR₂ and S.

In particular, the compounds of the formula (91) here are hole-transporting compounds.

Preferred embodiments of the compounds of the formulae (85) to (91) are furthermore compounds in which the symbols and indices used have the preferred meanings mentioned above.

Preferred embodiments of the compounds of the formula (85) are the structures shown in the following table.

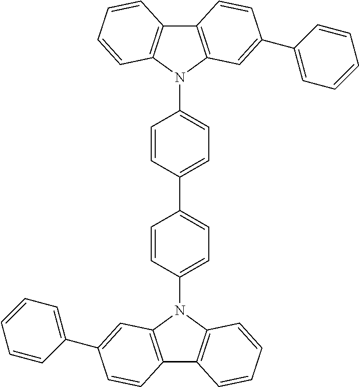 [SMILES: c1ccc(-c2ccc3c4ccccc4n(-c4ccc(-c5ccc(-n6c7ccccc7c7ccc(-c8ccccc8)cc76)cc5)cc4)c3c2)cc1]

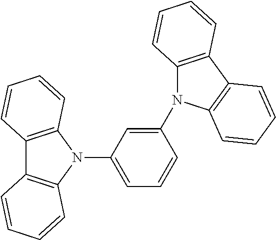 [SMILES: c1cc(-n2c3ccccc3c3ccccc32)cc(-n2c3ccccc3c3ccccc32)c1]

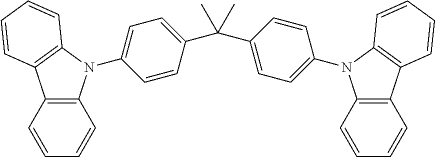 [SMILES: CC(C)(c1ccc(-n2c3ccccc3c3ccccc32)cc1)c1ccc(-n2c3ccccc3c3ccccc32)cc1]

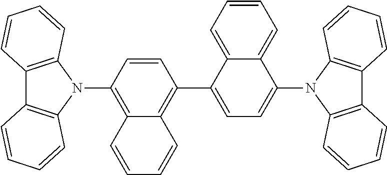 [SMILES: c1ccc2c(-n3c4ccccc4c4ccccc43)ccc(-c3ccc(-n4c5ccccc5c5ccccc54)c4ccccc34)c2c1]

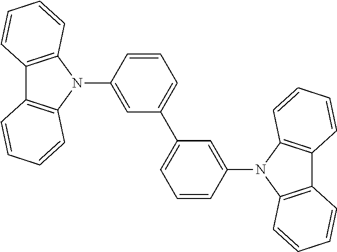 [SMILES: c1cc(-c2cccc(-n3c4ccccc4c4ccccc43)c2)cc(-n2c3ccccc3c3ccccc32)c1]

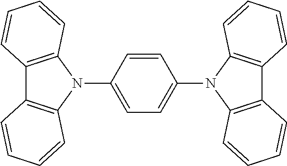 [SMILES: c1ccc2c(c1)c1ccccc1n2-c1ccc(-n2c3ccccc3c3ccccc32)cc1]

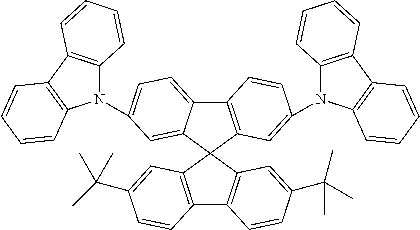 [SMILES: CC(C)(C)c1ccc2c(c1)C1(c3cc(-n4c5ccccc5c5ccccc54)ccc3-c3ccc(-n4c5ccccc5c5ccccc54)cc31)c1cc(C(C)(C)C)ccc1-2]

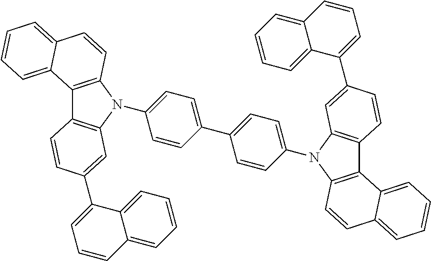 [SMILES: c1ccc2c(-c3ccc4c5c6ccccc6ccc5n(-c5ccc(-c6ccc(-n7c8cc(-c9cccc%10ccccc9%10)ccc8c8c9ccccc9ccc87)cc6)cc5)c4c3)cccc2c1]

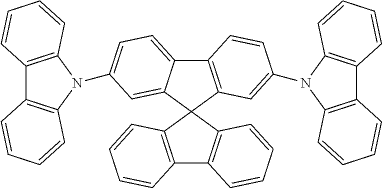 [SMILES: c1ccc2c(c1)-c1ccccc1C21c2cc(-n3c4ccccc4c4ccccc43)ccc2-c2ccc(-n3c4ccccc4c4ccccc43)cc21]

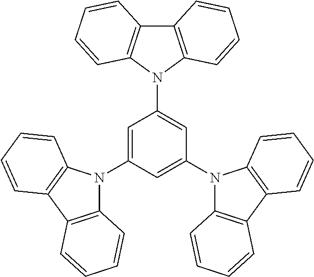 [SMILES: c1ccc2c(c1)c1ccccc1n2-c1cc(-n2c3ccccc3c3ccccc32)cc(-n2c3ccccc3c3ccccc32)c1]

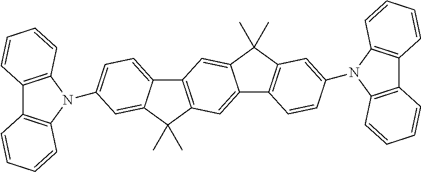 [SMILES: CC1(C)c2cc(-n3c4ccccc4c4ccccc43)ccc2-c2cc3c(cc21)-c1ccc(-n2c4ccccc4c4ccccc42)cc1C3(C)C]

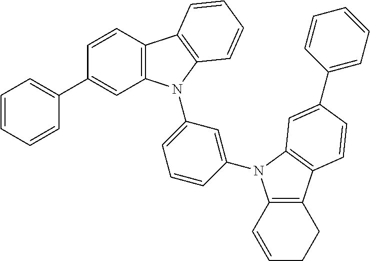 [SMILES: C1=Cc2c(c3ccc(-c4ccccc4)cc3n2-c2cccc(-n3c4ccccc4c4ccc(-c5ccccc5)cc43)c2)CC1]

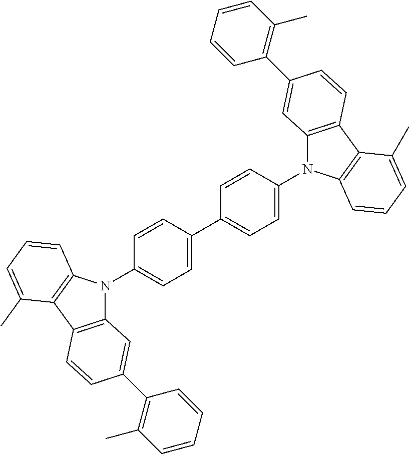

Preferred embodiments of the compounds of the formula (86) are the structures shown in the following table.

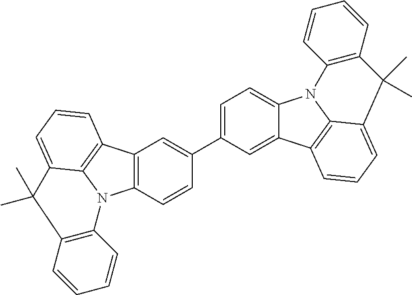

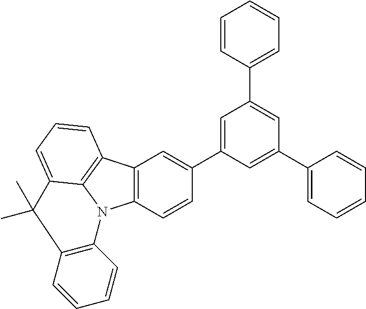 [SMILES: CC1(C)c2ccccc2-n2c3ccc(-c4cc(-c5ccccc5)cc(-c5ccccc5)c4)cc3c3cccc1c32]

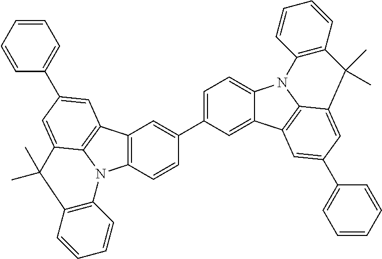 [SMILES: CC1(C)c2ccccc2-n2c3ccc(-c4ccc5c(c4)c4cc(-c6ccccc6)cc6c4n5-c4ccccc4C6(C)C)cc3c3cc(-c4ccccc4)cc1c32]

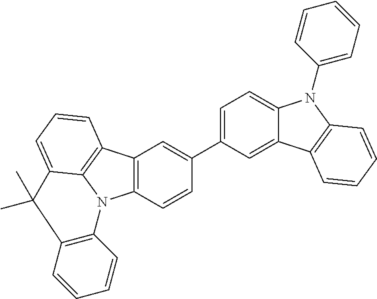 [SMILES: CC1(C)c2ccccc2-n2c3ccc(-c4ccc5c(c4)c4ccccc4n5-c4ccccc4)cc3c3cccc1c32]

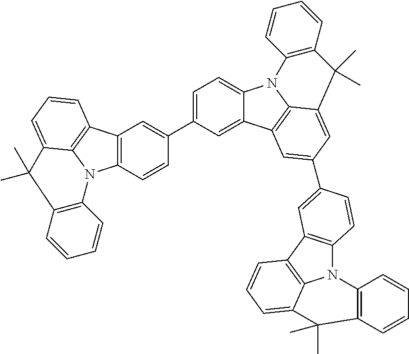 [SMILES: CC1(C)c2ccccc2-n2c3ccc(-c4ccc5c(c4)c4cc(-c6ccc7c(c6)c6cccc8c6n7-c6ccccc6C8(C)C)cc6c4n5-c4ccccc4C6(C)C)cc3c3cccc1c32]

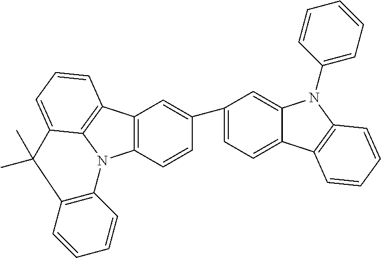 [SMILES: CC1(C)c2ccccc2-n2c3ccc(-c4ccc5c6ccccc6n(-c6ccccc6)c5c4)cc3c3cccc1c32]

Preferred embodiments of the compounds of the formula (87) are the structures shown in the following table.

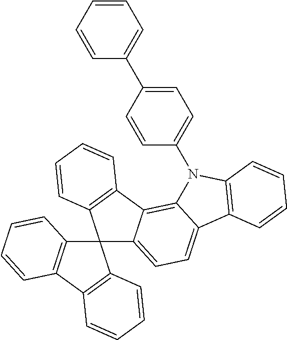 [SMILES: c1ccc(-c2ccc(-n3c4ccccc4c4ccc5c(c43)-c3ccccc3C53c4ccccc4-c4ccccc43)cc2)cc1]

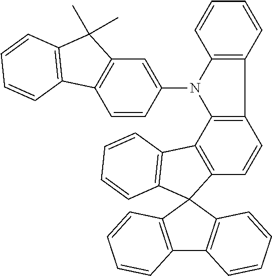 [SMILES: CC1(C)c2ccccc2-c2ccc(-n3c4ccccc4c4ccc5c(c43)-c3ccccc3C53c4ccccc4-c4ccccc43)cc21]

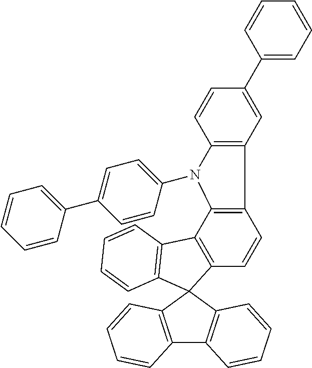 [SMILES: c1ccc(-c2ccc(-n3c4ccc(-c5ccccc5)cc4c4ccc5c(c43)-c3ccccc3C53c4ccccc4-c4ccccc43)cc2)cc1]

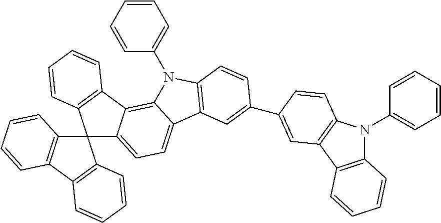 [SMILES: c1ccc(-n2c3ccccc3c3cc(-c4ccc5c(c4)c4ccc6c(c4n5-c4ccccc4)-c4ccccc4C64c5ccccc5-c5ccccc54)ccc32)cc1]

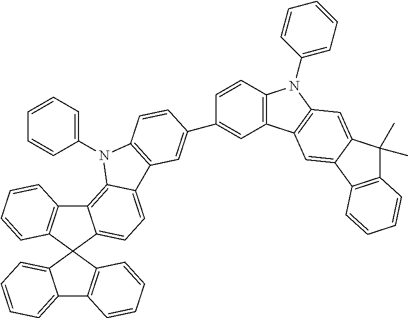 [SMILES: CC1(C)c2ccccc2-c2cc3c4cc(-c5ccc6c(c5)c5ccc7c(c5n6-c5ccccc5)-c5ccccc5C75c6ccccc6-c6ccccc65)ccc4n(-c4ccccc4)c3cc21]

Preferred embodiments of the compounds of the formulae (88) to (90) are the structures shown in the following table.

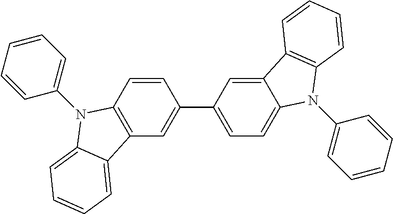 [SMILES: c1ccc(-n2c3ccccc3c3cc(-c4ccc5c(c4)c4ccccc4n5-c4ccccc4)ccc32)cc1]

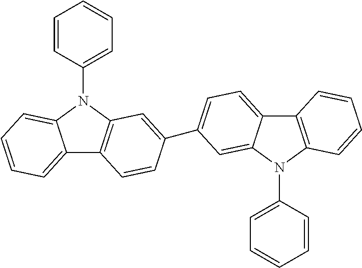 [SMILES: c1ccc(-n2c3ccccc3c3ccc(-c4ccc5c6ccccc6n(-c6ccccc6)c5c4)cc32)cc1]

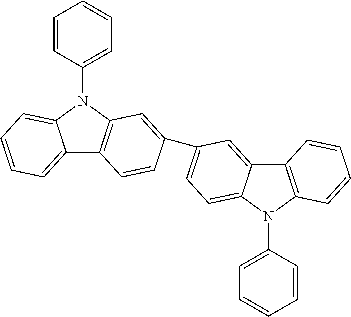 [SMILES: c1ccc(-n2c3ccccc3c3cc(-c4ccc5c6ccccc6n(-c6ccccc6)c5c4)ccc32)cc1]

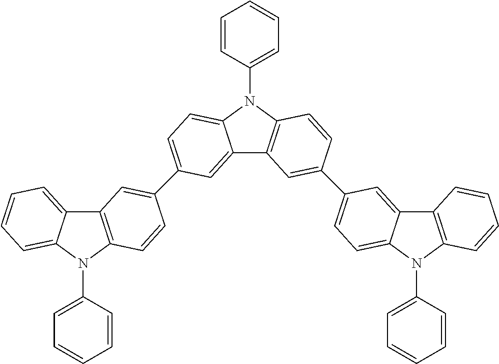 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

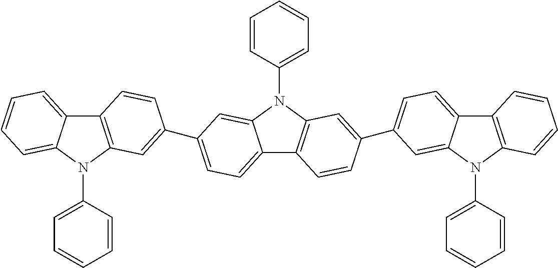 [SMILES: c1ccc(-n2c3ccccc3c3ccc(-c4ccc5c6ccc(-c7ccc8c9ccccc9n(-c9ccccc9)c8c7)cc6n(-c6ccccc6)c5c4)cc32)cc1]

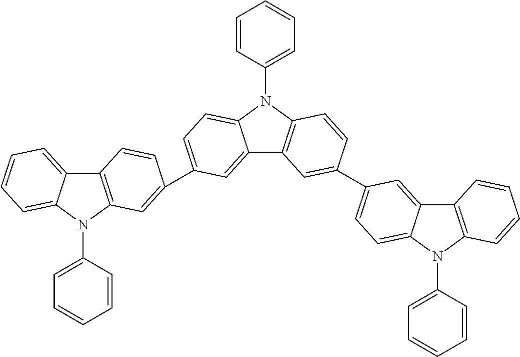 [SMILES: c1ccc(-n2c3ccccc3c3cc(-c4ccc5c(c4)c4cc(-c6ccc7c8ccccc8n(-c8ccccc8)c7c6)ccc4n5-c4ccccc4)ccc32)cc1]

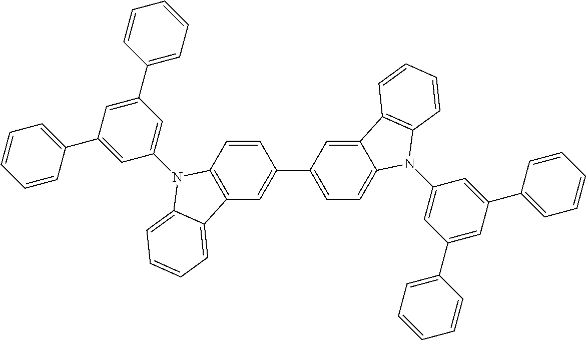 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1]

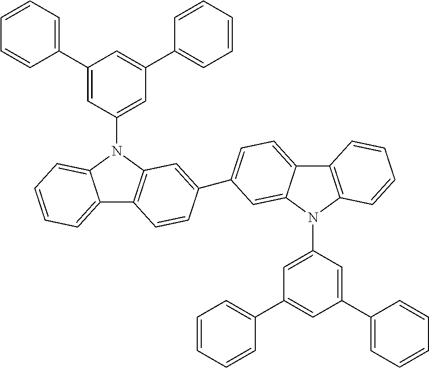 [SMILES: c1ccc(-c2cc(-c3ccccc3)cc(-n3c4ccccc4c4ccc(-c5ccc6c7ccccc7n(-c7cc(-c8ccccc8)cc(-c8ccccc8)c7)c6c5)cc43)c2)cc1]

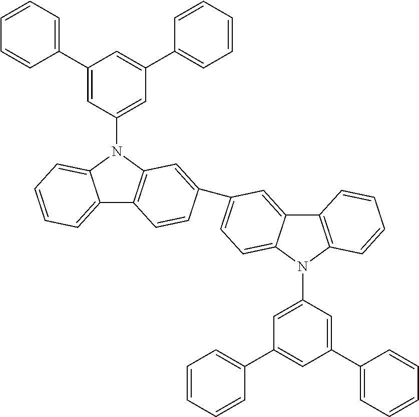 [SMILES: c1ccc(-c2cc(-c3ccccc3)cc(-n3c4ccccc4c4cc(-c5ccc6c7ccccc7n(-c7cc(-c8ccccc8)cc(-c8ccccc8)c7)c6c5)ccc43)c2)cc1]

The organic electroluminescent device is described in greater detail below.

The organic electroluminescent device comprises cathode, anode and emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers and/or charge-generation layers. However, it should be pointed out that each of these layers does not necessarily have to be present.

In the other layers of the organic electroluminescent device according to the invention, in particular in the hole-injection and -transport layers and in the electron-injection and -transport layers, use can be made of all materials as are usually employed in accordance with the prior art. The hole-transport layers here may also be p-doped and the electron-transport layers may also be n-doped. A p-doped layer here is taken to mean a layer in which free holes are generated and whose conductivity has thereby been increased. A comprehensive discussion of doped transport layers in OLEDs can be found in Chem. Rev. 2007, 107, 1233. The p-dopant is particularly preferably capable of oxidising the hole-transport material in the hole-transport layer, i.e. has a sufficiently high redox potential, in particular a higher redox potential than the hole-transport material. Suitable dopants are in principle all compounds which are electron-acceptor compounds and are able to increase the conductivity of the organic layer by oxidation of the host. The person skilled in the art will be able to identify suitable compounds without major effort on the basis of his general expert knowledge. Particularly suitable dopants are the compounds disclosed in WO 2011/073149, EP 1968131, EP 2276085, EP 2213662, EP 1722602, EP 2045848, DE 102007031220, U.S. Pat. No. 8,044,390, U.S. Pat. No. 8,057,712, WO 2009/003455, WO 2010/094378, WO 2011/120709 and US 2010/0096600.

The person skilled in the art will therefore be able to employ, without inventive step, all materials known for organic electroluminescent devices in combination with the emitting layer according to the invention.

The cathode preferably comprises metals having a low work function, metal alloys or multilayered structures comprising different metals, such as, for example, alkaline-earth metals, alkali metals, main-group metals or lanthanoids (for example Ca, Ba, Mg, Al, In, Mg, Yb, Sm, etc.). Furthermore suitable are alloys of an alkali metal or alkaline-earth metal and silver, for example an alloy of magnesium and silver. In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF₂, MgO, NaF, CsF, Cs₂CO₃, etc.). The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. At least one of the electrodes here must be transparent or partially transparent in order to facilitate the coupling-out of light. A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The device is correspondingly (depending on the application) structured, provided with contacts and finally hermetically sealed, since the lifetime of devices of this type is drastically shortened in the presence of water and/or air.

Preference is furthermore given to an organic electroluminescent device, characterised in that one or more layers are applied by means of a sublimation process, in which the materials are vapour-deposited in vacuum sublimation units at an initial pressure of less than 10⁻⁵ mbar, preferably less than 10⁻⁶ mbar. However, it is also possible for the pressure to be even lower, for example less than 10⁻⁷ mbar.

Preference is likewise given to an organic electroluminescent device, characterised in that one or more layers are applied by means of the OVPD (organic vapour-phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys, Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), inkjet printing or nozzle printing. Soluble compounds are necessary for this purpose, which are obtained, for example, by suitable substitution. These processes are also suitable, in particular, for oligomers, dendrimers and polymers.

These processes are generally known to the person skilled in the art and can be applied by him without inventive step to organic electroluminescent devices comprising the compounds according to the invention.

The present invention therefore furthermore relates to a process for the production of an organic electroluminescent device according to the invention, characterised in that at least one layer is applied by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

The organic electroluminescent devices according to the invention are distinguished over the prior art by one or more of the following surprising advantages:
1. The organic electroluminescent devices according to the invention have an improved lifetime compared with devices in accordance with the prior art.
2. The organic electroluminescent devices according to the invention have higher efficiency,
3. The organic electroluminescent devices according to the invention have a lower voltage.
4. The organic electroluminescent devices according to the invention have an improved roll-off behaviour.

These above-mentioned advantages arise in direct comparison with organic electroluminescent devices which otherwise have the same structure and comprise the same materials, but which comprise the same TADF compound in a lower doping concentration.

The invention is explained in greater detail by the following examples without wishing to restrict it thereby. The person skilled in the art will be able to carry out the invention throughout the range disclosed on the basis of the descriptions and produce further organic electroluminescent devices according to the invention without inventive step.

### EXAMPLES

### Determination of HOMO, LUMO, Singlet and Triplet Level

The HOMO and LUMO energy levels and the energy of the lowest triplet state T₁ or of the lowest excited singlet state S₁ of the materials are determined via quantum-chemical calculations. To this end, the “Gaussian09W” software package (Gaussian Inc.) is used. In order to calculate organic substances without metals (denoted by “org.” method in Table 4), firstly a geometry optimisation is carried out using the “Ground State/Semi-empirical/Default Spin/AM1/Charge 0/Spin Singlet” method. This is followed by an energy calculation on the basis of the optimised geometry. The “TD-SFC/DFT/Default Spin/B3PW91” method with the “6-31G(d)” base set is used here (Charge 0, Spin Singlet). For metal-containing compounds (denoted by “organom.” method in Table 4), the geometry is optimised via the “Ground State/Hartree-Fock/Default Spin/LanL2 MB/Charge 0/Spin Singlet” method. The energy calculation is carried out analogously to the organic substances as described above, with the difference that the “LanL2DZ” base set is used for the metal atom and the “6-31G(d)” base set is used for the ligands. The energy calculation gives the HOMO energy level HEh or LUMO energy level LEh in hartree units. The HOMO and LUMO energy levels calibrated with reference to cyclic voltammetry measurements are determined therefrom in electron volts as follows:

HOMO(eV)=((HEh*27.212)−0.9899)/1.1206

LUMO(eV)=((LEh*27.212)−2.0041)/1.385

These values are to be regarded in the sense of this application as HOMO and LUMO energy levels of the materials.

The lowest triplet state T₁ is defined as the energy of the triplet state having the lowest energy which arises from the quantum-chemical calculation described.

The lowest excited singlet state S₁ is defined as the energy of the excited singlet state having the lowest energy which arises from the quantum-chemical calculation described.

Table 4 below shows the HOMO and LUMO energy levels and S₁ and T₁ of the various materials.

### Determination of the PL Quantum Efficiency (PLQE)

A 50 nm thick film of the emission layers used in the various OLEDs is applied to a suitable transparent substrate, preferably quartz, i.e. the layer comprises the same materials in the same concentration as the OLED. The same production conditions are used here as in the production of the emission layer for the OLEDs. An absorption spectrum of this film is measured in the wavelength range from 350-500 nm. To this end, the reflection spectrum R(λ) and the transmission spectrum T(λ) of the sample are determined at an angle of incidence of 6° (i.e. virtually perpendicular incidence). The absorption spectrum in the sense of this application is defined as A(λ)=1−R(λ)−T(λ).

If A(λ)≦0.3 in the range 350-500 nm, the wavelength belonging to the maximum of the absorption spectrum in the range 350-500 nm is defined as λ_{exc}. If A(λ)>0.3 for any wavelength, the greatest wavelength at which A(λ) changes from a value less than 0.3 to a value greater than 0.3 or from a value greater than 0.3 to a value less than 0.3 is defined as λ^{exc}.

The PLQE is determined using a Hamamatsu C9920-02 measurement system. The principle is based on excitation of the sample by light of defined wavelength and measurement of the absorbed and emitted radiation. The sample is located in an Ulbricht sphere (“integrating sphere”) during measurement. The spectrum of the excitation light is approximately Gaussian with a full width at half maximum of <10 nm and a peak wavelength λ_{exc} as defined above. The PLQE is determined by the evaluation method which is usual for the said measurement system. It is vital to ensure that the sample does not come into contact with oxygen at any time, since the PLQE of materials having a small energetic separation between S₁ and T₁ is reduced very considerably by oxygen (H. Uoyama et al., Nature 2012, Vol. 492, 234).

Table 2 shows the PLQE for the emission layers of the OLEDs as defined above together with the excitation wavelength used.

### Determination of the Decay Time

The decay time is determined using a sample produced as described above under “Determination of the PL quantum efficiency (PLQE)”. The sample is excited at a temperature of 295 K by a laser pulse (wavelength 266 nm, pulse duration 1.5 ns, pulse energy 200 ρJ, ray diameter 4 mm). The sample is located in a vacuum (<10⁻⁵ mbar) here. After the excitation (defined as t=0), the change in the intensity of the emitted photoluminescence over time is measured. The photoluminescence exhibits a steep drop at the beginning, which is attributable to the prompt fluorescence of the TADF compound. As time continues, a slower drop is observed, the delayed fluorescence (see, for example, H. Uoyama et al., Nature, vol. 492, no. 7428, pp. 234-238, 2012 and K. Masui et al., Organic Electronics, vol. 14, no. 11, pp. 2721-2726, 2013). The decay time tₐ in the sense of this application is the decay time of the delayed fluorescence and is determined as follows: a time t_{d} is selected at which the prompt fluorescence has decayed significantly below the intensity of the delayed fluorescence (<1%), so that the following determination of the decay time is not influenced thereby. This choice can be made by a person skilled in the art. For the measurement data from time t_{d}, the decay time tₐ=tₑ−t_{d} is determined. tₑ here is the time after t=t_{d} at which the intensity has for the first time dropped to 1/e of its value at t=t_{d}.

Table 2 shows the values of tₐ and t_{d} which are determined for the emission layers of the OLEDs according to the invention.

### Determination of Vapour-Deposition Rates and Layer Thicknesses

For the production of a film comprising two materials A and B in which material A is present in an amount of X % by vol. and material B is present in an amount of (100−X) % by vol., the vapour-deposition rates RA for material A and RB for material B are set in such a way that RA/RB=X/(100−X). The two materials are subsequently evaporated together until a layer of the desired thickness is obtained. The vapour-deposition rates are controlled with the aid of vibrating quartz crystals. The rates RA and RB here are calibrated vapour-deposition rates. In order to calibrate these vapour-deposition rates, the following procedure is followed in each case: a layer of the pure material is applied to a glass substrate through a shadow mask, the time required for this is denoted by tₜₑₛₜ, the rate recorded by the vibrating quartz crystal is denoted by Rₜₑₛₜ. During the coating through the shadow mask, a step forms between coated and uncoated regions. An aluminium layer with a thickness of 100 nm is then applied, which is formed in such a way that the step and a sufficiently large, adjacent region are covered by it for the subsequent layer-thickness measurement. The layer thickness D corresponds to the height of the step between coated and uncoated regions, which is determined with the aid of a Dektak profilometer (pressure 5 mg, tip radius 25 μm). The calibrated rate R=D/tₜₑₛₜ is determined from the layer thickness D, which is now known, and the vapour-deposition time. If the measured layer thickness is less than 80 nm, the calibration is repeated, with the vapour-deposition time being adjusted in accordance with the formula tₜₑₛₜ=100 nm/R.

### Production of the OLEDs

The data of various OLEDs are presented in Examples V1 to E13 below (see Tables 1 and 2).

Glass plates coated with structured ITO (indium tin oxide) in a thickness of 50 nm form the substrates for the OLEDs. The substrates are wet-cleaned (dishwasher, Merck Extran detergent), subsequently dried by heating at 250° C. for 15 min and treated with an argon plasma for 150 s and then with an oxygen plasma for 130 s before the coating (for Examples V1-E7 and E1-E9), The glass plates for Examples V8-V11 and E10-E13 are treated with an oxygen plasma for 130 s. These plasma-treated glass plates form the substrates to which the OLEDs are applied. The substrates remain in vacuo before the coating. The coating begins at the latest 10 min after the plasma treatment.

The OLEDs have in principle the following layer structure: substrate/optional hole-injection layer (HIL)/optional hole-transport layer (HTL)/optional interlayer (IL)/electron-blocking layer (EBL)/emission layer (EML)/hole-blocking layer (HBL)/electron-transport layer (ETL)/optional electron-injection layer (EIL) and finally a cathode. The cathode is formed by an aluminium layer with a thickness of 100 nm. The precise structure of the OLEDs is shown in Table 2. The materials required for the production of the OLEDs are shown in Table 3.

All materials are applied by thermal vapour deposition in a vacuum chamber. The emission layer here always consists of a matrix material (host material) and the TADF compound, i.e. the emitting material which exhibits a small energetic difference between S₁ and T₁. This is admixed with the matrix material in a certain proportion by volume by co-evaporation. An expression such as IC1:D1 (95%:5%) here means that material IC1 is present in the layer in a proportion by volume of 95% and D1 is present in the layer in a proportion of 5%. Analogously, the electron-transport layer may also consist of a mixture of two materials.

The OLEDs are characterised by standard methods. For this purpose, the electroluminescence spectra, the current efficiency (measured in cd/A), the power efficiency (measured in lm/W) and the external quantum efficiency (EQE, measured in percent) as a function of the luminous density, calculated from current/voltage/luminous density characteristic lines (IUL characteristic lines) assuming Lambert emission characteristics, and the lifetime are determined. The electroluminescence spectra are determined at a luminous density of 1000 cd/m², and the CIE 1931 x and y colour coordinates are calculated therefrom. The term U1000 in Table 2 denotes the voltage required for a luminous density of 1000 cd/m². CE1000 and PE1000 denote the current and power efficiency respectively which are achieved at 1000 cd/m². Finally, EQE1000 denotes the external quantum efficiency at an operating luminous density of 1000 cd/m².

The roll-off is defined as EQE at 5000 cd/m² divided by EQE at 500 cd/m², i.e. a high value corresponds to a small drop in the efficiency at high luminous densities, which is advantageous.

The lifetime LT is defined as the time after which the luminous density drops from the initial luminous density to a certain proportion L1 on operation at constant current. An expression of j0=10 mA/cm², L1=80% in Table 2 means that the luminous density drops to 80% of its initial value after time LT on operation at 10 mA/cm².

The emitting dopant employed in the emission layer is compound D1, which has an energetic separation between S₁ and T₁ of 0.09 eV, or compound D2, for which the difference between S₁ and T₁ is 0.06 eV

The data for the various OLEDs are summarised in Table 2. Examples V1-V11 are comparative examples in accordance with the prior art, Examples E1-E13 show data of OLEDs according to the invention. Some of the examples are described in greater detail below, where it should be noted that this only represents a selection of the data shown in the table.

Through the use of the TADF compound in higher concentrations, a significant improvement in the lifetime is obtained. For example, virtually double the lifetime is obtained for Example E4 (10% by vol.) than for Example V4 (5% by vol.). The very good efficiency of greater than 20% EQE is retained even at the higher concentration of 10% by vol. of the TADF compound. A further increase in the lifetime is possible by increasing the concentration to 15% by vol. of the TADF compound.

By increasing the concentration, it is furthermore possible to improve the efficiency, as shown by the comparison of Example E6 with V5 or E7 with V6.

Examples E1-E3, E8 and E9 show that an improvement in the operating voltage can furthermore be achieved.

Furthermore, an improvement in the roll-off behaviour through the use of higher concentrations of the TADF compound can also be observed (for example Examples V3, E3).

TABLE 1
Structure of the OLEDs

| | HIL | HTL | IL | EBL | EML | HBL | ETL | EIL |
|---|---|---|---|---|---|---|---|---|
| Ex. | Thickness | Thickness | Thickness | Thickness | Thickness | Thickness | Thickness | Thickness |
| V1 | HAT | — | — | SpA1 | IC3:D1 | IC1 | ST2:LiQ | — |
| | 5 nm | | | 85 nm | (95%:5%) | 10 nm | (50%:50%) | |
| | | | | | 15 nm | | 40 nm | |
| V2 | — | — | — | SpA1 | IC4:D1 | IC1 | ST2:LiQ | — |
| | | | | 90 nm | (95%:5%) | 10 nm | (50%:50%) | |
| | | | | | 15 nm | | 40 nm | |
| V3 | SpMA1:F4T | — | — | SpMA1 | IC4:D1 | IC1 | ST2:LiQ | — |
| | (95%:5%) | | | 80 nm | (95%:5%) | 10 nm | (50%:50%) | |
| | 10 nm | | | | 15 nm | | 40 nm | |
| V4 | HAT | SpA1 | HAT | SpMA1 | IC1:D1 | IC1 | ST2:LiQ | — |
| | 5 nm | 70 nm | 5 nm | 20 nm | (95%:5%) | 10 nm | (50%:50%) | |
| | | | | | 15 nm | | 40 nm | |
| V5 | SpMA1:F4T | SpMA1 | — | SpMA2 | IC1:D1 | IC1 | ST2:LiQ | — |
| | (95%:5%) | 80 nm | | 10 nm | (95%:5%) | 10 nm | (50%:50%) | |
| | 10 nm | | | | 15 nm | | 40 nm | |
| V6 | SpMA1:F4T | SpMA1 | IC2 | CBP | IC1:D1 | IC1 | ST2 | LiQ |
| | (95%:5%) | 65 nm | 10 nm | 5 nm | (95%:5%) | 10 nm | 40 nm | 3 nm |
| | 10 nm | | | | 15 nm | | | |
| V7 | SpMA1:F4T | SpMA1 | SpMA2 | IC2 | BCP:D1 | IC1 | ST2 | LiQ |
| | (95%:5%) | 65 nm | 10 nm | 5 nm | (95%:5%) | 10 nm | 40 nm | 3 nm |
| | 10 nm | | | | 15 nm | | | |
| V8 | — | — | — | SpMA1 | CBP:D2 | IC1 | ST2 | LiQ |
| | | | | 90 nm | (95%:5%) | 10 nm | 45 nm | 3 nm |
| | | | | | 15 nm | | | |
| V9 | — | — | — | SpMA1 | IC1:D2 | IC1 | ST2 | LiQ |
| | | | | 90 nm | (95%:5%) | 10 nm | 45 nm | 3 nm |
| | | | | | 15 nm | | | |
| V10 | — | — | — | SpMA1 | IC6:D2 | IC1 | ST2 | LiQ |
| | | | | 90 nm | (95%:5%) | 10 nm | 45 nm | 3 nm |
| | | | | | 15 nm | | | |
| V11 | — | — | — | SpMA1 | L1:D2 | IC1 | ST2 | LiQ |
| | | | | 90 nm | (95%:5%) | 10 nm | 45 nm | 3 nm |
| | | | | | 15 nm | | | |
| E1 | HAT | — | — | SpA1 | IC3:D1 | IC1 | ST2:LiQ | — |
| | 5 nm | | | 85 nm | (90%:10%) | 10 nm | (50%:50%) | |
| | | | | | 15 nm | | 40 nm | |
| E2 | — | — | — | SpA1 | IC4:D1 | IC1 | ST2:LiQ | — |
| | | | | 90 nm | (90%:10%) | 10 nm | (50%:50%) | |
| | | | | | 15 nm | | 40 nm | |
| E3 | SpMA1:F4T | — | — | SpMA1 | IC4:D1 | IC1 | ST2:LiQ | — |
| | (95%:5%) | | | 80 nm | (90%:10%) | 10 nm | (50%:50%) | |
| | 10 nm | | | | 15 nm | | 40 nm | |
| E4 | HAT | SpA1 | HAT | SpMA1 | IC1:D1 | IC1 | ST2:LiQ | — |
| | 5 nm | 70 nm | 5 nm | 20 nm | (90%:10%) | 10 nm | (50%:50%) | |
| | | | | | 15 nm | | 40 nm | |
| E5 | HAT | SpA1 | HAT | SpMA1 | IC1:D1 | IC1 | ST2:LiQ | — |
| | 5 nm | 70 nm | 5 nm | 20 nm | (85%:15%) | 10 nm | (50%:50%) | |
| | | | | | 15 nm | | 40 nm | |
| E6 | SpMA1:F4T | SpMA1 | — | SpMA2 | IC1:D1 | IC1 | ST2:LiQ | — |
| | (95%:5%) | 80 nm | | 10 nm | (90%:10%) | 10 nm | (50%:50%) | |
| | 10 nm | | | | 15 nm | | 40 nm | |
| E7 | SpMA1:F4T | SpMA1 | IC2 | CBP | IC1:D1 | IC1 | ST2 | LiQ |
| | (95%:5%) | 65 nm | 10 nm | 5 nm | (90%:10%) | 10 nm | 40 nm | 3 nm |
| | 10 nm | | | | 15 nm | | | |
| E8 | SpMA1:F4T | SpMA1 | IC2 | CBP | IC1:D1 | IC1 | ST2 | LiQ |
| | (95%:5%) | 65 nm | 10 nm | 5 nm | (85%:15%) | 10 nm | 40 nm | 3 nm |
| | 10 nm | | | | 15 nm | | | |
| E9 | SpMA1:F4T | SpMA1 | SpMA2 | IC2 | BCP:D1 | IC1 | ST2 | LiQ |
| | (95%:5%) | 65 nm | 10 nm | 5 nm | (85%:15%) | 10 nm | 40 nm | 3 nm |
| | 10 nm | | | | 15 nm | | | |
| E10 | — | — | — | SpMA1 | CBP:D2 | IC1 | ST2 | LiQ |
| | | | | 90 nm | (90%:10%) | 10 nm | 45 nm | 3 nm |
| | | | | | 15 nm | | | |
| E11 | — | — | — | SpMA1 | IC1:D2 | IC1 | ST2 | LiQ |
| | | | | 90 nm | (90%:10%) | 10 nm | 45 nm | 3 nm |
| | | | | | 15 nm | | | |
| E12 | — | — | — | SpMA1 | IC6:D2 | IC1 | ST2 | LiQ |
| | | | | 90 nm | (90%:10%) | 10 nm | 45 nm | 3 nm |
| | | | | | 15 nm | | | |
| E13 | — | — | — | SpMA1 | L1:D2 | IC1 | ST2 | LiQ |
| | | | | 90 nm | (90%:10%) | 10 nm | 45 nm | 3 nm |
| | | | | | 15 nm | | | |

TABLE 2
Data of the OLEDs

| | U1000 | CE1000 | PE1000 | EQE | CIE x/y at | Roll- | | | LT | | λₑₓₒ | t_{d} | tₑ |
|---|---|---|---|---|---|---|---|---|---|---|---|---|---|
| Ex. | (V) | (cd/A) | (lm/W) | 1000 | 1000 cd/m² | off | j0 | L1 % | (h) | PLQE % | nm | μs | μs |
| V1 | 4.0 | 42 | 33 | 12.5% | 0.32/0.60 | 0.72 | 10 mA/cm² | 80 | 82 | 77 | 350 | 7 | 7.0 |
| V2 | 5.7 | 21 | 12 | 6.5% | 0.29/0.59 | 0.61 | 10 mA/cm² | 80 | 33 | 84 | 359 | 6 | 4.3 |
| V3 | 4.0 | 46 | 36 | 14.0% | 0.28/0.60 | 0.61 | 10 mA/cm² | 80 | 38 | 84 | 359 | 6 | 4.3 |
| V4 | 3.6 | 65 | 56 | 20.8% | 0.25/0.58 | 0.72 | 10 mA/cm² | 80 | 44 | 92 | 350 | 7 | 5.4 |
| V5 | 3.3 | 67 | 64 | 21.1% | 0.26/0.59 | 0.70 | 10 mA/cm² | 80 | 52 | 92 | 350 | 7 | 5.4 |
| V6 | 3.2 | 68 | 66 | 21.3% | 0.26/0.58 | 0.73 | 10 mA/cm² | 80 | 38 | 92 | 350 | 7 | 5.4 |
| V7 | 6.6 | 5.3 | 2.5 | 1.7% | 0.25/0.56 | 0.58 | 10 mA/cm² | 80 | 1 | 59 | 350 | 6 | 5.9 |
| V8 | 8.1 | 20 | 7.6 | 6.7% | 0.49/0.49 | 0.64 | 10 mA/cm² | 80 | 14 | 43 | 350 | 6 | 5.1 |
| V9 | 5.3 | 27 | 16 | 9.6% | 0.51/0.48 | 0.80 | 10 mA/cm² | 80 | 69 | 41 | 350 | 7 | 4.6 |
| V10 | 8.1 | 14.4 | 5.6 | 5.8% | 0.52/0.46 | 0.77 | 10 mA/cm² | 80 | 68 | 37 | 350 | 6 | 5.3 |
| V11 | 5.8 | 20 | 10.8 | 7.8% | 0.52/0.47 | 0.76 | 10 mA/cm² | 80 | 165 | 46 | 368 | 7 | 4.3 |
| E1 | 3.9 | 51 | 42 | 15.7% | 0.29/0.59 | 0.70 | 10 mA/cm² | 80 | 68 | 74 | 350 | 6 | 6.2 |
| E2 | 5.4 | 22 | 13 | 6.6% | 0.30/0.60 | 0.79 | 10 mA/cm² | 80 | 83 | 77 | 360 | 6 | 4.5 |
| E3 | 3.9 | 53 | 43 | 15.8% | 0.29/0.60 | 0.66 | 10 mA/cm² | 80 | 69 | 77 | 360 | 6 | 4.5 |
| E4 | 3.6 | 67 | 58 | 20.2% | 0.29/0.60 | 0.73 | 10 mA/cm² | 80 | 83 | 87 | 350 | 7 | 4.9 |
| E5 | 3.6 | 59 | 51 | 17.5% | 0.31/0.60 | 0.76 | 10 mA/cm² | 80 | 102 | 81 | 350 | 7 | 4.8 |
| E6 | 3.3 | 74 | 70 | 22.0% | 0.30/0.60 | 0.72 | 10 mA/cm² | 80 | 63 | 87 | 350 | 7 | 4.9 |
| E7 | 3.2 | 74 | 73 | 22.4% | 0.29/0.60 | 0.74 | 10 mA/cm² | 80 | 44 | 87 | 350 | 7 | 4.9 |
| E8 | 3.1 | 72 | 72 | 21.1% | 0.32/0.60 | 0.75 | 10 mA/cm² | 80 | 49 | 81 | 350 | 7 | 4.8 |
| E9 | 4.9 | 9.8 | 6.3 | 2.9% | 0.31/0.60 | 0.72 | 10 mA/cm² | 80 | 1 | 90 | 350 | 7 | 6.3 |
| E10 | 8.1 | 14.6 | 5.7 | 6.3% | 0.54/0.45 | 0.71 | 10 mA/cm² | 80 | 25 | 35 | 350 | 5 | 4.9 |
| E11 | 5.9 | 16.2 | 8.6 | 7.3% | 0.55/0.44 | 0.80 | 10 mA/cm² | 80 | 95 | 33 | 350 | 6 | 6.2 |
| E12 | 8.0 | 12.7 | 5.0 | 5.7% | 0.54/0.44 | 0.80 | 10 mA/cm² | 80 | 76 | 29 | 350 | 6 | 5.0 |
| E13 | 6.4 | 14.5 | 7.2 | 6.5% | 0.55/0.44 | 0.78 | 10 mA/cm² | 80 | 210 | 37 | 370 | 7 | 4.6 |

TABLE 3
Structural formulae of the materials for the OLEDs

| | |
|---|---|
| 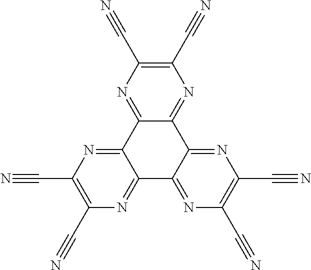 HAT | 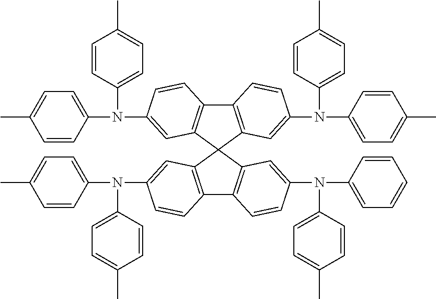 |
| | SpA1 |
| 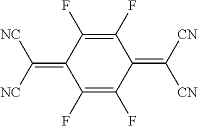 F4T | 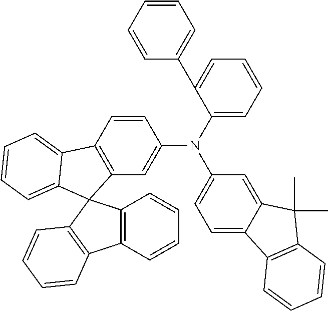 |
| | SpMA1 |
| 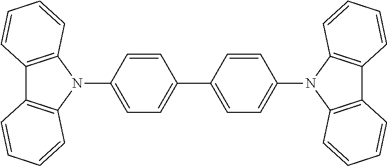 CBP | 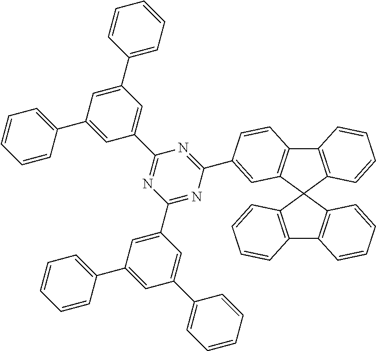 |
| | ST2 |
| 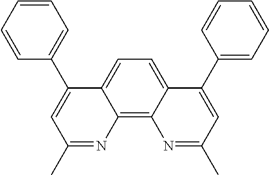 | 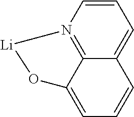 LiQ |
| BCP | |
| 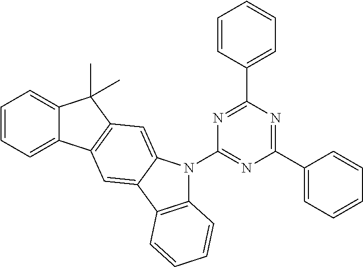 IC1 | 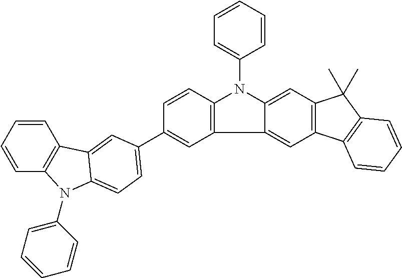 IC2 |
| 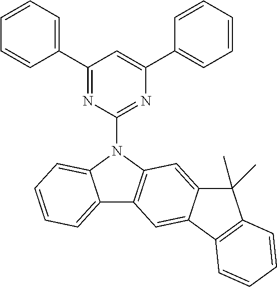 | 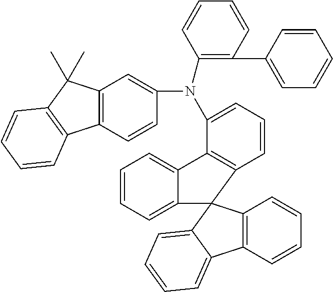 |
| IC3 | SpMA2 |
| 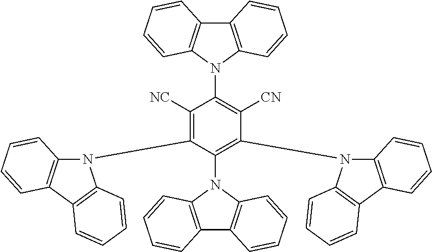 | 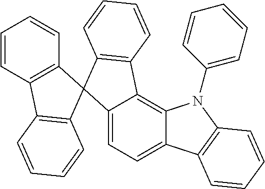 IC4 |
| D1 | |
| 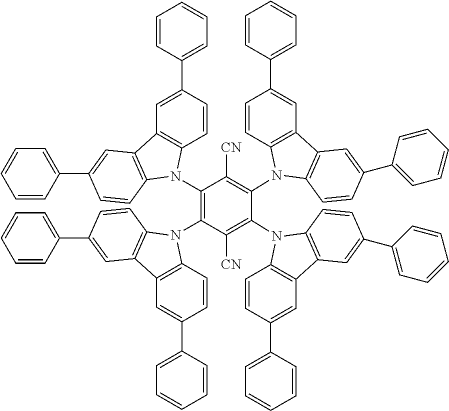 | 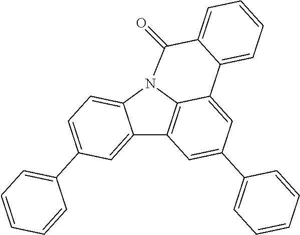 L1 |
| D2 | |
| 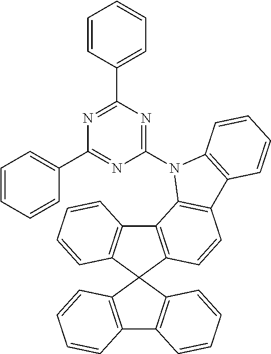 IC6 | |

TABLE 4
HOMO, LUMO, T₁, S₁ of the
relevant materials

| | | HOMO | LUMO | S₁ | T₁ |
|---|---|---|---|---|---|
| Material | Method | (ev) | (ev) | (ev) | (ev) |
| D1 | org. | −6.11 | −3.40 | 2.50 | 2.41 |
| D2 | org. | −5.92 | −3.61 | 2.09 | 2.03 |
| CBP | org. | −5.67 | −2.38 | 3.59 | 3.11 |
| BCP | org. | −6.15 | −2.44 | 3.61 | 2.70 |
| IC1 | org. | −5.79 | −2.83 | 3.09 | 2.69 |
| IC3 | org. | −5.62 | −2.75 | 3.02 | 2.75 |
| IC4 | org. | −5.74 | −2.23 | 3.59 | 2.72 |
| SpA1 | org. | −4.87 | −2.14 | 2.94 | 2.34 |
| SpMA1 | org. | −5.25 | −2.18 | 3.34 | 2.58 |
| IC2 | org. | −5.40 | −2.11 | 3.24 | 2.80 |
| HAT | org. | −8.86 | −4.93 | | |
| F4T | org. | −7.91 | −5.21 | | |
| ST2 | org. | −6.03 | −2.82 | 3.32 | 2.68 |
| LiQ | organom. | −5.17 | −2.39 | 2.85 | 2.13 |
| L1 | org. | −6.09 | −2.80 | 2.70 | 3.46 |
| IC6 | org. | −5.87 | −2.85 | 2.72 | 3.14 |

1.-11. (canceled)

12. An organic electroluminescent device comprising cathode, anode and emitting layer, which comprises the following compounds:
(A) a matrix compound; and
(B) a luminescent organic compound which has a separation between the lowest triplet state T₁ and the first excited singlet state S₁ of ≦0.15 eV (TADF compound),
wherein the TADF compound is present in the emitting layer in a doping concentration of 7% by vol. or more.

13. The organic electroluminescent device according to claim 12, wherein the TADF compound in a layer in a mixture with the matrix compound has a luminescence quantum efficiency of at least 40%.

14. The organic electroluminescent device according to claim 12, wherein the separation between S₁ and T₁ of the TADF compound is ≦0.10 eV.

15. The organic electroluminescent device according to claim 12, wherein the separation between S₁ and T₁ of the TADF compound is ≦0.08 eV.

16. The organic electroluminescent device according to claim 12, wherein the separation between S₁ and T₁ of the TADF compound is ≦0.05 eV.

17. The organic electroluminescent device according to claim 12, wherein the TADF compound is an aromatic compound which has both donor and also acceptor substituents.

18. The organic electroluminescent device according to claim 12, wherein the following applies to the LUMO of the TADF compound LUMO(TADF) and the HOMO of the matrix HOMO(matrix):
LUMO(TADF)−HOMO(matrix)>S₁(TADF)−0.4 eV,
where S₁(TADF) is the first excited singlet state S₁ of the TADF compound.

19. The organic electroluminescent device according to claim 12, wherein the doping concentration of the TADF compound in the emitting layer is 25% by vol. or less.

20. The organic electroluminescent device according to claim 12, wherein the doping concentration of the TADF compound in the emitting layer is 7 to 20% by vol.

21. The organic electroluminescent device according to claim 12, wherein the doping concentration of the TADF compound in the emitting layer is 9 to 18% by vol.

22. The organic electroluminescent device according to claim 12, wherein the doping concentration of the TADF compound in the emitting layer is 10 to 15% by vol.

23. The organic electroluminescent device according to claim 12, wherein the lowest triplet energy of the matrix compound is a maximum of 0.1 eV lower than the triplet energy of the TADF compound.

24. The organic electroluminescent device according to claim 12, wherein the matrix compound is an electron-transporting or hole-transporting or bipolar compound or a non-charge-transporting compound.

25. The organic electroluminescent device according to claim 12, wherein the matrix compound is selected from the group consisting of ketones, phosphine oxides, sulfoxides, sulfones, triarylamines, carbazoles, indolocarbazoles, indenocarbazoles, azacarbazoles, bipolar matrix materials, silanes, azaboroles, boronic esters, diazasiloles, diazaphospholes, triazines, pyrimidines, lactams, quinoxalines, Be complexes, Zn complexes, Al complexes and bridged carbazoles.

26. Process for the production of the organic electroluminescent device according to claim 12, which comprises applying at least one layer by means of a sublimation process and/or in that at least one layer is applied by means of an organic vapour phase deposition process or with the aid of carrier-gas sublimation and/or in that at least one layer is applied from solution, by spin coating or by means of a printing process.
